(19) United States
(12) Patent Application Publication
(10) Pub. No.: US 2010/0219991 A1
(43) Pub. Date: Sep. 2, 2010

(54) New Generation Data Compression Methods

(76) Inventor: Bob Tang, London (GB)

Correspondence Address: Bob Tang, Flat 82 Eton Hall, Eton College Road, London, NW3 2DH, GB

(21) Appl. No.: 12/087,894

(22) PCT Filed: Jan. 23, 2007
(86) PCT No.: PCT/GB2007/000224

§ 371 Date: Jul. 17, 2008

(30) Foreign Application Priority Data
Jan. 23, 2006 (GB) 0601232.2
Jan. 23, 2006 (GB) 0601306.4
Jan. 27, 2006 (GB) 0601604.2
Feb. 24, 2006 (GB) 0603730.3
Feb. 24, 2006 (GB) 0603780.8

(51) Int. Cl. H03M 5/00; H03M 7/00; H03M 7/40

(52) U.S. Cl. 341/55; 341/50; 341/67

(57) ABSTRACT

Methods or sub-component method step/s necessary for lossless data compressions of input binary (or adaptable for even N-ary) data file, or for compression/representation of sequential list of positive integers (or offsetted to all be positive integers >0, which may be a sequential list of variable length binary base positive integer digit numbers or even N-ary base positive integer digit numbers) are described, providing many magnitudes orders improvements over existing state-of-art best available methods such as Rice-Coulomb encodings/RunLength based/LZW encodings . . . etc.

The methods or sub-component method step/s further makes possible or forms the basis/sub-component method step/s for ‘infinite data compressions’ algorithms to be adapted designed implemented.

very powerful new digital data compression technique principles are presented here (for all digitised video, image, audio, texts, software binaries . . . etc storage & transmissions):

In digitised files, when stored in binary representation the file consists of sequences of ‘0’s & ‘1’s. Take the example of an original binary data file with 1 Million binary digits, the file will consists of sequential sequences of ‘0’s & ‘1’s of various consecutive lengths.

The number of consecutive ‘0’s (or consecutive ‘1’s) followed by a number of consecutive ‘1’s (or consecutive ‘0’s) which is in turn followed by a number of consecutive ‘0’ (or consecutive ‘1’s) . . . & so forth (successive sequential number of bits of alternately ‘0’s & ‘1’s, from the very 1^{st} consecutive bit/s pattern to the very last bit/s pattern in the original binary data file) varies, & would need to be represented/provided/recorded by binary digit/s of variable lengths, such as existing Rice encoding . . . etc which incidentally does not guarantee the number of bits required to encode a consecutive number of bit/s all of same binary value ‘always’ does not exceed the consecutive number of bit/s all of same binary value to be represented/encoded.

A method to encode/represent/provide/record a sequential list of variable length binary digit numbers is to eg use a single ‘0’ bit to represent 1 consecutive # of bit (all of same binary value), ‘10 ’ to represent 2 consecutive # of bits, ‘110’ to represent 3 consecutive # of bits, ‘111’ to notify that the consecutive # of bits is now to be ‘extended’ represented by further additional bit/s: as example an occurrence of a further single ‘0’ to now represent 4 consecutive # of bits (cumulative bits pattern here is ‘1110’, which is ‘111’ followed by ‘0’), an occurrence of a further single ‘10’ to now represent 5 consecutive # of bits (cumulative bits pattern here is ‘11110’, which is ‘111’ followed by ‘10’), an occurrence of a further ‘110’ to now represent 6 consecutive # of bits (cumulative bits pattern here is ‘111110’, which is ‘111’ followed by ‘110’), an occurrence of a further ‘111’ to now notify that the consecutive # of bits is now to be ‘extended’ represented by further additional bit/s (cumulative bits pattern here is ‘111111x . . . x’, which is ‘111’ followed by ‘111’ and further followed by the variable length bit/s ‘x . . . x’ to be supplied, eg 7 is to be represented by cumulative bits pattern ‘1111110’, 8 is to be represented by ‘11111110’, 9 is to be represented by ‘111111110’, 10 is to be represented by ‘1111111110’, 11 is to be represented by ‘11111111110’, 12 is to be represented by ‘111111111110’, 16 is to be represented by ‘1111111111111110’ . . . etc and so forth) . . . and so forth. Note here positive integer number N could always be represented in above scheme by (N−1) number of leading ‘1’s followed by a single ‘0’ marker/delimiter end-bit. Note also a total of exactly N number of bit/s pattern is required to represent number N.

Another scheme, among many possible, based on above method to encode/represent/provide/record a sequential list of variable length binary digit numbers is to eg use a single ‘0’ bit to represent 1 consecutive # of bit (all of same binary value), ‘10’ to represent 2 consecutive # of bits, ‘111’ to represent 3 consecutive # of bits, ‘110’ to notify that the consecutive # of bits is now to be ‘extended’ represented by further additional bit/s: as example an occurrence of a further single ‘0’ to now represent 4 consecutive # of bits (cumulative bits pattern here is ‘1100’, which is ‘110’ followed by ‘0’), an occurrence of a further single ‘10’ to now represent 5 consecutive # of bits (cumulative bits pattern here is ‘11010’, which is ‘110’ followed by ‘10’), an occurrence of a further ‘111’ to now represent 6 consecutive # of bits (cumulative bits pattern here is ‘110111’, which is ‘110’ followed by ‘111’), an occurrence of a further ‘110’ to now notify that the consecutive # of bits is now to be ‘extended’ represented by further additional bit/s (cumulative bits pattern here is ‘110110x . . . x’, which is ‘110’ followed by ‘110’ and further followed by the variable length bit/s ‘x . . . x’ to be supplied, eg 7 is to be represented by cumulative bits pattern ‘1101100’, 8 is to be represented by ‘11011010’, 9 is to be represented by ‘110110111’, 10 is to be represented by ‘1101101100’, 11 is to be represented by ‘11011011010’, 12 is to be represented by ‘110110110111’, 16 is to be represented by ‘1101101101101100’ etc and so forth) . . . and so forth. Note here positive integer number N could always be represented in above scheme by Integer[(N−1)/3] number of leading occurrence/s of bits pattern ‘110’ followed by bits pattern corresponding to Remainder representation of {N−Integer[(N−1)/3)]*3} marker/delimiter end-bit/s (ie a single ‘0’ bit to represent Remainder value of 1, ‘10’ bits pattern to represent Remainder value of 2, ‘111’ bits pattern to represent Remainder value of 3). Note also a total of exactly N number of bit/s pattern is required to represent number N here.

Yet another variant scheme, among many possible, based on above method to encode/represent/provide/record a sequential list of variable length binary digit numbers is to eg use a single ‘0’ bit to represent 1 consecutive # of bit (all of same binary value), ‘1’ to notify that the consecutive # of bits is now to be ‘extended’ represented by further additional bit/s: as example an occurrence of a further single ‘0’ to now represent 2 consecutive # of bits (cumulative bits pattern here is ‘10’, which is ‘1’ followed by ‘0’), an occurrence of a further ‘1’ to now notify that the consecutive # of bits is now to be ‘extended’ represented by further additional bit/s (cumulative bits pattern here is ‘11x . . . x’, which is ‘1’ followed by ‘1’ and further followed by the variable length bit/s ‘x . . . x’ to be supplied, eg 3 is to be represented by cumulative bits pattern ‘110’, 4 is to be represented by ‘1110’, 5 is to be represented by ‘11110’, 6 is to be represented by ‘111110’, 7 is to be represented by ‘1111110’, 8 is to be represented by ‘11111110’, 9 is to be represented by ‘111111110’ . . . etc and so forth) . . . and so forth. Note here positive integer number N could always be represented in above scheme by (N−1) number of leading ‘1’s followed by a single ‘0’ marker/delimiter end-bit. Note also a total of exactly N number of bit/s pattern is required to represent number N here.

Note any number representation system/s to be designed here must ensure that each of the ‘symbols’ or number representation ‘bits pattern’ (eg in one of the above system illustrated they are ‘0’ ‘10’ ‘110’ ‘111’) cannot be ‘replicable’ by any combinations of the other ‘symbols’, ie cannot be made to be seen to be ‘present’ in any ‘leading’ portion/‘leading’ substring of any combinations of any number of the other ‘symbols’.

There could be many other representation systems, eg: 0->1 10->2 11-> ‘extend’, ‘swapping 1 & 0 symbols’ from preceding number representation gives 1->1 01->2 00-> extend, or 0->1 11->2 10-> extend, ‘swapping 1 & 0 symbols’ from preceding number representation gives 1->1 00->2 01-> ‘extend’, or 0->1 10->2 111->3 110-> extend, or 1->1 01->2 001->3 000->4 . . . etc. Many schemes/permutations are possible.

Such successive sequential integers representation system could be designed to reduce the maximum consecutive number of bits of all same binary value (all ‘0’s, or ‘1’s) that is present in the resultant ‘Integers File’ (with original binary data file as input), eg representation system 0->1 10->2 111->3 101->‘extend’, or representation system 0->1 11->2 10->‘extend’ could both accomplish this very efficiently, assuming the original input binary file consists predominantly of very large number of consecutive bits of same binary value & there are only very small number of successive sequential adjacent single bits of successively alternating ‘0’ & ‘1’ value in the input original binary file, &/or there are only very small number of successive sequential adjacent 2 consecutive bits of alternating ‘00’ & ‘11’ value in the input binary file, &/or there are only very small number of successive sequential adjacent 3 consecutive bits of alternating ‘000’ & ‘111’ value in the input binary file, &/or also there are very small number of successive sequential adjacent combinations of the preceding various consecutive bits patterns (eg ‘0’ &/or ‘00’ &/or ‘000’, eg ‘1’ &/or ‘11’ &/or ‘111’)

To further reduce the maximum number of consecutive bits all of same binary value in the resultant ‘Integers File’, the representation/recording of the successive sequential consecutive number of bit/s in the original input binary file can successive sequentially ‘alternately’ switch between two selected number representation systems, eg:

alternately switched between
(1) 0->1 11->2 10->extend
&
(2) 1->0 01->2 00 -> extend
OR
Alternately switched between
0->1 10->2 111->3 110->extend
&
1->1 01->2 000->3 001->extend
. . . etc

Note after the stage described above now, such designed successive sequential list of integers representation system (used to successive sequentially record the number of consecutive bits of all same binary value) now always require exactly the same number of bits as the number of consecutive bits of all same binary value, to represent the number of consecutive bits of all same binary value (& never more).

The recording of each & every of the successive sequential number of consecutive bits into an ‘Integers File’ continues until all successive sequential number of bit/s all of same binary value in the original binary data file starting from the very first consecutive bit/s to the very last consecutive bit/s are all individually recorded in the ‘Integers File’. Note successive sequential consecutive bit/s of same binary value ‘switches’ value successive sequentially alternately from ‘1’->‘0’ & ‘0’->‘1’ (between preceding consecutive bit/s all of same binary bit value & the immediately following consecutive bit/s all of same binary bit value).

The number representation/encoding method here will always record/transmit to remote receiver the binary value of the very 1^{st} consecutive number of bit/s ‘0’ or ‘1’ of the very initial 1^{st} original input binary data file (not the binary value of the very 1^{st} consecutive number of bit/s ‘0’ or ‘1’ of the ‘Integers File’ produced from the input original binary data file, also not any of the subsequent iterations' input files) used in the very initial 1^{st} iteration in the ‘unary representation’ process (ie which lossless reconstruction process would attempt to subsequently ‘recreate’ faithfully, not the binary value of the very consecutive number of bit/s ‘0’ or ‘1’ of the final iteration's resultant final ‘Reduced File’: note only the very initial 1^{st} original input binary file input file's very 1^{st} consecutive bit/s' binary value needs be provided, not all the successive iterations' input files’): eg with pre-agreed format to insert/pre-append an ‘extra’ very first single ‘1’ bit or an ‘extra’ very first single ‘0’ bit in eg the very first bit position of the final iteration's resultant ‘Integers File’ to notify that the value of the very first ‘bit’ in the original binary data file as ‘1’ or ‘0’ respectively. The costs here is only 1 single bit for the complete whole ‘unary representation’ process, & could here conveniently be ignored/disregarded in all calculations of encoding efficiencies.

Note it is not necessary to provide/store all the very 1^{st} consecutive bit/s' binary value in each & every of all the iterations' input files! since during each & every of all the lossless reconstruction iterations the reconstruction process at each iteration could simply ‘assume as either 0 or 1’ or even ‘wrongly guess either 0 or 1’ any of the reconstruction iterations' resultant file's very 1^{st} consecutive bit/s' binary value: when all the lossless reconstruction iterations are completed, the final reconstruction iterations' eventual resultant file's very 1^{st} consecutive bit/s' binary value is compared to the provided/stored parameter of the binary value of the very initial 1^{st} original input binary data file, IF both indicates the same binary value then all is fine & the very initial 1^{st} original input binary data file has been losslessly reconstructed faithfully, OTHERWISE each & everyone of all the bits' binary value in the reconstruction iterations' final resultant file will be ‘swapped’/‘switched’ to be of opposite binary value & this will now provide the required lossless faithful reconstruction of the very initial 1^{st} original input binary data file. This is so because each & every of all the ‘unary representation’ process iterations & each & every of all the lossless reconstruction process ‘reverse flow’ iterations here will always produce either a correct resultant file or a ‘correct but reversed bits’ resultant file with each & every bits' having the ‘reversed’ opposite binary value as the correct resultant file.

The above method can ‘always’ losslessly represent the original binary data file into a new ‘Integers File’ of exactly the same size (ignoring the above pre-appended single bit). And if required this process can be performed repeatedly iteratively on the already lossless current ‘Integers File’ to obtain a new ‘Integers File’, UNTIL some criteria is achieved such as eg the maximum consecutive number of bits in the latest new ‘Integers File’ is not more than C. The ‘Integers File’ produced at each iteration then serves as the new input ‘original binary data file’ in the next iteration, to produce resultant new ‘Integers File’. To losslessly reconstruct the original binary data file, various parameters of the ‘unary representation’ process iterations which should at least include the total number of ‘unary representation’ process iterations, and the final ‘Integers File’ (together with the single binary bit parameter recording the starting binary value, either ‘0’ or ‘1’, of the very 1^{st} consecutive bit/s of the very initial 1^{st} original input binary data file used in the very initial 1^{st} iteration in the ‘unary representation’), needs be recorded, provided or transmitted to remote receiver.

Optionally, between any two successive iterations stage the input new original binary data file may further be pre-processed by other existing specified or designed lossless compression methods/algorithms to reduce the file size, before starting the subsequent iterations (this option could eg be recorded or conveyed to receiver using eg 1 or a fixed number of binary bits appended at pre-arranged/ascertained initial bit position/s pre-appended at the beginning or post appended at the end of the recording/transmissions (before or after the ‘Integers File’ &/or other parameters are recorded/transmitted to receiver).

The above-described embodiments merely illustrate the principles of the invention. Those skilled in the art may make various modifications and changes that will embody and fall within the principles of the invention thereof.

```
/**************** OUTLINE REFINED SUMMARY *******************/
    Uses ‘extended’ number representation system/s or various variant schemes of
    ‘extended’ number representation system, where specifically the specific length
    of consecutive bit/s all of same binary value (or successive positive integers) in
    input data file to be compressed could be designed represented by eg 0-> 1 10->2
    11->‘extend’ (ie 11 bits pattern where occurred means one should look to further
    following bit/s pattern to determine the value of the number represented) 110-> 3
    1110->4 1111-> again extend (here ‘11’ follows immediately by ‘11’ means to
    repeat extend) 11110->5 111110->6 111111->repeat extend . . . & so forth ad
    infinitum, OR eg 0-> 1 11->2 10->‘extend’ (ie 10 bits pattern where occurred
    means one should look to further following bit/s pattern to determine the value of
    the number represented) 100-> 3 1011->4 1010-> again extend (here ‘10’
    follows immediately by ‘10’ means to repeat extend) 10100->5 101011->6
    101010->repeat extend . . . & so forth ad infinitum, OR as above but with binary
    values now all switched ie ‘0’ in place of ‘1’ & ‘1’ in place of ‘0’
    OR
    eg 0->1 10->2 110->3 111->extend 1110->4 11110->5 111110->6 111111->
    repeat extend . . . & so forth ad infinitum, OR eg 0->1 10->2 111->3 110->
    extend 1100->4 11010->5 110111->6 110110->repeat extend . . . & so forth
    ad infinitum, OR as above but with binary values now all switched ie ‘0’ in place
    of ‘1’ & ‘1’ in place of ‘0’
    OR
    Similar but with progressively larger number of bits used to represent ‘extend’ eg
    1111 or 1110 (or corresponding ‘switched binary value scheme) ->extend . . . &
    so forth etc . . . similarly schemes with progressively larger number of bits used to
    represent ‘extend’ designed such that none of any of the number representations
    bit/s pattern of any lengths/or any combinations of any number of the number
    representations bit/s pattern of any lengths could form the leading prefix of any of
    the ‘extend’ bits pattern
/********************************** END ********************************/
```

Here is presented a new data compression coding method.

This method (could also be adapted to apply to ternary . . . etc, or to various structure):

examine the original binary data file of arbitrary size sequentially, from starting bit position to end bit position, looking for each successive sequential next earliest occurrences of exact ‘10’ bit patterns (length 2 bits, with a ‘1’ bit follows by a ‘0’ bit), hereinafter refer to as a ‘block’. In the original binary data file a ‘10’ block of length 2 bits may be preceded by a number of consecutive bit/s all of same binary value ‘0’s which in turn may or may not be followed by a number of consecutive ‘1’s bit/s (ie consecutive bit/s of ‘0’s which in turn may or may not be followed by a number of consecutive ‘1’s bit/s, then this present ‘10’ block), or preceded only by a number of consecutive bit/s all of same binary value ‘1’s (ie consecutive bit/s of ‘1’s then this present ‘10’ block), or just preceded by a ‘10’ block (ie this present ‘10’ block does not have any preceding consecutive bit/s of all ‘0’s &/or all ‘1’s, separating this present ‘10’ block & its preceding ‘10’ block). Note there will always be another immediate sequential next earliest occurrence of a ‘10’ block. The very last consecutive bit/s all of same value binary bits in the original binary data file may be just consecutive bit/s of all ‘1’s &/or all ‘0’s (or ‘none’) immediately following the very last ‘10’ block in the original binary data file, thus an ‘artificial’ single bit will always be post-appended/inserted at the very end bit position of the ‘compressed file’ to help notify/indicate whether there are any consecutive bit/s of all ‘0’s &/or all ‘1’s immediately preceding this post-appended/inserted ‘artificial’ single bit (this would increase the total ‘compressed file’ size only by 1 single bit, & this extra 1 single bit costs can justifiably conveniently hereinafter be completely disregarded/ignored in all compression ratio efficiency calculations): setting this post-appended/inserted ‘artificial’ bit to opposite/‘switched’ binary value as the very last recorded single bit's binary value indicates there are no consecutive bit/s of all ‘0’s &/or all ‘1’s whatsoever preceding this ‘artificial’ single bit, setting this post-appended/inserted ‘artificial’ bit to the same binary value as the very last recorded single bit's binary value indicates there are consecutive bit/s of all ‘0’s &/or all ‘1’s preceding this ‘artificial’ bit.

Note the very initial 1^{st} recorded bit in the ‘Compress File’ could be convention pre-arranged to start recording the very initial first occurrence of very 1^{st} ‘10’ block in the input file with eg a single ‘1’ bit to conveniently correctly convey/indicate that the very initial 1^{st} ‘10’ block in the input file has preceding consecutive bit/s of ‘0’s &/or ‘1’s, and to use eg a single ‘0’ bit to conveniently correctly convey/indicate that the very initial 1^{st} ‘10’ block in the input file has preceding consecutive bit/s of ‘1’s. Note this very initial 1^{st} recorded bit does not have an immediately preceding recorded bit to ascertain if it's binary value is different/opposite to an immediately preceding recorded bit's binary value, otherwise would be unable to know if this very 1^{st} recorded bit in the ‘Compress File’ represents ‘10’ block with preceding consecutive bit/s of ‘0’s &/or ‘1’s.

Each of these successive sequential earliest next occurrences of ‘10’ end-delimited blocks is successively sequentially recorded in a new compressed binary data file with just one single ‘1’ binary bit, or one single ‘0’ binary bit, used to record a ‘10’ block (could be pre-arranged to start recording the very initial first occurrence of a ‘10’ block with eg a single ‘1’ bit to indicate there are no consecutive bit/s of all ‘0’s &/or all ‘1’s whatsoever preceding this very initial first ‘10’ block whereas a single ‘0’ indicates there are consecutive bit/s of all ‘0’s &/or all ‘1’s preceding this very initial first ‘10’ block). If there is a ‘10’ block immediately precedent & adjacent to a present ‘10’ block (ie there is no intervening consecutive bit/s of all ‘0’s &/or all ‘1’s between the present ‘10’ block & its immediately precedent adjacent ‘10’ block) then it is ‘switched’ to using just one single binary bit of opposite/‘switched’ binary value to the precedent last recorded single bit's binary value, to record this present ‘10’ block, & if the next earliest occurrence of a ‘10’ block is again immediately adjacent to this latest immediately preceding ‘10’ block (ie there is no intervening consecutive bit/s of all ‘0’s &/or all ‘1’s whatsoever between this present ‘10’ block & its immediately precedent ‘10’ block) then it is again ‘switched’ to using just one single binary bit of opposite/‘switched’ binary value to the precedent last recorded single bit's binary value, to record this present ‘10’ block ie alternatively ‘switched’ using just a single ‘0’ & ‘1’ binary bit to record these successive sequential consecutive immediately adjacent ‘10’ blocks (ie there is no intervening consecutive bit/s of all ‘0’s &/or all ‘1’s whatsoever between any two successive sequential adjacent occurrences of ‘10’ blocks here). Were all blocks in the original binary data file comprises of all 10 blocks each immediately adjacent to its immediately preceding block ie there is no intervening consecutive bit/s of all ‘0’s &/or all ‘1’s whatsoever between any two of the successive sequential occurrences of ‘10’ blocks, then the compressed file will only just consists of successive sequential alternate single ‘0’ bit & single ‘1’ bit, and this would yield lossless compression ratio of 2 (this would also be amenable to further conveniently yield magnitude orders much higher compression ratios by describing the file as bit pattern ‘10’ repeated a number of time via combining using other commonly known compression method/s such as eg run length encoding, LZW . . . etc).

If there is intervening consecutive bit/s of all ‘0’s &/or all ‘1’s preceding a present ‘10’ block, then just one single bit of same binary value as the preceding last recorded single bit value (which may be either ‘0’ or ‘1’) is now used to record this present block. Here we would now see in the compressed file occurrence of two consecutive same value binary bits. Were there again intervening consecutive bit/s of all ‘0’s &/or all ‘1’s preceding the present next earliest occurrence of a ‘10’ block, then just one single bit of same binary value as the preceding latest recorded single bit value (which may be either ‘0’ or ‘1’) is again now used to record this present progressive successive next ‘10’ block. Here we would now see in the compressed file occurrence of three consecutive same value binary bits & so forth. If the progressive successive present next ‘10’ block is not immediately adjacent to an immediately preceding ‘10’ block (ie there are intervening consecutive bit/s of all ‘0’s &/or all ‘1’s between this present next ‘10’ block & the immediately preceding ‘10’ block) then it is ‘switched’ to using just one single binary bit (which is to be of same binary value to the preceding latest single recorded bit value) to record this present ‘10’ block.

Thus it can be readily seen that if a single bit's binary value in the new ‘compressed file’ is ‘switched’/‘changed’ from the immediately preceding single bit's binary value, it represents one present ‘10’ block with no intervening consecutive bit/s of all ‘0’s &/or all ‘1’s between this present block and the immediately preceding ‘10’ block in the original binary data file (thus achieving compression ratio of 2) and does not require any further additional information whatsoever to be losslessly reconstructed.

It can also readily be seen that successive sequence of recorded bits of all same binary value (ie sequence of bits all of ‘non-alternating’ same binary value, beginning from the first ‘non-alternating’ ‘non-switched’ binary value bit (ignoring, not including the immediately preceding recorded bit which has last ‘switched’ value but is necessarily also of the same binary value as this present successive sequence's all same binary value)) represents successive sequences of ‘10’ blocks each of which has preceding consecutive bits of all ‘0’s &/or all ‘1’s, & would requires further additional information (about whether there are further consecutive all 0 bit/s &/or consecutive all ‘1’ bit/s immediately preceding each of the ‘10’ blocks, and the total number of each of the consecutive all ‘1’ &/or consecutive all ‘0’ bits which immediately precedes the ‘10’ blocks) to be able to losslessly reconstruct the corresponding bit patterns in the original binary data file.

Note the successive sequence all of ‘non-alternating’ same binary value here may consist of any number of bits, from 1 to any number.

Next, in a ‘first pass’ stage which uses as input the ‘Compressed File’ & also references the original binary data file, the compression process here steps successive sequentially through each of the single bit in the ‘Compressed File’ which represents ‘10’ blocks which has further additional consecutive ‘0’ bit/s &/or ‘1’ bit/s immediately preceding it as is the original binary data file (these ‘10’ blocks with either further additional consecutive ‘0’ &/or consecutive ‘1’ bit/s immediately preceding it are represented in the new ‘compressed file’ as ‘non-alternating’ ‘non-switched’ single binary value bit/s with same binary value as the immediately preceding ‘compressed’ bit value (ignoring, not including the immediately preceding bit which has last ‘switched’ value but is necessarily also of the same binary value as the present successive sequence's single bit/s of all same binary value)), and record in a new ‘First Pass’ binary data file whether a number of consecutive ‘0’ bit/s now immediately precedes the present ‘10’ block, or a number of consecutive ‘1’ bit/s now immediately precedes the present ‘10’ block: using a single ‘0’ bit to indicate a number of consecutive ‘0’ bit/s immediately precedes the present ‘10’ block (it may be that consecutive bit/s of all ‘1’s in turn may follow the consecutive bit/s of all ‘0’s, ie in original binary data file there are bits pattern of consecutive bit/s of ‘0’s then consecutive bit/s of ‘1’s then this present ‘10’ block: this scenario will be dealt with later in the Description body), & using a single ‘1’ bit to indicate only a number of consecutive ‘1’ bit/s immediately precedes the present ‘10’ block (here there will always not be any consecutive ‘0’s in turn following the consecutive bit/s of all ‘1’s !). Thus in addition to the new ‘Compressed File’ with successive sequential single binary bit of either ‘0’ or ‘1’ (some alternatingly ‘switches’ to opposite value from the immediately preceding compressed bit's binary value ie to represent ‘10’ blocks with no intervening preceding consecutive bit/s whatsoever between the present ‘10’ block & the preceding ‘10’ block, & some with same binary value as the immediately preceding compressed bit's binary value ie to indicate there is intervening consecutive bit/s of all ‘0’s &/or all 1's between the present ‘10’ block and the preceding ‘10’ block), we now also have a new ‘First Pass File’ of individual single bits which indicates whether a number of consecutive ‘0’ bit/s which in turn may or may not be followed by a number of consecutive ‘1’ bit/s, or only just a number of consecutive ‘1’ bit/s, now immediately precedes the present ‘10’ block, represented in the ‘First Pass File’ as a single ‘0’ bit if the intervening consecutive bit/s are all ‘0’s which in turn may or may not be followed by consecutive bit/s of all ‘1’s, & represented in the ‘First Pass File’ as a single ‘1’ bit if the intervening consecutive bit/s are only all

Note this ‘First Pass’ stage will only successively step through all single ‘non-alternating’ ‘non-switched’ binary bit/s in the ‘Compressed File (completely skipping all single alternating ‘switched’ single bit/s in the ‘Compressed File’) ie which correspond to a ‘10’ block in the original binary data file which has intervening consecutive bit/s of all ‘0’s &/or all ‘1’s preceding the present ‘10’ block. Note also each of these single bit of either ‘0’ or ‘1’ in the ‘First Pass File’ in addition to indicating whether the consecutive bit/s are all ‘0’s (which in turn may or may not be followed by consecutive bit/s of all ‘1’s) or just consecutive bit/s of only all ‘1’s, also incidentally indicates there is at least 1 consecutive bit of ‘0’ or ‘1’ preceding a particular ‘10’ block. Note the total number of all such single ‘non-alternating’ ‘non-switched’ binary bit/s in the ‘Compressed File is always less than or in very worst equal to the total number of all single bits in the ‘Compressed File’: statistically it usually should be around half the total number of all single bits in the ‘Compressed File’. The total number of individual single binary bits in the ‘First Pass File’ is always less than or at the very worst equal to the total number of individual single binary bits in the ‘Compressed File’: statistically it usually should be around half the total number of individual single binary bits in the ‘Compressed File’.

Next, the compression process goes through a ‘second pass’ stage, which uses as input the ‘First Pass’ binary data file (also referencing the earlier ‘Compressed File’ & original data file) & produces as output a new ‘Second Pass File’ binary data file of individual single bits:

it steps through successive sequentially each of the individual single bits in the ‘First Pass’ binary data file to record into the new ‘Second Pass File’ a single ‘0’ bit if the number of consecutive bits of either ‘0’s or ‘1’s (indicated by individual single bit's binary value in the ‘First Pass File) preceding the corresponding ‘10’ block in the original binary data file is exactly 1 (thereafter during each subsequent ‘pass’ there is no further need to further process these ‘10’ blocks ie no further needs to record any increase of by 1 the total number of consecutive bits of all same binary value which immediately precedes the corresponding ‘10’ block in the original binary data file), or record a single ‘1’ bit if the number of consecutive bits of either ‘0’s or ‘1’s (indicated by individual single bit's binary value in the ‘First Pass File) preceding the corresponding ‘10’ block in the original binary data file is at least 2 or more.

Note the binary value ‘0’ or ‘1’ of these consecutive number of all same binary value bits is already provided in the earlier ‘First Pass File’. Note also the total number of all the individual single binary bits in the ‘Second Pass File’ is always exactly the same as the total number of all individual bits in the ‘First Pass File’.

Repetitively next, the compression process goes through a ‘third pass’ stage, which uses as input the ‘Second Pass’ binary data file (also referencing the earlier ‘Compressed File’ & original binary data file & ‘First Pass File’) & produces as output a new ‘Third Pass File’ binary data file of individual single bits: it steps through successive sequentially each of the individual single bits in the ‘Second Pass’ binary data file to record into the new ‘Third Pass File’ a single ‘0’ bit if the number of consecutive bits of either ‘0’s or ‘1’s (indicated by individual single bit's binary value in the ‘First Pass File) preceding the corresponding ‘10’ block in the original binary data file is exactly 2 (thereafter during each subsequent ‘pass’ there is no further need to further process these ‘10’ blocks ie no further needs to record any increase of by 1 the total number of consecutive bits of all same binary value which immediately precedes the corresponding ‘10’ block in the original binary data file), or record a single ‘1’ bit if the number of consecutive bits of either ‘0’s or ‘1’s (indicated by individual single bit's binary value in the ‘First Pass File) preceding the corresponding ‘10’ block in the original binary data file is at least 3 or more.

Note the binary value ‘0’ or ‘1’ of these consecutive number of all same binary value bits is already provided in the earlier ‘First Pass File’. Note also the total number of all the individual binary bits in the ‘Third Pass File’ is always less than or at the very worst equal to the total number of all individual bits in the ‘Second Pass File’, & in all subsequent Nth Pass the total number of all the individual binary bits in the ‘N Pass File’ is always less than or at the very worst equal to the total number of all individual bits in the ‘N−1 Pass File’

Again & again . . . & so forth . . . repetitively next, the compression process goes through an Nth pass stage, which uses as input the ‘N−1 Pass’ binary data file (also referencing the earlier ‘Compressed File’ & original binary data file & ‘First Pass File’ to ‘N−2 Pass File) & produces as output a new ‘N Pass File’ binary data file of individual single bits:

it steps through successive sequentially each of the individual single bits in the ‘N−1 Pass’ binary data file to record into the new ‘N Pass File’ a single ‘0’ bit if the number of consecutive bits of either ‘0’s or ‘1’s (indicated by individual single bit's binary value in the ‘First Pass File) preceding the corresponding ‘10’ block in the original binary data file is exactly N−1 (thereafter during each subsequent ‘pass’ there is no further need to further process these ‘10’ blocks ie no further needs to record any increase of by 1 the total number of consecutive bits of all same binary value which immediately precedes the corresponding ‘10’ block in the original binary data file), or record a single ‘1’ bit if the number of consecutive bits of either ‘0’s or ‘1’s (indicated by individual single bit's binary value in the ‘First Pass File) preceding the corresponding ‘10’ block in the original binary data file is at least N or more.

Note in the very latest pass (ie with N=total number of all ‘Passes’ so far), if there would not be any number of consecutive bits of all same binary value greater than N preceding any of the corresponding ‘10’ blocks in the original binary data file, then there is no further need to proceed onto further subsequent N+1 pass. It is obvious, or can be inferred, that all ‘10’ blocks with a single ‘1’ bit recorded in the final last ‘N Pass File’ indeed all have exactly N consecutive bits of all same binary value.

Note the binary value ‘0’ or ‘1’ of these consecutive number of all same binary value bits is already provided in the earlier ‘First Pass File’. Note also the total number of all the individual binary bits in the ‘N Pass File’ is always less than or in the very worst case equal to the total number of all individual bits in the ‘N−1 Pass File’, statistically it usually should be around half the total number of individual single binary bits in the ‘N−1 Pass File’.

Now at this stage of compression process reached, we have completely ‘encoded’ all the ‘10’ blocks in the original binary data file & whether or not there are any consecutive bit/s of ‘0’s or ‘1’s preceding each of the ‘10’ blocks (recorded in ‘compressed file’), if so whether the consecutive bit/s preceding a particular ‘10’ block is all of binary value ‘0’s or ‘1’s (recorded in ‘First Pass File’), & the ‘total’ number of consecutive bit/s of either ‘0’s or ‘1’s preceding a particular ‘10’ block (recorded in ‘Second Pass File’ to ‘N Pass File’). But if the consecutive bit/s preceding a particular ‘10’ block had been notified to be of binary value ‘0’s (from the ‘First Pass File’), then in turn there may or may not possibly be consecutive bit/s of all ‘1’s which may follow the consecutive bit/s of all ‘1’s: this needs to ‘encoded’ before lossless reconstructions could be achieved.

The compression process now takes as input the ‘First Pass File’ (also referencing original binary data file & ‘Compress File’ & ‘First Pass File’ to ‘N Pass File’) & successive sequentially steps through each of the single ‘0’ bit skipping all the single ‘1’ bit in the input ‘First Pass File’ (ie successive sequentially stepping through only those corresponding ‘10’ blocks with preceding consecutive ‘0’ bit/s, statistically the total number of single ‘0’ bit in the ‘First Pass File’ should be around half of the total number of all single bit of ‘0’ or ‘1’ in the ‘First Pass File’), record a single ‘0’ bit in a new ‘First Extra1 Pass File’ if there is no consecutive ‘1’ bit/s which follows the consecutive ‘0’ bit/s & record a single ‘1’ bit in a new ‘First Extra1 Pass File’ if there is at least 1 or more consecutive ‘1’ bit/s which follows the consecutive ‘0’ bit/s. Note the total number of single bits of either ‘0’ or ‘1’ in the ‘First Extra1 Pass File’ is always less than or at worst equal to the total number of single bits in the ‘First Pass File.

Next the compression process proceeds onto ‘Second Extra1 Pass’ using as input the earlier ‘First Extra1 File’ (also referencing original binary data file & ‘Compress File’ & ‘First Pass File’ to ‘N Pass File’ & ‘First Extra1 Pass), stepping successively sequentially through each single ‘1’ bit in the ‘First Extra1 File’ (ie only those corresponding ‘10’ blocks in the original binary data file with at least 1 or more consecutive ‘1’ bit/s following consecutive ‘0’ bit/s, & completely skipping all single ‘0’ bit in the ‘First Extra1 Pass File’) recording a single ‘0’ bit in the new ‘Second Extra1 File’ if there is only exactly 1 consecutive ‘1’ bit following consecutive ‘0’ bit/s, & recording a single ‘1’ bit in the new ‘Second Extra1 File’ if there is at least 2 or more consecutive ‘1’ bits following consecutive ‘0’ bit/s.

Again next the compression process proceeds onto ‘Third Extra1 Pass’ using as input the earlier ‘Second Extra1 File’ (also referencing original binary data file & ‘Compress File’ & ‘First Pass File’ to ‘N Pass File’ & ‘First Extra1 Pass’ to ‘Second Extra1 Pass File’), stepping successively sequentially through each single ‘1’ bit in the ‘Second Extra1 File’ (ie only those corresponding ‘10’ blocks with at least 2 or more consecutive ‘1’ bit/s following consecutive ‘0’ bit/s in the original binary data file, & completely skipping all single ‘0’ bit in the ‘Second Extra1 Pass File’) recording a single ‘0’ bit in the new ‘Second Extra1 File’ if there is only exactly 2 consecutive ‘1’ bits following consecutive ‘0’ bit/s, & recording a single ‘1’ bit in the new ‘Second Extra1 File’ if there is at least 3 or more consecutive ‘1’ bits following consecutive ‘0’ bit/s & so forth.

At M Extra1 Pass, compression process proceeds onto ‘M Extra1 Pass’ using as input the earlier ‘M−1 Extra1 File’ (also referencing original binary data file & ‘Compress File’ & ‘First Pass File’ to ‘N Pass File’ & ‘First Extra1 Pass File’ to ‘M−2 Extra1 Pass File’), stepping successively sequentially through each single ‘1’ bit in the ‘M−1 Extra1 File’ (ie only those corresponding ‘10’ blocks with preceding at least M or more consecutive ‘1’ bit/s following consecutive ‘0’ bit/s in the original binary data file, & completely skipping all single ‘0’ bit in the ‘M−1 Extra1 Pass File’) recording a single ‘0’ bit in the new ‘M Extra1 File’ if there is only exactly M consecutive ‘1’ bits following consecutive ‘0’ bit/s & recording a single ‘1’ bit in the new ‘M Extra1 File’ if there is at least M+1 or more consecutive ‘1’ bits following consecutive ‘0’ bit/s

Note in the very latest pass (ie with M=total number of all ‘Passes’ so far), if there would not be any number of consecutive bits of all same binary value greater than M preceding any of the corresponding ‘10’ blocks in the original binary data file, then there is no further need to proceed onto further subsequent M+1 pass. It is obvious, or can be inferred, that all ‘10’ blocks with a single ‘1’ bit recorded in the final last ‘M Pass File’ indeed all have exactly M consecutive bits of all same binary value.

The original binary data file can thus always now be losslessly reconstructed from these ‘Compressed File’ & (if any) ‘1^{st} Pass File’ to ‘N Pass File’ & (if any) ‘1^{st} Extra 1 Pass File’ to ‘M Extra1 Pass File’, together with the various very small number of parameters of the whole complete compression process iterations which should at least include the number of Pass Files N, the number of Extra1 Pass Files M, the single ‘artificial’ bit value (if not already post-appended to the resultant ‘Compress File’).

All of these files ‘Compressed File’ & (if any) 1^{st} Pass File to ‘N Pass File’ & (if any) ‘1^{st} Extra1 Pass File’ to ‘M Extra1 Pass File’ may also if required be merged as a single file & transmitted to remote receiver, together with various parameters of the whole complete compression process iterations which should at least include the single ‘artificial’ bit value (if not already post-appended to the resultant ‘Compress File’), N the number of Pass Files & M the number of Extra1 Pass Files (from which the total Passes N & total Extra1 Passes M are conveyed) & the sizes of each files in the same respective order at which they are merged, to be separately transmitted to remote receiver (in pre-arranged/pre-agreed protocol &/or fixed format) to enable lossless reconstructions. All the various parameters above could also be eg pre-appended to the above merged file at pre-defined/pre-agreed initial bit position/s or byte/s position/s &/or particular fixed format/syntax (instead of separately transmitting these parameters to remote receiver), thus there is now a just a single file to be transmitted.

Further any of these individual files, or the single merged file could again be used as new ‘original binary data file to be processed anew to produced new Compressed File’ & a number of new Pass Files & a number of new Extra1 Pass Files, together with the parameters of this latest compression process (which should also now include the total number of ‘compressions iterations anew’ parameter) to enable lossless reconstruction of the very 1st initial original binary data file: all these files above, &/or together with the parameters (which should now further include a new parameter of the total number of ‘compressions iterations anew’), could then be merged into a latest new single merged file from which the very 1^{st} initial original binary data file could be losslessly reconstructed . . . this latest new single merged file could iteratively repetitively again be used as another latest new ‘original binary data file’ to be processed anew/compression iterations anew . . . & so forth, achieving very large lossless compression ratio.

Optionally, between any two successive Passes &/or Extra1 Passes &/or ‘compression iterations anew’ stage the input new ‘compressed file’ &/or the input latest ‘Pass File’ &/or the input latest ‘Extra1 Pass File’ may further be pre-processed by other specified lossless compression methods/algorithms to enable further reductions of the file size by the other ‘conveyed’ algorithm/s &/or enable subsequent reductions of the resultant file size by this compression process (eg to first pre-process to reduce or increase the maximum run-length of consecutive bits, or to ‘flip’ all ‘0’ bits to ‘1’ bits & all ‘1’ bits to ‘0’ bits in the input file (if doing so provides better compression ratio), or to ‘jumble’ the bits in the input file mapping each present bit to some other pre-agreed bit positions (could even generate a small integer random numbers set to randomly select the pre-agreed ‘bits transposition mapping method), or to take advantage of pre-dominant repetitive patterns that exists in the input file eg very pre-dominantly large number of successive consecutive alternately ‘1’ bit & ‘0’ bit or very pre-dominantly large number of successive same bits patterns . . . etc). Compression process could optionally evaluate some or all of the possible various pre-agreed algorithms to choose the one that yields a good compression ratio. This algorithm selection option at each passes &/or iterations could eg be recorded or conveyed to receiver in a separate parameters file of pre-agreed protocol/fixed format/pre-agreed syntax, or using a number of eg 1 or a fixed number of binary bits appended at pre-arranged/ascertained initial beginning bit position/s to convey algorithms option selection parameters corresponding to each ‘passes’ &/or ‘compression iterations anew’ stages, which may pre-appended within the single merged file to be transmitted to remote receiver.

Note the recording convention of the meanings of single bit of ‘0’ or ‘1’ (into ‘compression file’ & ‘Pass Files’ &/or ‘Extra1 Pass Files’ &/or ‘parameters file’ . . . etc) could always be ‘swapped’, so ‘1’ now has the meaning of ‘0’ used previously & ‘0’ now has the meaning of ‘1’ used previously. The block's bits patterns ‘01’ may be used instead of existing block's bits pattern of ‘10’. And the number representation system could be varied where required eg 0->1 10->2 110->3 111->‘extend’ could be varied to now be 0->0 10->1 111->2 110->‘extend’ . . . etc.

This new compression method uses only individual single bit of ‘0’ or ‘1’ throughout, without use of any kind/designed sets of ‘binary number representations’. It first notes the defined ‘transitions’ nodes (from ‘1’ to ‘0’, or could also alternatively be from ‘0’ to ‘1’) within the original binary data file representing these blocks of ‘10’ bits pattern (there could be various other possible bit patterns representing the transitions eg ‘01’, or using both ‘10’ & ‘01’ together, or even using bit patterns of a variable number of consecutive ‘1’ bit/s follows by a variable number of consecutive ‘0’ bit/s . . . etc), and record them as either single ‘0’ or ‘1’ bit. The binary value of the successive next single bit recorded could either ‘switched’ or remains the same from the preceding latest recorded single bit's binary value, to convey desired information. The number of consecutive bit/s preceding a particular single bit (or transition nodes) is recorded via successive passes each pass successive sequentially stepping through only single ‘1’ bits completely skipping all ‘0’ bits in the previous recorded ‘Pass File’

/********************** OUTLINE REFINED SUMMARY *******************/

| | |
|---|---|
| 1. | Methods or sub-component method step/s for lossless data compressions, said |
| | methods or sub-component method step/s here: |
| | Examine input binary data file sequentially looking for each successive |
| | sequential next earliest occurrence of exact ‘10’ bits pattern (length 2 bits, with |
| | ‘1’ bit followed by a ‘0’ bit), this ‘10’ end-delimited block may be preceded by a |
| | number of consecutive bit/s all of same binary value ‘0’s which in turn may or |
| | may not be followed by a number of consecutive bit/s all of same binary value |
| | ‘1’s OR just preceded by a number of consecutive bit/s all of same binary value |
| | ‘1’s OR just preceded by a previous ‘10’ block: |
| | each of these successive sequential earliest next occurrence of ‘10’ end-delimited |
| | block is successively sequentially recorded/represented in a new binary |
| | ‘Compress File’ with a single ‘1’ binary bit (or a single ‘0’ bit) used to record a |
| | ‘10’ end-delimited block, OPTIONALLY could be pre-arranged to start the |
| | recording of the very 1^{st} ‘10’ end-delimited block with a single ‘1’ (alternatively a |
| | single ‘0’) binary bit to indicate there are no consecutive bit/s whatsoever |
| | preceding the very initial 1^{st} ‘10’ block WHEREAS with a single ‘0’ |
| | (alternatively a single ‘1’) binary bit to indicate there are a number of consecutive |
| | bit/s of all ‘0’/s or all ‘0’/s followed by all ‘1’/s or all ‘1’/s only preceding |
| | this very initial 1^{st} ‘10’ block |
| | IF there is a ‘10’ block immediately preceding & adjacent to a present ‘10’ |
| | block (ie there is no other intervening consecutive bits) then it is switched to |
| | using just a single binary bit of opposite/‘switched’ binary value to the preceding |
| | last recorded single bit's binary value to record this present ‘10’ block into the |
| | binary ‘Compress File’ |
| | AND if there is other intervening consecutive bit/s then just use one single bit of |
| | same binary value as the preceding last recorded single bit's binary value to |
| | record this present ‘10’ block into the binary ‘Compress File’. |
| | The very last consecutive bit/s all of same value binary bits in the input binary |
| | data file may be just consecutive bit/s of all ‘0’/s or all ‘0’/s followed by all |
| | ‘1’/s or just all ‘1’/s (or ‘none’ whatsoever) immediately following the |
| | very last ‘10’ block in the original binary data file, thus an ‘artificial’ single bit |
| | will always be post-appended/inserted at the very end bit position of the |
| | ‘compressed file’ to help notify/indicate whether there are any consecutive |
| | bit/s of all ‘0’s &/or all ‘1’s immediately preceding this post-appended/ |
| | inserted ‘artificial’ single: setting this post-appended/inserted ‘artificial’ bit |
| | to opposite/‘switched’ binary value as the very last recorded single bit's binary |
| | value indicates there are no consecutive bit/s of all ‘0’s &/or all ‘1’s whatsoever |
| | preceding this ‘artificial’ single bit, setting this post-appended/inserted |
| | ‘artificial’ bit to the same binary value as the very last recorded single bit's |
| | binary value indicates there are consecutive bit/s of all ‘0’s &/or all ‘1’s |
| | preceding this ‘artificial’ bit. |
| 2. | Methods or sub-component method step/s for lossless data compressions, said |
| | methods or sub-component method step/s |
| | here NEXT FURTHER: |
| | Next in a ‘1^{st} Pass’ stage uses as input the ‘Compress File’ & also references |
| | the very 1^{st} initial original binary input file, compression process here steps |
| | successive sequentially through each of the single bit in the ‘Compress File’ |
| | representing ‘10’ end-delimited blocks in the very 1^{st} initial original binary |
| | input file which has additional further consecutive bit/s immediately |
| | preceding the ‘10’ end-delimiter as in the very 1^{st} initial original binary input |
| | file, and record in a new ‘1^{st} Pass’ binary file using a single ‘0’ bit |
| | (alternatively a single ‘1’ bit) to indicate IF number of consecutive bit/s |
| | all of same binary value ‘0’s (which further may or may not be followed by |
| | consecutive bit/s all of same binary value ‘1’s) immediately precedes this |
| | present ‘10’ end-delimited block OTHERWISE using single ‘1’ bit |
| | (alternatively a single ‘0’ bit) to indicate only consecutive bit/s all of same |
| | binary ‘1’s immediately precedes this present ‘10’ |
| | end-delimited block. |
| | Next again the compression process goes through a ‘2^{nd} Pass’ stage using as |
| | input the ‘1^{st} Pass’ binary file above (also referencing earlier binary |
| | ‘Compress File’ & very 1^{st} initial original binary input file) & produces a |
| | binary ‘2^{nd} Pass’ file consisting of individual single bits: |

it steps through successive sequentially each of the individual single bits in the
‘First Pass’ binary data file to record into the new ‘Second Pass File’ a single ‘0’ bit
(alternative a single ‘1’ bit) if the number of consecutive bits of either ‘0’s or ‘1’s
(binary value of which indicated by individual single bit's binary value in the ‘First
Pass File) preceding the corresponding ‘10’ block in the original binary data file is
exactly 1 (thereafter during each subsequent ‘pass’ there is no further need to further
process these ‘10’ blocks ie no further needs to record any increase of by 1 the total
number of consecutive bits of all same binary value which immediately precedes the
corresponding ‘10’ block in the original binary data file), or record a single ‘1’ bit
(corresponding alternatively a single ‘0’ bit) if the number of consecutive bits of either
‘0’s or ‘1’s (indicated by individual single bit's binary value in the ‘First Pass File)
preceding the corresponding ‘10’ block in the original binary data file is at least 2 or
more.

Repetitively next, the compression process goes through a ‘third pass’ stage,
which uses as input the ‘Second Pass’ binary data file (also referencing the
earlier ‘Compressed File’ & original binary data file & ‘First Pass File’ & ‘2^{nd}
Pass File) &
produces as output a new ‘Third Pass File’ binary data file of individual single
bits:

it steps through successive sequentially each of the individual single bits in the
‘Second Pass’ binary data file to record into the new ‘Third Pass File’ a single ‘0’
bit (alternative a single ‘1’ bit) if the number of consecutive bits of either ‘0’s or ‘1’s
(binary value of which indicated by individual single bit's binary value in the ‘First
Pass File) preceding the corresponding ‘10’ block in the original binary data file is
exactly 2 (thereafter during each subsequent ‘pass’ there is no further need to further
process these ‘10’ blocks ie no further needs to record any increase of by 1 the total
number of consecutive bits of all same binary value which immediately precedes the
corresponding ‘10’ block in the original binary data file), or record a single ‘1’ bit
(corresponding alternatively a single ‘0’ bit) if the number of consecutive bits of either
‘0’s or ‘1’s (binary value of which indicated by individual single bit's binary value in
the ‘First Pass File) preceding the corresponding ‘10’ block in the very 1^{st} initial
original binary data file is at least 3 or more.

Again & again . . . & so forth . . . repetitively next, the compression process
goes through an ‘Nth pass’ stage, which uses as input the ‘N − 1 Pass’ binary
data file (also referencing the earlier ‘Compressed File’ & original binary data
file & ‘First Pass File’ to ‘N − 2 Pass File) & produces as output a new ‘N Pass
File’ binary data file of individual single bits:

it steps through successive sequentially each of the individual single bits in the ‘N − 1
Pass’ binary data file to record into the new ‘N Pass File’ a single ‘0’ bit
(alternatively a single ‘1’ bit) if the number of consecutive bits of either ‘0’s or ‘1’s
(binary value of which indicated by individual single bit's binary value in the ‘First
Pass File) preceding the corresponding ‘10’ block in the original binary data file is
exactly N − 1 (thereafter during each subsequent ‘pass’ there is no further need to
further process these ‘10’ blocks ie no further needs to record any increase of by 1
the total number of consecutive bits of all same binary value which immediately
precedes the corresponding ‘10’ block in the original binary data file), or record a
single ‘1’ bit (alternatively a single ‘0’ bit) if the number of consecutive bits of
either ‘0’s or ‘1’s (binary value of which indicated by individual single bit's binary
value in the ‘First Pass File) preceding the corresponding ‘10’ block in the original
binary data file is at least N or more:
Note in the very latest pass (ie with N = total number of all ‘Passes’ so far), if there
would not be any number of consecutive bits of all same binary value greater than N
preceding any of the corresponding ‘10’blocks in the original binary data file, then
there is no further need to proceed onto further subsequent N + 1 pass, it is obvious,
or can be inferred that all ‘10’ blocks with a single ‘1’ bit recorded in the final last ‘N
Pass File’ indeed all have exactly N consecutive bits of all same binary value.

The compression process now takes as input the ‘First Pass File’ (also
referencing original binary data file & ‘Compress File’ & ‘First Pass File’ to
‘N Pass File’) & successive sequentially steps through each of the single ‘0’ bit
skipping all the single ‘1’ bit in the input ‘First Pass File’ (ie successive
sequentially stepping through only those corresponding ‘10’ blocks with
preceding consecutive ‘0’ bit/s), record a single ‘0’ bit (alternatively a single
‘1’ bit) in a new ‘First Extra1 Pass File’ if there is no consecutive ‘1’ bit/s which
follows the consecutive ‘0’ bit/s & record a single ‘1’ bit (corresponding
alternatively a single ‘0’ bit) in a new ‘First Extra1 Pass File’ if there is at least 1
or more consecutive ‘1’ bit/s which follows the consecutive ‘0’ bit/s
Next the compression process proceeds onto ‘Second Extra1 Pass’ using as
input the earlier ‘First Extra1 File’ (also referencing original binary data file &
‘Compress File’ & ‘First Pass File’ to ‘N Pass File’ & ‘First Extra1 Pass),
stepping successively sequentially through each single ‘1’ bit in the ‘First
Extra1 File’ (ie only those corresponding ‘10’ blocks in the original binary data
file with at least 1 or more consecutive ‘1’ bit/s following consecutive ‘0’bit/s,
& completely skipping all single ‘0’ bit in the ‘First Extra1 Pass File’) recording
a single ‘0’ bit (alternatively a single ‘1’ bit) in the new ‘Second Extra1 File’ if
there is only exactly 1 consecutive ‘1’ bit following consecutive ‘0’
bit/s, & recording a single ‘1’ bit (corresponding alternatively a single ‘0’ bit)
in the new ‘Second Extra1 File’ if there is at least 2 or more consecutive ‘1’
bits following consecutive ‘0’ bit/s.
Again next the compression process proceeds onto ‘Third Extra1 Pass’ using as
input the earlier ‘Second Extra1 File’ (also referencing original binary data file
& ‘Compress File’ & ‘First Pass File’ to ‘N Pass File’ & ‘First Extra1 Pass’
to ‘Second Extra1 Pass File’), stepping successively sequentially through
each single ‘1’ bit in the ‘Second Extra1 File’ (ie only those corresponding ‘10’
blocks with at least 2 or more consecutive ‘1’ bit/s following consecutive
‘0’bit/s in the original binary data file, & completely skipping all single ‘0’ bit in
the ‘Second Extra1 Pass File’) recording a single ‘0’ bit (alternatively a single
‘1’ bit) in the new ‘Second Extra1 File’ if there is only exactly 2 consecutive
‘1’ bits following consecutive ‘0’ bit/s, & recording a single ‘1’ bit
(corresponding alternatively a single ‘0’ bit) in the new ‘Second Extra1 File’ if
there is at least 3 or more consecutive ‘1’ bits following consecutive ‘0’
bit/s . . . & so forth.
At M Extra1 Pass, compression process proceeds onto ‘M Extra1 Pass’ using
as input the earlier ‘M − 1 Extra1 File’ (also referencing original binary data
file & ‘Compress File’ & ‘First Pass File’ to ‘N Pass File’ & ‘First Extra1
Pass File’ to ‘M − 2 Extra1 Pass File’), stepping successively sequentially
through each single ‘1’ bit in the ‘M − 1 Extra1 File’ (ie only those
corresponding ‘10’ blocks with preceding at least M or more consecutive ‘1’
bit/s following consecutive ‘0’bit/s in the original binary data file, &
completely skipping all single ‘0’ bit in the ‘M − 1 Extra1 Pass File’) recording
a single ‘0’ bit (alternatively a single ‘1’ bit) in the new ‘M Extra1 File’ if
there is only exactly M consecutive ‘1’ bits following consecutive ‘0’ bit/s &
recording a single ‘1’ bit (corresponding alternatively a single ‘0’ bit)
in the new ‘M Extra1 File’ if there is at least M + 1 or more consecutive ‘1’
bits following consecutive ‘0’ bit/s:
Note in the very latest pass (ie with M = total number of all ‘Passes’ so far),
if there would not be any number of consecutive bits of all same binary
value greater than M preceding any of the corresponding ‘10’blocks in the
original binary data file, then there is no further need to proceed onto further
subsequent M + 1 pass, it is obvious or can be inferred that all ‘10’ blocks
with a single ‘1’ bit recorded in the final last ‘M Pass File’ indeed all have
exactly M consecutive bits of all same binary value.
Methods or sub-component method step/s for lossless reconstruction of
compressed data, said methods or sub-
component method step/s here:

Accept as input from these ‘Compressed File’ & (if any) ‘1^{st} Pass File’ to ‘N Pass
File’ & (if any) ‘1^{st} Extra 1Pass File’ to ‘M Extra1 Pass File’, together with the
various very small number of parameters of the whole complete compression process
iterations which should at least include the number of Pass Files N, the number of
Extra1 Pass Files M, the single ‘artificial’ bit value (if not already post-appended to
the resultant ‘Compress File’).
OPTIONALLY All of these files ‘Compressed File’ & (if any) ‘1^{st} Pass File’ to
‘N Pass File’ & (if any) ‘1^{st} Extra1 Pass File’ to ‘M Extra1 Pass File’ are merged as a
single, together with various parameters of the whole complete compression process
iterations which should at least include the single ‘artificial’ bit value (if not
already post-appended to the resultant ‘Compress File’), N the number of Pass Files
& M the number of Extra1 Pass Files (from which the total Passes N & total Extra1
Passes M are conveyed) & the sizes of each files in the same respective order at
which they are merged (in pre-arranged/pre-agreed protocol &/or fixed format) to
enable lossless reconstructions:
OPTIONALLY All the various parameters above could also be eg pre-appended to
the above merged file at pre-defined/pre-agreed initial bit position/s or byte/s
position/s &/or particular fixed format/syntax thus there is now a just a single file
OPTIONALLY any of these individual files, or the single merged file could again
be used as new ‘original binary data file’ to be processed anew to produced new
‘Compressed File’ & a number of new Pass Files & a number of new Extra1 Pass
Files, together with the parameters of this latest compression process (which should
also now include the total number of ‘compressions iterations anew’ parameter) to
enable lossless reconstruction of the very 1st initial original binary data file: all these
files above, &/or together with the parameters (which should now further include a
new parameter of the total number of ‘compressions iterations anew’), could then be
merged into a latest new single merged file from which the very 1^{st} initial original
binary data file could be losslessly reconstructed . . . this latest new single
merged file could iteratively repetitively again be used as another latest new ‘original
binary data file’ to be processed anew/compression iterations anew . . . & so
forth, achieving very large lossless compression ratio.
/******************************* END **********************************/

Another variant implementation of the compression technique principles for lossless compression here would be to (in outline only):
1. Successive sequential record in Compress File using a single ‘0’ or ‘1’ bit each next earliest possible occurrence of ‘10’ block in the original binary data file, in manner as described in earlier implementation above (successive bit's binary value alternately ‘switched, or remain same as preceding latest recorded bit's binary value).
2. Successive sequentially stepping through each of the ‘non-alternating’ ‘non-switched’ single bit in the ‘Compress File’ (completely ignoring/skipping all the alternating ‘switched’ single bit) to record a single bit of ‘0’ in a new ‘First Pass File’ if the corresponding ‘10’ block in the original binary data file has preceding consecutive bit/s of all ‘0’s which then may or may not possibly in turn be followed by consecutive bit's of all ‘1’s, and to record a single bit of ‘1’ in a new ‘First Pass File’ if the corresponding ‘10’ block in the original binary data file only has preceding consecutive bit/s of all ‘1’s (in manner as described in earlier implementation above).
3. Successive sequentially stepping through each & every of the single bits (whether ‘0’ or ‘1’ binary value) in the ‘First Pass File’ to record in a new ‘Second Pass File’ the total number of consecutive bit/s (of ‘0’ or ‘1’, already indicated in the ‘First Pass File’) preceding the corresponding ‘10’ block in the original binary data file: the ‘total’ number of consecutive bit/s here recorded/represented using number representation system which uses exactly the same number of bit/s as the total number of consecutive bit/s (of all same binary value) that it records/represents: examples of such number representation systems are disclosed earlier in the description body eg 0->1 10->2 110->3 111->‘extend’, or 0->1 10->2 11->‘extend’, or 1->1 00->2 01->‘extend’ . . . etc. (Note here in place of the above number representation system/s illustrated, ‘unary’ number representation system could be used instead: ‘alternately’ continuous successively ‘switched’ between using a number of ‘unary’ ‘0’ bit/s & a number of ‘unary’ ‘1’s bit/s, same number of ‘unary’ bit/s as the number of consecutive bit/s of all same binary value, to represent the ‘total’ number of consecutive bit/s: a single ‘1’ bit or a single ‘0’ bit to represent ‘total’ number of 1 consecutive bit, 2 consecutive ‘1’s or 2 consecutive ‘0’s bits to represent ‘total’ number of 2 consecutive bits . . . N consecutive ‘1’s bits or N consecutive ‘0’ bits to represent ‘total’ number of N consecutive bits).
   Subsequent to this ‘Second Pass’ stage where the ‘total’ number of consecutive bit/s are completely recorded (instead of incrementing the number of consecutive bit/s by 1 at each subsequent passes, as in earlier described implementation in the description body), there is no further need whatsoever to proceed with any further subsequent passes.
4. Successively sequentially stepping through only each of the single ‘0’ bit completely ignore/skipping all the single ‘1’ bits in the ‘First Pass File’, record in a new ‘First Extra1 Pass File’ the total number of consecutive bit/s of all ‘1’s (which follows the consecutive bit/s of all ‘0’s) preceding the corresponding ‘10’ block in the original binary data file: the ‘total’ number of consecutive ‘1’s bit/s here are recorded/represented using number representation system which costs only 1 ‘extra’ single bit more than the total number of consecutive ‘1’s bit/s that it records/represents: examples of such number representation systems are similar to as disclosed earlier in the description body eg here it is 0->0 10->1 110->2 111->‘extend’, or 0->0 10->1 11->‘extend’, or 1->0 00->1 01->‘extend’ . . . etc. (Note here in place of the above number representation system/s illustrated, ‘unary’ number representation system could be used instead: ‘alternately’ continuous successively ‘switched’ between using a number of ‘unary’ ‘0’ bit/s & a number of ‘unary’ ‘1’s bit/s, 1 more than the ‘total’ number of consecutive bit/s of all same binary value, to represent the ‘total’ number of consecutive bit/s of all same binary value: here it is a single ‘1’ bit or a single ‘0’ bit to represent 0 consecutive ‘1’ bit/s (ie there is zero, no consecutive ‘1’ bit/s), 2 consecutive ‘1’s or 2 consecutive ‘0’s bits to represent ‘total’ of 1 consecutive ‘1’s bits . . . N consecutive ‘1’s bits or N consecutive ‘0’ bits to represent of ‘total’ of N−1 consecutive bits)
   Subsequent to this ‘First Extra1 Pass’ stage where the ‘total’ number of consecutive bit/s of all ‘1’s are completely recorded (instead of incrementing the number of consecutive bit/s by 1 at each subsequent Extra1 passes, as in earlier described implementation in the description body), there is no further need whatsoever to proceed with any further subsequent Extra1 passes.
5. From the above ‘Compress File’ & ‘First Pass File’ & ‘Second Pass File’ & ‘First Extra1 Pass File’, together with the various compression process parameters (whether separately transmitted to remote receiver, or pre-appended to the beginning of the single ‘merged’ file of all the files above & then transmitted to remote receiver), the original binary data file can always be losslessly reconstructed.

Another further example variant implementation, among may possible, would be to ‘swapped’ representing next adjacent ‘10’ block (with no preceding consecutive bit/s of ‘0’s &/or ‘1’s) using a single ‘non-alternating’ ‘non-switched’ bit value, and representing next earliest occurrence of next ‘10’ block (with preceding consecutive bit/s of ‘0’s &/or ‘1’s) using a single alternately switched bit value.

Another adapted implementation, among many possible, will be to just use a single ‘0’ bit to represent successive sequential immediately next adjacent ‘10’ block & a single ‘1’ bit to represent successive sequential next occurrence of a ‘10’ block with immediately preceding ‘0’s &/or ‘1’s (instead of above earlier described ‘alternatingly’ ‘switched’/‘same’ as immediately preceding recorded bit's binary value . . . ): all the other subsequent steps would be similar to or similarly adapted as the above earlier described implementation.

Note all the methods above identifies/records/represents successive ‘transitions’ in the bits patterns within the input file such as 1->0 &/or 0->1 ‘transitions’ or various combinations of such transitions, & represent/record them using less bits than the ‘transition’ bits patterns (eg ‘10’ block here corresponds to 1->0 transitions in the bits patterns within the input file, & record/represent the ‘transition’ bits pattern here as a single bit). The different features/characteristics associated with each recorded/represented ‘transition’ bits pattern (eg whether its exact ‘10’ block with exact length of 2 bits . . . etc) would be conveyed/notified eg via ‘alternating’ ‘switched’ binary value scheme, or simply using single ‘0’ & single ‘1’ bit to differentiate. Such ‘transition’ bits patterns combinations could also be eg 0->1 (ie ‘01’ block’), or eg 1->0->1 (ie ‘101’ block), or eg ‘111 . . . 1’->‘000 . . . 0’ (ie ‘111 . . . 1000 . . . 0’ block) . . . etc.

NOTE: the term ‘Unary’ where occurs in the Description Body has its own meaning, and is not to be taken to be of the EXACT same meaning/attributes as with existing common usage.

```
/**************** OUTLINE REFINED SUMMARY *******************/
3. Methods or sub-component method step/s based on and modified from the earlier
  Methods:
Successive sequential record in ‘Compress File’ using a single ‘0’ or ‘1’ bit each
next earliest possible occurrence of ‘10’ block in the original binary data file, in
manner as described in earlier Methods (successive bit's binary value alternately
‘switched, or remain same as preceding latest recorded bit's binary value).
Successive sequentially stepping through each of the ‘non-alternating’ ‘non-
switched’ single bit in the ‘Compress File’ (completely ignoring/skipping all the
alternating ‘switched’ single bit) to record a single bit of ‘0’ in a new ‘First Pass File’ if
the corresponding ‘10’ block in the original binary data file has preceding
consecutive bit/s of all ‘0’s which then may or may not possibly in turn be followed
by consecutive bit/s of all ‘1’s, and to record a single bit of ‘1’ in a new ‘First Pass
File’ if the corresponding ‘10’ block in the original binary data file only has preceding
consecutive bit/s of all ‘1’s (in manner as described in earlier implementation above).
Successive sequentially stepping through each & every of the single bits (whether
‘0’ or ‘1’ binary value) in the ‘First Pass File’ to record in a new ‘Second Pass File’
the ‘total’ number of consecutive bit/s (of ‘0’ or ‘1’, already indicated in the ‘First
Pass File’) preceding the corresponding‘10’ block in the original binary data file: the
‘total’ number of consecutive bit/s here recorded/represented using number
representation system which uses exactly the same number of bit/s or less than as in
the total number of consecutive bit/s (of all same binary value) that it records/
represents: examples of such number representation systems are disclosed earlier in
the description body eg 0->1 10->2 110 ->3 111->‘extend’, or 0->1 10->2 11->
‘extend’, or 1->1 00->2 01->‘extend’ ....etc. (Note here in place of the above
number representation system/s illustrated, ‘unary’ number representation system
could be used instead: ‘alternately’ continuous successively ‘switched’ between using
a number of ‘unary’ ‘0’ bit/s & a number of ‘unary’ ‘1’s bit/s, same number of
‘unary’ bit/s as the number of consecutive bit/s of all same binary value, to represent
the ‘total’ number of consecutive bit/s: a single ‘1’ bit or a single ‘0’ bit to represent
‘total’ number of 1 consecutive bit, 2 consecutive ‘1’s or 2 consecutive ‘0’s bits to
represent ‘total’ number of 2 consecutive bits.....N consecutive ‘1’s bits or N
consecutive ‘0’ bits to represent ‘total’ number of N consecutive bits), OR using any
of the number representation system/s as described earlier.
  Subsequent to this ‘Second Pass’ stage where the ‘total’ number of consecutive
  bit/s are completely recorded (instead of incrementing the number of consecutive
  bit/s by 1 at each subsequent passes, as in earlier described implementation in the
  description body), there is no further need whatsoever to proceed with any
  further subsequent passes.
Successively sequentially stepping through only each of the single ‘0’ bit completely
ignore/skipping all the single ‘1’ bits in the ‘First Pass File’, record in a new ‘First
Extra1 Pass File’ the ‘total’ number of consecutive bit/s of all ‘1’s (which follows
the consecutive bit/s of all ‘0’s) preceding the corresponding‘10’ block in the
original binary data file: the ‘total’ number of consecutive ‘1’s bit/s here are
recorded/represented using number representation system which costs only 1 ‘extra’
single bit more than the total number of consecutive ‘1’s bit/s that it records/
represents: examples of such number representation systems are similar to as
disclosed earlier in the description body eg here it is 0->0 10->1 110 ->2 111->
‘extend’, or 0->0 10->1 11->‘extend’, or 1->0 00->1 01->‘extend’ ....etc.
(Note here in place of the above number representation system/s illustrated, ‘unary’
number representation system could be used instead: ‘alternately’ continuous
successively ‘switched’ between using a number of ‘unary’ ‘0’ bit/s & a number of
‘unary’ ‘1’s bit/s, 1 more than the ‘total’ number of consecutive bit/s of all same
binary value, to represent the ‘total’ number of consecutive bit/s of all same binary
value: here it is a single ‘1’ bit or a single ‘0’ bit to represent 0 consecutive ‘1’ bit/s
(ie there is zero, no consecutive ‘1’ bit/s), 2 consecutive ‘1’s or 2 consecutive ‘0’s
bits to represent ‘total’ of 1 consecutive ‘1’s bits .....N consecutive ‘1’s bits or N
consecutive ‘0’ bits to represent of ‘total’ of N − 1 consecutive bits), OR using any
of the number representation system/s as described earlier
  Subsequent to this ‘First Extra1 Pass’ stage where the ‘total’ number of
  consecutive bit/s of all ‘1’s are completely recorded (instead of incrementing the
  number of consecutive bit/s by 1 at each subsequent Extra1 passes, as in earlier
  described implementation in the description body), there is no further need
  whatsoever to proceed with any further subsequent Extra1 passes.
4. 13. Methods or sub-component method step/s for lossless reconstruction of
    compressed data, said methods or sub-
    component method step/s here:
  From the above ‘Compress File’ & ‘First Pass File’ & ‘Second Pass File’ &
‘First Extra1 Pass File’, together with the various compression process parameters (or
pre-appended to the beginning of the single ‘merged’ file of all the files), the original
binary data file can always be losslessly reconstructed.
/************************ END *********************************/
```

Here is again presented another new, but related, data compression coding method.

This method (could also be adapted to apply to ternary . . . etc, or to various structure):

examine the original binary data file of arbitrary size sequentially, from initial very 1^{st} starting consecutive bit/s all of same binary value (either ‘0’s, or ‘1’s) to the very end consecutive bit/s all of same binary value position (either ‘0’s, or ‘1’s), looking for each successive sequential immediately next adjacent consecutive bit/s all of same binary value (ie a single ‘0’ or a single ‘1’, or a number of consecutive ‘0’s or a number of consecutive ‘1’s: note each successive sequential immediately next adjacent consecutive bit/s in the original binary input file will all be of different/opposite binary value to the binary value of its immediately preceding consecutive bit/s, ie alternatingly ‘switched’ from 0/s to 1/s & 1/s to 0/s successively):

Each of these successive sequential immediately next adjacent consecutive bit/s all of same binary value in the original binary data file is successively sequentially recorded in a new ‘Unary Representation’ data file with just one single ‘1’ binary bit or with just one single ‘0’ binary bit, if the consecutive bit/s consists of just a single bit of ‘0’ or a single bit of ‘1’. Note the very initial 1^{st} recorded bit in the ‘Unary File’ could be convention pre-arranged to start recording the very initial first occurrence of consecutive bit/s all of same binary value in the input file with eg a single ‘0’ bit to conveniently correctly convey/indicate that the very initial 1^{st} consecutive bit/s all of same binary value in the input file is of length only 1 single bit, & with eg a single ‘1’ bit to conveniently correctly convey/indicate that the very initial 1^{st} consecutive bit/s all of same binary value in the input file is of length at least 2 or more bits.

The ‘Unary Representation’ process here will always provide/store as a ‘single bit parameter’ (or transmit to remote receiver) the binary value of the very 1^{st} consecutive bit/s of all ‘0’/s or ‘1’/s of the very initial 1^{st} original input binary file used in the very initial 1^{st} iteration in the ‘unary representation’ process (ie which lossless reconstruction process would attempt to subsequently ‘recreate’ faithfully, not the binary value of the very 1^{st} consecutive number of bit/s of ‘0’/s or ‘1’/s of the final iteration's resultant final ‘Unary File’: note only the very initial 1^{st} original input binary file input file's very 1^{st} consecutive bit/s' binary value needs be provided, not all the successive iterations' input files’), which may also optionally be conveyed eg with pre-agreed format to insert/pre-append an ‘extra’ very first single ‘1’ bit or an ‘extra’ very first single ‘0’ bit in eg the very first bit position of the final iteration's resultant ‘Unary File’ to notify that the value of the very first ‘bit’ in the very initial 1^{st} original input binary data file is ‘1’ or ‘0’ respectively. The costs here is only 1 single bit for the complete entire iterations process, & could here conveniently be completely ignored/disregarded in all calculations/discussions of compression ratio efficiencies.

Note it is not necessary to provide/store all the very 1^{st} consecutive bit/s' binary value in each & every of all the iterations' input files! since during each & every of all the lossless reconstruction iterations the reconstruction process at each iteration could simply ‘assume as either 0 or 1’ or even ‘wrongly guess either 0 or 1’ any of the reconstruction iterations' resultant file's very 1^{st} consecutive bit/s' binary value: when all the lossless reconstruction iterations are completed, the final reconstruction iterations' eventual resultant file's very 1^{st} consecutive bit/s' binary value is compared to the provided/stored parameter of the binary value of the very initial 1^{st} original input binary data file, IF both indicates the same binary value then all is fine & the very initial 1^{st} original input binary data file has been losslessly reconstructed faithfully, OTHERWISE each & everyone of all the bits' binary value in the reconstruction iterations' final resultant file will be ‘swapped’/‘switched’ to be of opposite binary value & this will now provide the required lossless faithful reconstruction of the very initial 1^{st} original input binary data file. This is so because each & every of all the ‘unary representation’ process iterations & each & every of all the lossless reconstruction process ‘reverse flow’ iterations here will always produce either a correct resultant file or a ‘correct but reversed bits’ resultant file with each & every bits' having the ‘reversed’ opposite binary value as the correct resultant file.

If the immediately next adjacent consecutive bit/s is consists of just a single binary bit (necessarily always of different/opposite binary value to the binary value of its immediately preceding binary bit) in the original binary data file, then it is ‘switched’ to using just a single binary bit with binary value different/opposite to the latest recorded binary bit value entry in the ‘Unary File’, to represent/record this present single consecutive bit in the ‘Unary File’. And if the immediately next adjacent consecutive bit/s is now again consists of just a single binary bit (necessarily always of different/opposite binary value to the binary value of its immediately preceding binary bit) in the original binary data file, then it is now again ‘switched’ to using just a single binary bit, with binary value different/opposite to the latest recorded binary bit value entry in the ‘Unary File’, to represent/record this present latest single consecutive bit in the ‘Unary File’ . . . ie successive alternatively ‘switched’ using just a single ‘0’ & ‘1’ binary bit to record these successive sequential consecutive immediately next adjacent sequences of consecutive bit/s (which necessarily always successive sequentially alternatingly ‘switches’ binary value from ‘0’ to ‘1’ & ‘1’ to ‘0’ continuously). Were all consecutive bit/s in the original binary data file comprises only of all consecutive bit/s successive sequentially alternatingly ‘switched’ having only just a single bit of ‘0’ or only just a single bit of ‘1’, then the ‘Unary File’ will also only just consists of successive sequential alternating ‘switched’ single ‘0’ bit & single ‘1’ bit, and this would yield lossless compression ratio of exactly 1 ie ‘Unary File’ will be of exact same size as the original binary data file (ignoring/disregarding the earlier described pre-appended 1 single bit extra costs, the ‘Unary File’ in this case would also be amenable to further different appropriately selected compression algorithm/s to conveniently yield magnitude orders much higher compression ratios by describing the file as successive alternating ‘switched’ bit pattern of just single ‘0’ bit & single ‘1’ bit repeated a number of times or via combining using other commonly known compression method/s such as eg run length encoding, ‘10’ blocks length encoding, LZW . . . etc).

If the immediately next adjacent consecutive bit/s in the original binary data file are not just a single ‘0’ bit or are not just a single ‘1’ bit (ie there are now at least 2 or more consecutive bits of all ‘0’s or of all ‘1’s), then they are represented/recorded in the ‘Unary File’ as a number of consecutive ‘adapted unary bits of unary 0’/s or ‘unary 1’/s, all of same binary value as the immediately preceding binary bit value recorded in the ‘Unary File’, except that in this ‘adapted’ unary representation the very last bit in this number of unary consecutive bits will be made to be ‘switched’ to be of different/opposite binary value to the binary value of all the other consecutive unary bit/s: ie the ‘adapted’ unary representation bits patterns now will be eg ‘01’ instead of ‘00’, ‘10’ instead of ‘11’, ‘001’ instead of ‘000’, ‘110’ instead of ‘111’, ‘0001’ instead of ‘0000’, ‘1110’ instead of ‘1111’, ‘000 . . . 01’ instead of 000 . . . 00′, ‘111 . . . 10 instead of ‘111 . . . 11’, note the very last bit in the corresponding number of consecutive ‘unary’ bits here is always made to be ‘switched to be of different/opposite binary value to the binary value of the other consecutive ‘unary’ bit/s, which incidentally acts as ‘adapted’ unary number delimiter/end marker. ‘01’ or ‘10’ represents 2 consecutive bits all of same binary value in the original binary data file, ‘0001’ or ‘1110’ represents 4 consecutive bits all of same binary value in the original binary data file). Here we would now see in the ‘Unary File’ occurrence of two consecutive same value binary bits, (previously it was just all successively ‘alternatingly’ ‘switched’ single bit of ‘0’ & ‘1’), incidentally the first occurrence of a single bit of same binary value as the binary value of its immediately preceding binary bit in the ‘Unary File’ also signifies the ‘start’ position of an ‘adapted’ unary number representation of at least 2 or more number of consecutive bits in the original binary data file and the ‘end’ position is ‘delimited/marked’ by occurrence of a first single bit made to be of different/opposite binary value to the binary value of all of the other ‘adapted’ unary consecutive bit/s.

If following a number at least 2 or more consecutive bits all of same binary value in the original binary data file, the immediate next adjacent consecutive bit/s is now again at least 2 more consecutive bits all of same binary value in the original binary data file (note in the original binary data file, only consecutive bit/s all of different/opposite binary value to the binary value of the immediately preceding consecutive bit/s follows the immediate preceding consecutive bit/s, ie each successive consecutive bit/s ‘switches’ binary value from the binary value of its immediately preceding consecutive bit/s→if knowing the binary value of the very 1^{st} initial consecutive bit/s of the original binary data file, the binary value of each & every & all the successive consecutive bit/s could be ascertained), then this present latest consecutive bits in the original input binary data file are represented/recorded in the ‘Unary File’ as a number of consecutive ‘adapted’ unary bits of ‘unary 0’ or ‘unary 1’, all of same binary value as the immediately preceding binary bit value recorded in the ‘Unary File’ ie of same binary value as the binary value of the immediately preceding ‘delimiter/end marker’ bit in the ‘Unary File’, except that the very last bit in this number of consecutive ‘unary’ bits will be made to be ‘switched’ to be of different/opposite binary value to the binary value of all the other consecutive ‘unary’ bit/s: ie the ‘adapted’ unary representation bits patterns now will be eg ‘01’ instead of ‘00’, ‘10’ instead of ‘11’, ‘001’ instead of ‘000’, ‘110’ instead of ‘111’, ‘0001’ instead of ‘0000’, ‘1110’ instead of ‘1111’, ‘000 . . . 01’ instead of ‘000 . . . 00’, ‘111 . . . 10 instead of ‘111 . . . 11’, note the very last bit in the number of consecutive ‘adapted’ unary bits here is always made to be ‘switched to be of different/opposite binary value to the binary value of the other consecutive ‘adapted’ unary bit/s, which incidentally acts as ‘adapted’ unary number delimiter/end marker. ‘01’ or ‘10’ represents 2 consecutive bits all of same binary value in the original binary data file, ‘0001’ or ‘1110’ represents 4 consecutive bits all of same binary value in the original binary data file.

If following a number at least 2 or more consecutive bits all of same binary value in the original binary data file, the immediate next adjacent consecutive bit/s is now just a single ‘0’ or just a single ‘1’ in the original binary data file (note in the original binary data file, only consecutive bit/s all of different/opposite binary value to the binary value of the immediately preceding consecutive bit/s follows the immediate preceding consecutive bit/s, ie each successive consecutive bit/s ‘switches’ binary value from the binary value of its immediately preceding consecutive bit/s→if knowing the binary value of the very 1^{st} initial consecutive bit/s of the original binary data file, the binary value of each & every & all the successive consecutive bit/s could be ascertained), then a single ‘0’ bit or a single ‘1’ bit of different/opposite binary value to the binary value of the immediately preceding recorded bit in the ‘Unary File’ (ie of different/opposite binary value to the immediately preceding recorded ‘delimiter/end marker’ bit) will be used to represent/record in the ‘Unary File’ this present latest consecutive bit/s of just a single bit.

Thus it can be readily seen that if a single bit's binary value in the new ‘Unary File’ is ‘switched’/‘changed’ from its immediately preceding single bit's binary value in the new ‘Unary File’, it represents consecutive bit/s of just one single bit of ‘0’ or just one single bit of ‘1’ in the original binary data file. If a single bit's binary value in the new ‘Unary File’ is the same as its immediately preceding single bit's binary value in the new ‘Unary File’, then all consecutive number of bit/s all of same binary value in the ‘Unary File’ starting with this single bit & together with the immediately next earliest occurred single bit made to be of different/opposite binary value to the binary value of these consecutive number of bit/s of all same binary value, will together form an ‘adapted’ unary number representation of the corresponding present latest consecutive number of bits all of same binary value in the original binary data file: this number is equal to the total number of consecutive ‘unary’ bits all of same binary value above +1 bit (ie consecutive number of ‘unary’ bits +1 ‘delimiter/end marker’ bit).

/**************** OUTLINE REFINED SUMMARY *******************/
5. Methods or sub-component method step/s for lossless data compressions, said
methods or sub-component method step/s here:
examine the original binary data file of arbitrary size sequentially, from initial very
1^{st} starting consecutive bit/s all of same binary value (either ‘0’s, or ‘1’s) to the very
end consecutive bit/s all of same binary value position (either ‘0’s, or ‘1’s), looking
for each successive sequential immediately next adjacent consecutive bit/s all of same
binary value (ie a single ‘0’ or a single ‘1’, or a number of consecutive ‘0’s or a
number of consecutive ‘1’s: note each successive sequential immediately next
adjacent consecutive bit/s in the original binary input file will all be of different/
opposite binary value to the binary value of its immediately preceding consecutive
bit/s, ie alternatingly ‘switched’ from 0/s to 1/s & 1/s to 0/s successively):
Each of these successive sequential immediately next adjacent consecutive bit/s all of
same binary value in the original binary data file is successively sequentially recorded in
a new ‘Unary Representation’ data file with just one single ‘1’ binary bit or with
just one single ‘0’ binary bit, if the consecutive bit/s consists of just a single bit of
‘0’ or a single bit of ‘1’
OPTIONALLY the very initial 1^{st} recorded bit in the ‘Unary File’ could be
convention pre-arranged to start recording the very initial first occurrence of
consecutive bit/s all of same binary value in the input file with eg a single ‘1’ bit to
conveniently correctly convey/indicate that the very initial 1^{st} consecutive bit/s all of
same binary value in the input file is of length only 1 single bit, & with eg a single
‘1’ bit to conveniently correctly convey/indicate that the very initial 1^{st} consecutive
bit/s all of same binary value in the input file is of length at least 2 or more bits.
If the immediately next adjacent consecutive bit/s is consists of just a single binary
bit (necessarily always of different/opposite binary value to the binary value of its
immediately preceding binary bit) in the original binary data file, then it is ‘switched’
to using just a single binary bit with binary value different/opposite to the latest
recorded binary bit value entry in the ‘Unary File’, to represent/record this present
single consecutive bit in the ‘Unary File’
If the immediately next adjacent consecutive bit/s in the original binary data file are
not just a single ‘0’ bit or are not just a single ‘1’ bit (ie there are now at least 2 or
more consecutive bits of all ‘0’s or of all ‘1’s), then they are represented/recorded in
the ‘Unary File’ as a number of consecutive ‘adapted unary bits of unary 0’/s or
‘unary 1’/s, all of same binary value as the immediately preceding binary bit value
recorded in the ‘Unary File’, except that in this ‘adapted’ unary representation the
very last bit in this number of unary consecutive bits will be made to be ‘switched’ to
be of different/opposite binary value to the binary value of all the other consecutive
unary bit/s
Each resultant ‘Unary File’ produced (which will always be of same equal file size
as the input file, ie ignoring/disregarding the 1 single bit extra costs to indicate the
very 1^{st} initial original binary input file) could subsequently be used as a new ‘input
file’ in subsequent repeated iterations, it is obvious here that at each iteration the
maximum length of consecutive bits all of same binary value in the resultant ‘Unary
File’ will be reduced by 1 compared to the maximum length of consecutive bits in the
iteration's new ‘input binary file’ used in the iteration:
The repeated iterations may be ‘stopped’ when maximum length of consecutive bits
all of same binary value in the resultant ‘Unary File’ becomes equal to certain
specified length, whereupon subsequently various different lossless compression
algorithm/s may be selected appropriately to actually reduce the file size as much as is
possible
/************************ END *********************************/

Each resultant ‘Unary File’ produced (which will always be of same equal file size as the input file, ie ignoring/disregarding the earlier described pre-appended 1 single bit extra costs) could subsequently be used as a new ‘input file’ in subsequent repeated iterations. It is obvious here that at each iteration the maximum length of consecutive bits all of same binary value in the resultant ‘Unary File’ will be reduced by 1 compared to the maximum length of consecutive bits in the new ‘original input binary file’ used in the iteration. The repeated iterations may be ‘stopped’ when maximum length of consecutive bits all of same binary value in the resultant ‘Unary File’ becomes equal to certain specified length, whereupon subsequently various different compression algorithm/s may be selected appropriately to actually reduce the file size as much as is possible while maintaining losslessness. Eg the final iteration may ‘stop’ upon maximum length of consecutive bits all of same binary value is equal to eg 2 ie such as eg only bit patterns ‘1010101001100101010011 . . . 10100110’ where there are not more than 2 consecutive ‘0’s & not more than 2 consecutive ‘1’s present anywhere in the resultant final ‘Unary File’.

An example compression algorithm to reduce the size of the above resultant final ‘Unary File’ with eg at most 2 consecutive bits present (algorithm could be similarly applied to any specified maximum number of consecutive bits eg 3/4/5 . . . etc) all of same binary value present, among various suitable algorithms possible (including any of earlier described compression methods . . . etc), will be to:
1. Successive sequentially steps through each immediately next adjacent consecutive bit/s (which could only be of lengths either 1 bit or 2 bits only, each immediately next adjacent consecutive bit/s will be of all different/opposite binary value from the binary value of the immediately preceding consecutive bit/s), from the very initial 1^{st} consecutive bit/s to the last consecutive bit/s in the input final ‘Unary File’ (or previous iteration's resultant ‘Reduced File’, if now used as input file in this iteration):
   to record a single bit into a new ‘Reduced File’ (of either ‘0’ or ‘1’ binary value) with binary value ‘switched’ to be of different/opposite binary value to the binary value of the immediately preceding ‘recorded’ bit in the ‘Reduced File’, if the present latest corresponding consecutive bit/s in the input final ‘Unary File’ consists only of a single ‘0’ bit or consists only of a single ‘1’ bit.

Note another possible adapted implementation, among many possible, will be to just use a single ‘0’ bit to represent successive sequential immediately next adjacent consecutive bit/s of just 1 single bit, & use a single ‘1’ bit to represent successive sequential next occurrence of 2 consecutive bits all of same binary value (instead of above described ‘alternatingly’ ‘switched’/‘same’ as immediately preceding recorded bit's binary value . . . ): here all the other subsequent steps would be similar to or similarly adapted as the above described implementation.

Note the very initial 1^{st} recorded bit in the ‘Reduced File’ could be convention pre-arranged to start recording the very initial first occurrence of consecutive bit/s (which can only be of length at most 2 bits here) all of same binary value in the input file with eg a single ‘1’ bit to conveniently correctly convey/indicate that the very initial 1^{st} consecutive bit/s all of same binary value in the input file is of length 2 bits (instead of just a single bit) & a single ‘1’ bit to conveniently correctly convey/indicate that the very initial 1^{st} consecutive bit/s all of same binary value in the input file is of length 1 single bit.
to record a single bit into a new ‘Reduced File’ (of either ‘0’ or ‘1’ binary value) with binary value to be the same binary value as the binary value of the immediately preceding ‘recorded’ bit in the ‘Reduced File’, if the present latest consecutive bit/s in the input file consists of 2 consecutive bits of either ‘00’ or ‘11’ bits patterns. Note whether this recorded single bit in the ‘Reduced File’ (of same binary value to its immediately preceding recorded bit in the ‘Reduced File’) represents/records 2 consecutive bits of bits pattern ‘00’ or bits pattern ‘11’ in the input file, could be ascertained provided the binary value of the initial very 1^{st} bit in the input file is known/made available, since each successive single recorded bit in the iteration's resultant ‘Reduced File’ represents corresponding successive consecutive bit/s in the input file (which can here only be of length either only 1 bit or only 2 bits) each with successive ‘alternate’ ‘switched’ binary value from the immediately preceding consecutive bit/s. Note this ‘file size reduction’ process iteration will always provide a resultant new ‘Reduced File’ with file size less than or at very worst equal to the file size of the input file ie again ignoring/disregarding the earlier described very small number of parameter bit/s costs. In cases where this ‘file size reduction’ process iteration's new resultant ‘Reduced File’ is equal (or very very close to) in size to the size of the input file, this invariably signifies the resultant new Reduced File consists only of very basic bit/s pattern/s repeated many many time throughout the resultant new ‘Reduced File’, & would be ideal to now for a different & appropriate algorithm to be next ‘selected’ to next reduce the file size by magnitude orders: eg resultant new ‘Reduced File’ may simply consists of regular continuous successive ‘alternating’ ‘switched’ bits pattern of single ‘0’ bit & single ‘1’ bit (ie an appropriate algorithm here could simply be Run Length type algorithm which compresses entire file as ‘10’ bits pattern or ‘01’ bits pattern repeated a specified number of times, &/or plus a single ‘end bit value’ . . . etc.

Note the very initial 1^{st} recorded bit in the ‘Reduced File’ could be pre-arranged to start recording the very initial first occurrence of consecutive bit/s (which can only be of length at most 2 bits here) all of same binary value in the input file with eg a single ‘1’ bit to conveniently correctly convey/indicate that the very initial 1^{st} consecutive bit/s all of same binary value in the input file is of length 2 bits (instead of just a single bit), & with eg a single ‘0’ bit to conveniently correctly convey/indicate that the very initial 1^{st} consecutive bit/s all of same binary value in the input file is of length 1 single bit.
The ‘file size reduction’ method here will always provide/store as a ‘single bit parameter’ (or transmit to remote receiver) the binary value of the very 1^{st} consecutive bit/s of all ‘0’/s or ‘1’/s of the very initial 1^{st} original input binary file used in the very initial 1^{st} iteration in the ‘unary representation’ process (ie which lossless reconstruction process would attempt to subsequently ‘recreate’ faithfully, its not the binary value of the very 1^{st} consecutive number of bit/s ‘0’ or ‘1’ of the final iteration's resultant final ‘Reduced File’: note only the very initial 1^{st} original input binary file input file's very 1^{st} consecutive bit/s' binary value needs be provided, not all the successive iterations' input files'), which could optionally be conveyed eg with pre-agreed format to insert/pre-append an ‘extra’ very first single ‘1’ bit or an ‘extra’ very first single ‘0’ bit in eg the very first bit position of the final iteration's resultant ‘Reduced File’ to notify that the value of the very first ‘bit’ in the very initial 1^{st} original input binary data file as ‘1’ or ‘0’ respectively. The costs here is only 1 single bit for the complete entire iterations process, & could here conveniently be completely ignored/disregarded in all calculations/discussions of compression ratio efficiencies.

Note it is not necessary to provide/store all the very 1^{st} consecutive bit/s' binary value in each & every of all the iterations' input files! since during each & every of all the lossless reconstruction iterations the reconstruction process at each iteration could simply ‘assume as either 0 or 1’ or even ‘wrongly guess either 0 or 1’ any of the reconstruction iterations' resultant file's very 1^{st} consecutive bit/s' binary value: when all the lossless reconstruction iterations are completed, the final reconstruction iterations' eventual resultant file's very 1^{st} consecutive bit/s' binary value is compared to the provided/stored parameter of the binary value of the very initial 1^{st} original input binary data file, IF both indicates the same binary value then all is fine & the very initial 1^{st} original input binary data file has been losslessly reconstructed faithfully, OTHERWISE each & everyone of all the bits' binary value in the reconstruction iterations' final resultant file will be ‘swapped’/‘switched’ to be of opposite binary value & this will now provide the required lossless faithful reconstruction of the very initial 1^{st} original input binary data file. This is so because each & every of all the ‘file size reduction’ & ‘unary representation’ process iterations & each & every of all the lossless reconstruction process iterations here will always produce either a correct resultant file or a correct but reversed bits' resultant file with each & every bits' having the ‘reversed’ opposite binary value as the correct resultant file.

Note also earlier described convention already indicates whether each & every iterations' input file's very 1^{st} consecutive bit/s' is of length 1 single bit or is of length at least eg 2 bits (or eg more), without any bit/s costs to the compression ratio efficiency whatsoever.
2. The resultant ‘Reduced File’ from Paragraph 1 above could now be used as new input file (in place of the input final ‘Unary File’, or any previous earlier iteration's input ‘Reduced File’) in a new iteration of the ‘file size reduction’ process in Paragraph 1 above, UNTIL certain specified criteria is attained eg certain specified compression ratio is achieved, or eg file size is reduced to certain specified size, or eg there remains not more than a specified total number of all consecutive 2 bits of same binary value in the latest iteration's ‘Reduced File’ . . . etc. The resultant ‘Reduced File’ at each iteration needs to be checked if number of max consecutive bits at end of the iteration grows to be > eg 2: if it does not then proceed to next ‘file size reduction’ as described in Paragraph 2 here, OTHERWISE (if > eg 2 now) then next iteration should go through earlier ‘unary representation’ process again until number of max consecutive bits again becomes not more than eg 2 before proceeds onto next iteration of ‘file size reduction’ process.
   Note these successive iterations flow sequence may be recorded as parameters of the overall compression process flow, stored or transmitted to remote receiver. However it is not necessary, since during the lossless faithful reconstruction iterations, if during ‘reverse flow’ reconstruction iteration of ‘file size reduction’ process the resultant file contains max consecutive bits of length > eg 2 then the next iteration/s will be iteration/s of the ‘unary representation’ process UNTIL the max consecutive bits present in the ‘reverse flow iteration's resultant file becomes eg 2 to then resume ‘reverse flow iteration/s’ of ‘file size reduction’ process.
3. The resultant final iteration's ‘Reduced File’, together with various of the parameters of the ‘file size reduction’ process which should at least include the total number of ‘file size reduction’ process iterations . . . , & together with the parameters of the earlier ‘Unary File’ process which should at least include the total number of ‘Unary File’ process iterations, & together with the ‘single bit parameter’ of the binary value of the very 1^{st} consecutive bit/s of all ‘0’/s or ‘1’/s of the very initial 1^{st} original input binary file used in the very initial 1^{st} iteration in the ‘unary representation’ process, & the ‘specified’ number of max consecutive bits, could now be stored locally or transmitted to remote receiver (whether ‘separately’, or pre-appended to pre-agreed fixed initial bit/s positions of the resultant final ‘Reduced File’) which would enable lossless faithful reconstruction of the very initial original binary data file.

```
/**************** OUTLINE REFINED SUMMARY *******************/
6. Methods or sub-component method step/s further compresses the resultant final
  iteration's ‘Unary File’ produced in earlier described Methods where the max
  consecutive bits all of same binary value therein is length 2 bits only, said
  methods or sub-component method step/s HERE FURTHER:
Successive sequentially steps through each immediately next adjacent consecutive
bit/s, from the very initial 1^{st} consecutive bit/s to the last consecutive bit/s in the input final
‘Unary File’ (or previous iteration's resultant ‘Reduced File’, if now used as
input file in this iteration):
to record a single bit into a new ‘Reduced File’ (of either ‘0’ or ‘1’ binary value)
with binary value ‘switched’ to be of different/opposite binary value to the binary
value of the immediately preceding ‘recorded’ bit in the ‘Reduced File’, if the present
latest corresponding consecutive bit/s in the input final ‘Unary File’ consists only of a
single ‘0’ bit or consists only of a single ‘1’ bit.
OPTIONALLY another possible adapted implementation, among many possible,
will be to just use a single ‘0’ bit to represent successive sequential immediately next
adjacent consecutive bit/s of just 1 single bit, & to represent successive sequential
next occurrence of 2 consecutive bits all of same binary value (instead of above
described ‘alternatingly’ ‘switched’/‘same’ as immediately preceding recorded bit's
binary value .....)
OPTIONALLY the very initial 1^{st} recorded bit in the ‘Reduced File’ could be
convention pre-arranged to start recording the very initial first occurrence of
consecutive bit/s (which can only be of length at most 2 bits here) all of same binary
value in the input file with eg a single ‘1’ bit to conveniently correctly convey/
indicate that the very initial 1^{st} consecutive bit/s all of same binary value in the input
file is of length 2 bits (instead of just a single bit) & a single ‘1’ bit to conveniently
correctly convey/indicate that the very initial 1^{st} consecutive bit/s all of same binary
value in the input file is of length 1 single bit.
to record a single bit into a new ‘Reduced File’ (of either ‘0’ or ‘1’ binary value)
with binary value to be the same binary value as the binary value of the immediately
preceding ‘recorded’ bit in the ‘Reduced File’, if the present latest consecutive bit/s
in the input file consists of 2 consecutive bits of either ‘00’ or ‘11’ bits patterns
In cases where this ‘file size reduction’ process iteration's new resultant ‘Reduced
File’ is equal (or very very close to) in size to the size of the input file, this
invariably signifies the resultant new ‘Reduced File’ consists only of very basic bit/s
pattern/s repeated many many time throughout the resultant new ‘Reduced File’, &
would be ideal to now for a different & appropriate algorithm to be next ‘selected’ to
next reduce the file size by magnitude orders: eg resultant new ‘Reduced File’ may
simply consists of regular continuous successive ‘alternating’ ‘switched’ bits pattern
of single ‘0’ bit & single ‘1’ bit (ie an appropriate algorithm here could simply be
Run Length type algorithm which compresses entire file as ‘10’ bits pattern or ‘01’
bits pattern repeated a specified number of times, &/or plus a single ‘end bit
value’ .....etc
OPTIONALLY the very initial 1^{st} recorded bit in the ‘Reduced File’ could be pre-
arranged to start recording the very initial first occurrence of consecutive bit/s (which
can only be of length at most 2 bits here) all of same binary value in the input file
with eg a single ‘1’ bit to conveniently correctly convey/indicate that the very
initial 1^{st} consecutive bit/s all of same binary value in the input file is of length 2 bits
(instead of just a single bit), & with eg a single ‘1’ bit to conveniently correctly
convey/indicate that the very initial 1^{st} consecutive bit/s all of same binary value in
the input file is of length 1 single bit.
The ‘file size reduction’ method here will always provide/store as a ‘single bit
parameter’ the binary value of the very 1^{st} consecutive bit/s of all ‘0’/s or ‘1’/s of the
very initial 1^{st} original input binary file used in the very initial 1^{st} iteration in the
‘unary representation’ process (ie which lossless reconstruction process would
attempt to subsequently ‘recreate’ faithfully, its not the binary value of the very 1^{st}
consecutive number of bit/s ‘0’ or ‘1’ of the final iteration's resultant final ‘Reduced
File’: note only the very initial 1^{st} original input binary file input file's very 1^{st}
consecutive bit/s’ binary value needs be provided, not all the successive iterations’
input files’), which could optionally be conveyed eg with pre-agreed format to insert/
pre-append an ‘extra’ very first single ‘1’ bit or an ‘extra’ very first single ‘0’ bit in
eg the very first bit position of the final iteration's resultant ‘Reduced File’ to notify
that the value of the very first ‘bit’ in the very initial 1^{st} original input binary data file
as ‘1’ or ‘0’ respectively
2. Methods or sub-component method steps as described in earlier Methods, said
  methods or sub-component method step/s HERE FURTHER:
    The resultant ‘Reduced File’ from earlier Methods is now to be used as new
input file (in place of the input final ‘Unary File’, or any previous earlier iteration's
input ‘Reduced File’) in a new iteration of the ‘file size reduction’ process in
Paragraph 1 above, UNTIL certain specified criteria is attained eg certain specified
compression ratio is achieved, or eg file size is reduced to certain specified size, or eg
there remains not more than a specified total number of all consecutive 2 bits of same
binary value in the latest iteration's ‘Reduced File’ ...etc. The resultant ‘Reduced File’
at each iteration needs to be checked if number of max consecutive bits at end of the
iteration grows to be > eg 2: if it does not then proceed to next ‘file size reduction’
as described in Paragraph 2 here, OTHERWISE (if > eg 2 now) then next iteration
should go through earlier ‘unary representation’ process again until number of max
consecutive bits again becomes not more than eg 2 before proceeds onto next iteration
of ‘file size reduction’ process.
    The resultant final iteration's ‘Reduced File’, together with various of the
    parameters of the ‘file size reduction’ process which should at least include the
    total number of ‘file size reduction’ process iterations..., & together with the
    parameters of the earlier ‘Unary File’ process which should at least include the
    total number of ‘Unary File’ process iterations, & together with the ‘single bit
    parameter’ of the binary value of the very 1^{st} consecutive bit/s of all ‘0’/s or
    ‘1’/s of the very initial 1^{st} original input binary file used in the very initial 1^{st}
    iteration in the ‘unary representation’ process, & the ‘specified’ number of max
    consecutive bits, could now be stored (whether ‘separately’, or pre-appended to
    pre-agreed fixed initial bit/s positions of the resultant final ‘Reduced File’)
    which would enable lossless faithful reconstruction of the very initial original
    binary data file.
/************************ END *********************************/
```

Note the ‘file size reduction’ process could also use other various number representation system eg 0->1 10->2 11->3 . . . etc if the ‘unary representation’ process specifies ‘stop’ to be at max consecutive bits of eg 3 . . . etc. This method here first uses ‘unary representation’ process to iteratively reduces the maximum number of bits present in any consecutive bit/s of all same binary value in the new resultant final ‘Unary File’ to a specified maximum number eg 3 . . . etc (note here all the various iteration's resultant ‘Unary File/s’ including the resultant final ‘Unary File’ will be of exact same size as the very 1st initial original input binary data file size throughout, ie ignoring/disregarding the earlier described small number of parameter bit/s), then next ‘file size reduction’ process will produce a ‘Reduced File’ with file size always less than or at very worst equal to the file size of the present iteration's input file & IF there are now maximum number of bits present in any consecutive bit/s (all of same binary value) greater than the specified maximum number (eg 3 . . . etc) in this ‘file size reduction’ iteration's resultant new ‘Reduced File’ then the overall process flow will start again at the beginning of the ‘unary representation’ process above with this iteration's resultant new ‘Reduced File’ used as input file, OTHERWISE the overall process flow will iterate again in ‘file size reduction’ process with this iteration's resultant new ‘Reduced File’ used as input file This overall process flow repeatedly iterates UNTIL certain specified criteria is attained eg certain specified compression ratio is achieved, or eg file size is reduced to certain specified size, or eg there remains not more than a specified total number of all consecutive 3 bits of same binary value in the latest iteration's ‘Reduced File’ . . . etc

```
/**************** OUTLINE REFINED SUMMARY *******************/
7. Methods or sub-component method step/s based on or modified from methods or
  sub-component method step/s as described in earlier Methods, said
  methods or sub-component method step/s here:
  the ‘file size reduction’ process could also use other various number
representation system described earlier eg 0->1 10->2 11->3...etc if the ‘unary
representation’ process specifies ‘stop’ to be at max consecutive bits of eg 3 ...etc., this
method here first uses ‘unary representation’ process to iteratively reduces the
maximum number of bits present in any consecutive bit/s of all same binary value in
the new resultant final ‘Unary File’ to a specified maximum number eg 3 ...etc (note
here all the various iteration's resultant ‘Unary File/s’ including the resultant final
‘Unary File’ will be of exact same size as the very 1st initial original input binary data
file size throughout, ie ignoring/disregarding the earlier described small number of
parameter bit/s), then next ‘file size reduction’ process will produce a ‘Reduced
File’ with file size always less than or at very worst equal to the file size of the present
iteration's input file & IF there are now maximum number of bits present in any
consecutive bit/s (all of same binary value) greater than the specified maximum
number (eg 3...etc) in this ‘file size reduction’ iteration's resultant new ‘Reduced
File’ then the overall process flow will start again at the beginning of the ‘unary
representation’ process above with this iteration's resultant new ‘Reduced File’ used
as input file, OTHERWISE the overall process flow will iterate again in ‘file size
reduction’ process with this iteration's resultant new ‘Reduced File’ used as input file:
This overall process flow repeatedly iterates UNTIL certain specified criteria is
attained eg certain specified compression ratio is achieved, or eg file size is reduced to
certain specified size, or eg there remains not more than a specified total number of all
consecutive 3 bits of same binary value in the latest iteration's ‘Reduced File’...
/************************ END *********************************/
```

Here is another new powerful lossless compression method:

1. Uses ‘unextended’ number representation system/s (ie as described earlier BUT without needing to use/represent ‘extend’ symbol) sufficient to cover/represent number equal to ‘specified’ max number of consecutive bits present in the input file, eg if there are only max number of consecutive bits of 4 present in the input file THEN the ‘unextended’ number representation system could be eg 0->1 10->2 110->3 111->4 (‘111’->4 here gained 1 bit reduction, ie recording/representing eg 4 consecutive bits in the input file as 3 bits in the resultant ‘Number File’) . . . likewise similar ‘unextended’ number representation system could be designed/selected sufficient to cover/represent N maximum number of consecutive bits . . . etc.
2. Complete set of ‘unextended’ number representation systems to successively iteratively represent maximum number of eg 4 then 3 then 2 consecutive bits (ie from N maximum number down to 2 maximum number) could be designed/selected: eg 0->1 10->2 110->3 111->4 (111->4 here gained 1 bit reduction, ie recording/representing eg 4 consecutive bits in the input file as 3 bits in the resultant ‘Number File’), then 0->1 10->2 11->3 (‘11->3 here gained 1 bit reduction, ie recording/representing eg 3 consecutive bits in the input file as 2 bits in the resultant ‘Number File’), then now with only maximum consecutive of 2 bits in the latest input ‘Number File’ use 0->1 1->2 (‘1’->2 here gained 1 bit reduction, ie recording/representing eg 2 consecutive bits in the input file as 1 bits in the resultant ‘Number File’).

An ‘unextended number representation’ process iteration's resultant ‘Number File’ size will always be of less than or at very worst equal to the iteration's input file size: needs just pre-arrange to use pre-agreed ‘unextended’ number system/s which has smallest sufficient ‘symbols sets’ to first cover/represent number up to N, then which has smallest sufficient ‘symbols sets’ to cover/represent number up to N−1, then which has smallest sufficient ‘symbols sets’ to cover/represent number up to N−2, . . . & so forth . . . then which has smallest sufficient ‘symbols sets’ to cover/represent number up to specified number eg 2 . . . etc.

In cases where this ‘unextended number representation’ process iteration's new resultant ‘Number File’ is equal (or very very close to) in size to the size of the input file, this invariably signifies the resultant new ‘Number File’ consists only of very basic bit/s pattern/s repeated many many time throughout the resultant new ‘Number File’, & would be ideal to now for a different & appropriate algorithm to be next ‘selected’ to next reduce the file size by magnitude orders: eg resultant new ‘Number File’ may now likely simply consists of regular continuous successive ‘alternating’ ‘switched’ bits pattern of single ‘0’ bit & single ‘1’ bit (ie an appropriate algorithm here could simply be eg Run Length type algorithm which compresses entire file as ‘10’ bits pattern or ‘01’ bits pattern repeated a specified number of times, &/or plus a single ‘end bit value’ . . . etc).

3. Starting from the very initial 1^{st} consecutive bit/s to the last consecutive bit/s in the original input binary data file, the number of consecutive bit/s at each successive sequential consecutive bit/s is successively recorded/represented in the resultant ‘Number File’ using ‘unextended’ number representation system which has smallest sufficient ‘symbols set’ to cover/represent number up to the maximum number of N consecutive bits present in the original input binary data file.

Note an extra costs single bit needs be provided to indicate the very initial 1^{st} starting consecutive bit/s' binary value in the very initial 1^{st} original input file (it could also optionally record/indicate such extra costs single bit for each & every of all iterations, as parameters of the overall ‘unextended number representation’ process iterations! BUT this is unnecessary). This single bit parameter indicating the very initial 1^{st} starting consecutive bit/s' binary value in the very initial 1^{st} original input file could be stored/or transmitted to remote receiver separately from the final ‘Number File’, or be optionally pre-appended to the overall ‘unextended number representation’ process iterations resultant final ‘Number File’ & stored/or transmitted to remote receiver. This extra costs of only 1 single bit in the overall whole complete ‘unextended number representation’ process iterations will hereinafter conveniently be completely ignored/disregarded in all subsequent calculations/discussions on compression ratio efficiency.

Note it is not necessary to provide/store all the very 1^{st} consecutive bit/s' binary value in each & every of all the iterations' input files! since during each & every of all the lossless reconstruction iterations the reconstruction process at each iteration could simply ‘assume as either 0 or 1’ or even ‘wrongly guess either 0 or 1’ any of the reconstruction iterations' resultant file's very 1^{st} consecutive bit/s' binary value: when all the lossless reconstruction iterations are completed, the final reconstruction iterations' eventual resultant file's very 1^{st} consecutive bit/s' binary value is compared to the provided/stored parameter of the binary value of the very initial 1^{st} original input binary data file, IF both indicates the same binary value then all is fine & the very initial 1^{st} original input binary data file has been losslessly reconstructed faithfully, OTHERWISE each & everyone of all the bits' binary value in the reconstruction iterations' final resultant file will be ‘swapped’/‘switched’ to be of opposite binary value & this will now provide the required lossless faithful reconstruction of the very initial 1^{S}′ original input binary data file. This is so because each & every of all the ‘unary representation’ process iterations & each & every of all the lossless reconstruction process ‘reverse flow’ iterations here will always produce either a correct resultant file or a ‘correct but reversed bits’ resultant file with each & every bits' having the ‘reversed’ opposite binary value as the correct resultant file.

4. This previous iteration's resultant ‘Number File’ in Paragraph 3 above will now next be used as input file in subsequent next iteration (described in Paragraph 3), this time using ‘unextended’ number representation system which has smallest sufficient ‘symbols sets’ (ie symbol sets requiring the least number of bit/s, eg number representation system 0->1 10->2 11->3 requires only at most 2 bits, ie ‘11’, to represent 3 consecutive bits in the input file) to cover/represent up to the maximum number of now M consecutive bits present in this iteration's input file . . . & so forth UNTIL some specified criteria is reached eg the maximum number of consecutive bit/s in the iteration's resultant final ‘Number File’ is exactly eg 1 or 2 . . . etc, or certain specified compression ratio efficiency is attained, or the resultant final file size has been compressed to less than certain specified size . . . etc. Note the maximum number of M consecutive bits present in the previous iteration's resultant ‘Number File (which subsequently now becomes the next iteration's input file) could be larger than the maximum number of N consecutive bits present in the previous iteration's input file, ie it may be that now M>N (the maximum number M consecutive bits in the input file of an iteration could be ascertained by first examining the input file itself): IF so this subsequent next ‘unextended number representation’ iteration will now use using an ‘unextended’ number representation system which has smallest sufficient ‘symbols sets’ (ie this symbols set which now requiring the least number of bit/s to represent maximum number of M consecutive bits in the input file) to cover/represent up to the maximum number of now M consecutive bits present in this iteration's input file.
5. To lossless faithfully reconstruct the very initial 1^{st} original input binary data file, just need to provide the overall ‘unextended number representation’ process iterations resultant final ‘Number File’, together with parameters set/s of the overall iterations which should at least includes the very initial maximum number of consecutive bits present in the very initial 1^{st} original input binary data file used in the very 1^{st} ‘unextended number representation’ process iteration, & the extra costs single bit parameter value needed to indicate the very initial 1^{st} starting consecutive bit/s' binary value in the very initial 1^{st} original input binary data file used in the very 1^{st} ‘unextended number representation’ iteration. Other parameters could be included such as the total number of ‘unextended number representation’ iterations, the overall ‘unextended number representation’ process iterations' ‘specified’ ‘stop’ maximum consecutive bits number, (if any) the parameters regarding the different appropriate algorithm/s ‘selected’ to be used in a particular iteration stage . . . etc.

```
/**************** OUTLINE REFINED SUMMARY *******************/
8. Methods or sub-component method step/s for lossless data compressions, said
  methods or sub-component method step/s:
  uses number representation system/s as described in earlier Methods
  Starting from the very initial 1^{st} consecutive bit/s to the last consecutive bit/s in
the original input binary data file, the number of consecutive bit/s at each successive
sequential consecutive bit/s is successively recorded/represented in the resultant
‘Number File’ using above number representation system which has smallest
sufficient ‘symbols set’ to cover/represent number up to the maximum number of
consecutive bits present in the original input binary data file
    OPTIONALLY an extra costs single bit needs be provided to indicate the very
initial 1^{st} starting consecutive bit/s’ binary value in the very initial 1^{st} original input
file (it could also optionally record/indicate such extra costs single bit for each &
every of all iterations, as parameters of the overall number representation’ process
iterations ! BUT this is unnecessary), this single bit parameter indicating the very
initial 1^{st} starting consecutive bit/s’ binary value in the very initial 1^{st} original input file
could be stored separately from the final ‘Number File’, or be optionally pre-
appended to the overall number representation process iterations resultant final
‘Number File’
    This previous iteration's resultant ‘Number File’ in Paragraph 3 above will now next
be used as input file in subsequent next iteration, this time using number
representation system which has smallest sufficient ‘symbols sets’ (ie symbol sets
requiring the least number of bit/s, eg number representation system 0->1 10->2 11->
3 requires only at most 2 bits, ie ‘11’, to represent 3 consecutive bits in the input
file) to cover/represent up to the maximum number of now M consecutive bits
present in this iteration's input file .....& so forth UNTIL some specified criteria is
reached eg the maximum number of consecutive bit/s in the iteration's resultant final
‘Number File’ is exactly eg 1 or 2 ...etc, or certain specified compression ratio
efficiency is attained, or the resultant final file size has been compressed to less than
certain specified size...etc:
Note the maximum number of M consecutive bits present in the previous iteration's
resultant ‘Number File (which subsequently now becomes the next iteration's input
file) could be larger than the maximum number of N consecutive bits present in the
previous iteration's input file, ie it may be that now M > N (the maximum number M
consecutive bits in the input file of an iteration could be ascertained by first
examining the input file itself): IF so this subsequent next ‘unextended number
representation’ iteration will now use a number representation system which has
smallest sufficient ‘symbols sets’ (ie this symbols set which now requiring the least
number of bit/s to represent maximum number of M consecutive bits in the input file)
to cover/represent up to the maximum number of now M consecutive bits present
in this iteration's input file.
9. Methods or sub-component method step/s for lossless reconstruction of
    compressed data as described in earlier Methods, said methods or sub-
    component method step/s here:
    To lossless faithfully reconstruct the very initial 1^{st} original input binary data
file, just need to provide the overall number representation process iterations
resultant final ‘Number File’, together with parameters set/s of the overall iterations
which should at least includes the very initial maximum number of consecutive bits
present in the very initial 1^{st} original input binary data file used in the very 1^{st}
‘number representation process iteration, & the extra costs single bit parameter value
needed to indicate the very initial 1^{st} starting consecutive bit/s’ binary value in the
very initial 1^{st} original input binary data file used in the very 1^{st} ‘number
representation iteration: Other parameters could be included such as the total number
of number representation iterations, the overall number representation process
iterations’ ‘specified’ ‘stop’ maximum consecutive bits number, (if any) the
parameters regarding the different appropriate algorithm/s ‘selected’ to be used in a
particular iteration stage.
/************************ END *********************************/
```

Here is another variant, among many possible, of above immediately preceding described new powerful lossless compression method:

1. Uses ‘unextended’ number representation system/s (ie as described earlier BUT without needing to use/represent ‘extend’ symbol) sufficient to cover/represent number equal to ‘specified’ max number of consecutive bits present in the input file, eg if there are only max number of consecutive bits of 4 present in the input file THEN the ‘unextended’ number representation system could be eg 0->1 10->2 110->3 111->4 (‘111’->4 here gained 1 bit reduction, ie recording/representing eg 4 consecutive bits in the input file as 3 bits in the resultant ‘Number File’) . . . likewise similar ‘unextended’ number representation system could be designed/selected sufficient to cover/represent N maximum number of consecutive bits . . . etc.
2. Complete set of ‘unextended’ number representation systems to successively iteratively represent maximum number of eg 4 then 3 then 2 consecutive bits (ie from N maximum number down to 2 maximum number) could be designed/selected: eg 0->1 10->2 110->3 111->4 (111->4 here gained 1 bit reduction, ie recording/representing eg 4 consecutive bits in the input file as 3 bits in the resultant ‘Number File’), then 0->1 10->2 11->3 (‘11->3 here gained 1 bit reduction, ie recording/representing eg 3 consecutive bits in the input file as 2 bits in the resultant ‘Number File’), then now with only maximum consecutive of 2 bits in the latest input ‘Number File’ use 0->1 1->2 (‘1’->2 here gained 1 bit reduction, ie recording/representing eg 2 consecutive bits in the input file as 1 bits in the resultant ‘Number File’).

An ‘unextended number representation’ process iteration's resultant ‘Number File’ size will always be of less than or at very worst equal to the iteration's input file size: needs just pre-arrange to use pre-agreed ‘unextended’ number system/s which has smallest sufficient ‘symbols sets’ to first cover/represent number up to N, then which has smallest sufficient ‘symbols sets’ to cover/represent number up to N−1, then which has smallest sufficient ‘symbols sets’ to cover/represent number up to N−2, & so forth then which has smallest sufficient ‘symbols sets’ to cover/represent number up to specified number eg 2 . . . etc.

In cases where this ‘unextended number representation’ process iteration's new resultant ‘Number File’ is equal (or very very close to) in size to the size of the input file, this invariably signifies the resultant new ‘Number File’ consists only of very basic bit/s pattern/s repeated many many time throughout the resultant new ‘Number File’, & would be ideal to now for a different & appropriate algorithm to be next ‘selected’ to next reduce the file size by magnitude orders: eg resultant new ‘Number File’ may now likely simply consists of regular continuous successive ‘alternating’ ‘switched’ bits pattern of single ‘0’ bit & single ‘1’ bit (ie an appropriate algorithm here could simply be eg Run Length type algorithm which compresses entire file as ‘10’ bits pattern or ‘01’ bits pattern repeated a specified number of times, &/or plus a single ‘end bit value’ . . . etc).

3. Starting from the very initial 1^{st} consecutive bit/s to the last consecutive bit/s in the original input binary data file, the number of consecutive bit/s at each successive sequential consecutive bit/s is successively recorded/represented in the resultant ‘Number File’ using ‘unextended’ number representation system which has smallest sufficient ‘symbols set’ to cover/represent number up to the maximum number of N consecutive bits present in the original input binary data file.

Note an extra costs single bit needs be provided to indicate the very initial 1^{st} starting consecutive bit/s' binary value in the very initial 1^{st} original input file (it could also optionally record/indicate such extra costs single bit for each & every of all iterations, as parameters of the overall ‘unextended number representation’ process iterations! BUT this is unnecessary). This single bit parameter indicating the very initial 1^{st} starting consecutive bit/s' binary value in the very initial 1^{st} original input file could be stored/or transmitted to remote receiver separately from the final ‘Number File’, or be optionally pre-appended to the overall ‘unextended number representation’ process iterations resultant final ‘Number File’ & stored/or transmitted to remote receiver. This extra costs of only 1 single bit in the overall whole complete ‘unextended number representation’ process iterations will hereinafter conveniently be completely ignored/disregarded in all subsequent calculations/discussions on compression ratio efficiency.

Note it is not necessary to provide/store all the very 1^{st} consecutive bit/s' binary value in each & every of all the iterations' input files! since during each & every of all the lossless reconstruction iterations the reconstruction process at each iteration could simply ‘assume as either 0 or 1’ or even ‘wrongly guess either 0 or 1’ any of the reconstruction iterations' resultant file's very 1^{st} consecutive bit/s' binary value: when all the lossless reconstruction iterations are completed, the final reconstruction iterations' eventual resultant file's very 1^{st} consecutive bit/s' binary value is compared to the provided/stored parameter of the binary value of the very initial 1^{st} original input binary data file, IF both indicates the same binary value then all is fine & the very initial 1^{st} original input binary data file has been losslessly reconstructed faithfully, OTHERWISE each & everyone of all the bits' binary value in the reconstruction iterations' final resultant file will be ‘swapped’/‘switched’ to be of opposite binary value & this will now provide the required lossless faithful reconstruction of the very initial 1^{st} original input binary data file. This is so because each & every of all the ‘unary representation’ process iterations & each & every of all the lossless reconstruction process ‘reverse flow’ iterations here will always produce either a correct resultant file or a ‘correct but reversed bits’ resultant file with each & every bits' having the ‘reversed’ opposite binary value as the correct resultant file.

4. This previous iteration's resultant ‘Number File’ in Paragraph 3 above will now next be used as input file in subsequent next iteration (described in Paragraph 3), this time using ‘unextended’ number representation system which has smallest sufficient ‘symbols sets’ (ie symbol sets requiring the least number of bit/s, eg number representation system 0->1 10->2 11->3 requires only at most 2 bits, ie ‘11’, to represent 3 consecutive bits in the input file) to cover/represent up to the maximum number of now M consecutive bits present in this iteration's input file . . . & so forth UNTIL some specified criteria is reached eg the maximum number of consecutive bit/s in the iteration's resultant final ‘Number File’ is exactly eg 1 or 2 . . . etc, or certain specified compression ratio efficiency is attained, or the resultant final file size has been compressed to less than certain specified size . . . etc. Note the maximum number of M consecutive bits present in the previous iteration's resultant ‘Number File (which subsequently now becomes the next iteration's input file) could be larger than the maximum number of N consecutive bits present in the previous iteration's input file, ie it may be that now M>N (the maximum number M consecutive bits in the input file of an iteration could be ascertained by first examining the input file itself): IF so this subsequent next ‘unextended number representation’ iteration will now use using an ‘unextended’ number representation system which has smallest sufficient ‘symbols sets’ (ie this symbols set which now requiring the least number of bit/s to represent maximum number of M consecutive bits in the input file) to cover/represent up to the maximum number of now M consecutive bits present in this iteration's input file. Whenever M the maximum number of consecutive bits present in the latest iteration's resultant file becomes >=the maximum number of consecutive bits present in the latest iteration's input file THEN the particular iteration number/identification & the particular iteration's parameter M of maximum number of consecutive bits present in the latest iteration's resultant file needs be recorded/conveyed eg pre-appended to the resultant file at pre-specified initial bits positions OR separately stored/transmitted to remote receiver. Or each & every iterations' number/identification & corresponding maximum number of consecutive bits present in the latest iteration's resultant file could simply be all recorded/conveyed eg pre-appended to the resultant file at pre-specified initial bits positions OR separately stored/transmitted to remote receiver.
5. To lossless faithfully reconstruct the very initial 1^{st} original input binary data file, just need to provide the overall ‘unextended number representation’ process iterations resultant final ‘Number File’, together with parameters set/s of the overall iterations which should at least includes the very initial maximum number of consecutive bits present in the very initial 1^{st} original input binary data file used in the very 1^{st} ‘unextended number representation’ process iteration, & the extra costs single bit parameter value needed to indicate the very initial 1^{st} starting consecutive bit/s' binary value in the very initial 1^{st} original input binary data file used in the very 1st ‘unextended number representation’ iteration. Other parameters could be included such as the total number of ‘unextended number representation’ iterations, each & every iterations' corresponding parameter M (or only certain particular iteration/s′ number/identification together with their corresponding parameter M, ie when the iteration's resultant file's maximum number of consecutive bits >=the iteration's input file's maximum number of consecutive bits), the overall ‘unextended number representation’ process iterations’ ‘specified’ ‘stop’ maximum consecutive bits number, (if any) the parameters regarding the different appropriate algorithm/s ‘selected’ to be used in a particular iteration stage . . . etc.

Here is another variant, among many possible, of above immediately preceding described new powerful lossless compression method:

1. Uses ‘unextended’ number representation system/s (ie as described earlier BUT without needing to use/represent ‘extend’ symbol) sufficient to cover/represent number equal to ‘specified’ max number of consecutive bits present in the input file, eg if there are only max number of consecutive bits of 4 present in the input file THEN the ‘unextended’ number representation system could be eg 0->1 10->2 110->3 111->4 (‘111’->4 here gained 1 bit reduction, ie recording/representing eg 4 consecutive bits in the input file as 3 bits in the resultant ‘Number File’) . . . likewise similar ‘unextended’ number representation system could be designed/selected sufficient to cover/represent N maximum number of consecutive bits . . . etc. If there are at most N maximum number of consecutive bits all of same binary value in the input file, then the ‘unextended’ number representation system could be eg 0->1 10->2 110->3 1110->4 11110->5 111110->6 & so forth (N−2) number of leading ‘1’s followed by the end marker/delimiter bit of ‘0’->N−1 & eventually N−1 number of all ‘1’s->N, OR its ‘complement’ eg 1->1 01->2 001->3 0001->4 00001->5 000001->6 & so forth (N−2) number of leading ‘1’s followed by the end marker/delimiter bit of ‘0’->N−1 & eventually N−1 number of all ‘1’s->N.
2. Complete set of ‘unextended’ number representation systems to successively iteratively represent maximum number of eg 4 then 3 then 2 consecutive bits (ie from N maximum number down to 2 maximum number) could be designed/selected: eg 0->1 10->2 110->3 11′->4 (111->4 here gained 1 bit reduction, ie recording/representing eg 4 consecutive bits in the input file as 3 bits in the resultant ‘Number File’), then 0->1 10->2 11->3 (‘11->3 here gained 1 bit reduction, ie recording/representing eg 3 consecutive bits in the input file as 2 bits in the resultant ‘Number File’), then now with only maximum consecutive of 2 bits in the latest input ‘Number File’ use 0->1 1->2 (‘1’->2 here gained 1 bit reduction, ie recording/representing eg 2 consecutive bits in the input file as 1 bits in the resultant ‘Number File’).

An ‘unextended number number representation’ process iteration's resultant ‘Number File’ size will always be of less than or at very worst equal to the iteration's input file size: needs just pre-arrange to use pre-agreed ‘unextended’ number system/s which has smallest sufficient ‘symbols sets’ to first cover/represent number up to N, then which has smallest sufficient ‘symbols sets’ to cover/represent number up to N−1, then which has smallest sufficient ‘symbols sets’ to cover/represent number up to N−2, & so forth then which has smallest sufficient ‘symbols sets’ to cover/represent number up to specified number eg 2 . . . etc.

In cases where this ‘unextended number representation’ process iteration's new resultant ‘Number File’ is equal (or very very close to) in size to the size of the input file, this invariably signifies the resultant new Number File consists only of very basic bit/s pattern/s repeated many many time throughout the resultant new ‘Number File’, & would be ideal to now for a different & appropriate algorithm to be next ‘selected’ to next reduce the file size by magnitude orders: eg resultant new ‘Number File’ may now likely simply consists of regular continuous successive ‘alternating’ ‘switched’ bits pattern of single ‘0’ bit & single ‘1’ bit (ie an appropriate algorithm here could simply be eg Run Length type algorithm which compresses entire file as ‘10’ bits pattern or ‘01’ bits pattern repeated a specified number of times, &/or plus a single ‘end bit value’ . . . etc).

3. Starting from the very initial 1^{st} consecutive bit/s to the last consecutive bit/s in the original input binary data file, the number of consecutive bit/s at each successive sequential consecutive bit/s is successively recorded/represented in the resultant ‘Number File’ using ‘unextended’ number representation system which has smallest sufficient ‘symbols set’ to cover/represent number up to the maximum number of N consecutive bits present in the original input binary data file.

Note an extra costs single bit needs be provided to indicate the very initial 1^{st} starting consecutive bit/s' binary value in the very initial 1^{st} original input file (it could also optionally record/indicate such extra costs single bit for each & every of all iterations, as parameters of the overall ‘unextended number representation’ process iterations! BUT this is unnecessary). This single bit parameter indicating the very initial 1^{st} starting consecutive bit/s' binary value in the very initial 1^{st} original input file could be stored/or transmitted to remote receiver separately from the final ‘Number File’, or be optionally pre-appended to the overall ‘unextended number representation’ process iterations resultant final ‘Number File’ & stored/or transmitted to remote receiver. This extra costs of only 1 single bit in the overall whole complete ‘unextended number representation’ process iterations will hereinafter conveniently be completely ignored/disregarded in all subsequent calculations/discussions on compression ratio efficiency.

Note it is not necessary to provide/store all the very 1^{st} consecutive bit/s' binary value in each & every of all the iterations' input files! since during each & every of all the lossless reconstruction iterations the reconstruction process at each iteration could simply ‘assume as either 0 or 1’ or even ‘wrongly guess either 0 or 1’ any of the reconstruction iterations' resultant file's very 1^{st} consecutive bit/s' binary value: when all the lossless reconstruction iterations are completed, the final reconstruction iterations' eventual resultant file's very 1^{st} consecutive bit/s' binary value is compared to the provided/stored parameter of the binary value of the very initial 1^{st} original input binary data file, IF both indicates the same binary value then all is fine & the very initial 1^{st} original input binary data file has been losslessly reconstructed faithfully, OTHERWISE each & everyone of all the bits' binary value in the reconstruction iterations' final resultant file will be ‘swapped’/‘switched’ to be of opposite binary value & this will now provide the required lossless faithful reconstruction of the very initial 1^{st} original input binary data file. This is so because each & every of all the ‘unary representation’ process iterations & each & every of all the lossless reconstruction process ‘reverse flow’ iterations here will always produce either a correct resultant file or a ‘correct but reversed bits’ resultant file with each & every bits' having the ‘reversed’ opposite binary value as the correct resultant file.

4. This previous iteration's resultant ‘Number File’ in Paragraph 3 above will now next be used as input file in subsequent next iteration (described in Paragraph 3), this time using ‘unextended’ number representation system which has smallest sufficient ‘symbols sets’ (ie symbol sets requiring the least number of bit/s, eg number representation system 0->1 10->2 11->3 requires only at most 2 bits, ie ‘11’, to represent 3 consecutive bits in the input file) to cover/represent up to the maximum number of now N−1 consecutive bits present in this iteration's input file . . . & so forth (successive iterations to cover/represent up to the maximum number of initially N then now N−1, N−2, N−3 N−(N−2) consecutive bits . . . & so forth) UNTIL some specified criteria is reached eg the maximum number of consecutive bit/s in the iteration's resultant final ‘Number File’ is exactly eg 1 or 2 . . . etc, or certain specified compression ratio efficiency is attained, or the resultant final file size has been compressed to less than certain specified size . . . etc. Note the actual maximum number of M consecutive bits present in the previous iteration's resultant ‘Number File (which subsequently now becomes the next iteration's input file) could be larger than the maximum number of N consecutive bits present in the previous iteration's input file, ie it may be that now M>N (the maximum number M consecutive bits in the input file of an iteration could be ascertained by first examining the input file itself): EVEN IF so this subsequent next ‘unextended number representation’ iteration will still not be required to now use an ‘unextended’ number representation system which has smallest sufficient ‘symbols sets’ (ie this symbols set which now requiring the least number of bit/s to represent maximum number of M consecutive bits in the input file) to cover/represent up to the maximum number of now M consecutive bits present in this iteration's input file, this iteration could SIMPLY assume any consecutive number of bits >N−1 (all of same binary value) present in this iteration's input file to be composed of an integer multiple of N−1 consecutive bits PLUS a ‘remainder’ number of consecutive bits <N−1 (all of same binary value), & thus able to sequential successively utilise ‘unextended number representation’ system/s which has smallest sufficient ‘symbols sets’ to cover/represent up to the maximum number of initially N then now N−1, N−2, N−3 . . . . N−(N−2) consecutive bits present in each subsequent successive iteration's input file→its now obvious that the total number of iterations will only be at most N−1 (ie total of N−1 iterations, each successive iterations uses ‘unextended number representation’ system/s sufficient to cover/represent initially N then now N−1, N−2, N−3 . . . N−(N−2) maximum number of consecutive bits all of same binary value in the iteration's input file, & even though during any or some of these iterations eg during iteration which uses ‘unextended number representation’ system sufficient to cover/represent N−2 maximum consecutive number of bits it is also very possible that the actual maximum number of consecutive bits (all of same binary value) present in the iteration's input file is <N−2 (on the other hand if that the actual maximum number of consecutive bits (all of same binary value) present in the iteration's input file is >N−2, this iteration could SIMPLY assume any consecutive number of bits >N−1 (all of same binary value) present in this iteration's input file to be composed of an integer multiple of N−1 consecutive bits PLUS a ‘remainder’ number of consecutive bits <N−1 (all of same binary value): NOTE this ‘remainder’ number of consecutive bit/s on its own could not represent any particular ‘unextended number representation’ number eg ‘remainder’ bit/s of eg ‘1’ needs be combined with an immediately following bit of ‘0’ in the input file to be able to concatenate form bits pattern ‘10’ to represent the number ‘2’ . . . etc.
5. To lossless faithfully reconstruct the very initial 1^{st} original input binary data file, just need to provide the overall ‘unextended number representation’ process iterations resultant final ‘Number File’, together with parameters sets of the overall iterations which should at least includes the very initial maximum number of consecutive bits present in the very initial 1^{st} original input binary data file used in the very 1^{st} ‘unextended number representation’ process iteration, & the extra costs single bit parameter value needed to indicate the very initial 1^{st} starting consecutive bit/s' binary value in the very initial 1^{st} original input binary data file used in the very 1^{st} ‘unextended number representation’ iteration. Other parameters could be included such as the total number of ‘unextended number representation’ iterations, the overall ‘unextended number representation’ process iterations' ‘specified’ ‘stop’ maximum consecutive bits number, (if any) the parameters regarding the different appropriate algorithm/s ‘selected’ to be used in a particular iteration stage . . . etc.

```
/**************** OUTLINE REFINED SUMMARY *******************/
10. Methods or sub-component method step/s for lossless data based on and
  modifying the methods or sub-component method step/s as described in earlier
  Methods, said methods or sub-component method step/s:
  OPTIONALLY the number representation system & its ‘complement’ binary
  representation system are successively alternately used to record/represent
  successive consecutive bit/s all of same binary value
  the actual maximum number of M consecutive bits present in the previous
iteration's resultant ‘Number File (which subsequently now becomes the next
iteration's input file) could be larger than the maximum number of N consecutive bits
present in the previous iteration's input file, ie it may be that now M > N (the
maximum number M consecutive bits in the input file of an iteration could be
ascertained by first examining the input file itself), EVEN IF so this subsequent
next number representation iteration will still not be required to now use an number
representation system which has smallest sufficient ‘symbols sets’ (ie this symbols
set which now requiring the least number of bit/s to represent maximum number of M
consecutive bits in the input file) to cover/represent up to the maximum number of
now M consecutive bits present in this iteration's input file, this iteration could
SIMPLY assume any consecutive number of bits > N − 1 (all of same binary value)
present in this iteration's input file to be composed of an integer multiple of N − 1
consecutive bits PLUS a ‘remainder’ number of consecutive bits < N − 1 (all of same
binary value), & thus able to sequential successively utilise number representation
system/s which has smallest sufficient ‘symbols sets’ to cover/represent up to the
maximum number of initially N then now N − 1, N − 2, N − 3....N − (N − 2) consecutive
bits present in each subsequent successive iteration's input file → its now obvious
that the total number of iterations will only be at most N − 1 (ie total of N − 1
iterations, each successive iterations uses number representation system/s sufficient to
cover/represent initially N then now N − 1, N − 2, N − 3....N − (N − 2) maximum number of
consecutive bits all of same binary value in the iteration's input file, & even though
during any or some of these iterations eg during iteration which uses number
representation system sufficient to cover/represent N − 2 maximum consecutive
number of bits it is also very possible that the actual maximum number of consecutive
bits (all of same binary value) present in the iteration's input file is < N − 2 (on the
other hand if that the actual maximum number of consecutive bits (all of same binary
value) present in the iteration's input file is > N − 2, this iteration could SIMPLY
assume any consecutive number of bits > N − 1 (all of same binary value) present in
this iteration's input file to be composed of an integer multiple of N − 1 consecutive
bits PLUS a ‘remainder’ number of consecutive bits < N − 1 (all of same binary value):
NOTE this ‘remainder’ number of consecutive bit/s on its own could not represent
any particular number representation number eg ‘remainder’ bit/s of eg ‘1’ needs be
combined with an immediately following bit of ‘0’ in the input file to be able to
concatenate form bits pattern ‘10’ to represent the number ‘2’ ....
11.  Methods or sub-component method step/s for lossless reconstruction of
    compressed data as described in earlier Methods, said methods or sub-
    component method step/s here:
    Accept as input the overall ‘unextended number representation’ process
iterations resultant final ‘Number File’, together with parameters set/s of the overall
iterations which should at least includes the very initial maximum number of
consecutive bits present in the very initial 1^{st} original input binary data file used in
the very 1^{st} number representation process iteration, & the extra costs single bit
parameter value needed to indicate the very initial 1^{st} starting consecutive bit/s' binary
value in the very initial 1^{st} original input binary data file used in the very 1^{st} number
representation iteration, other parameters could be included such as the total number
of number representation iterations, the overall number representation process
iterations’ ‘specified’ ‘stop’ maximum consecutive bits number, (if any) the
parameters regarding the different appropriate algorithm/s ‘selected’ to be used in a
particular iteration stage
/************************ END *********************************/
```

Here is another adapted implementation, among many possible, of the above new powerful lossless compression method:

1. uses ‘unextended’ number representation system/s (ie as described earlier BUT without needing to use/represent ‘extend’ symbol) sufficient to cover/represent number equal to ‘specified’ max number of consecutive bits present in the input file, eg if there are only max number of consecutive bits of 4 present in the input file THEN the ‘unextended’ number representation system could be eg 0->1 10->2 110->3 111->4 (‘111’->4 here gained 1 bit reduction, ie recording/representing eg 4 consecutive bits in the input file as 3 bits in the resultant ‘Number File’) . . . likewise similar ‘unextended’ number representation system could be designed/selected sufficient to cover/represent N maximum number of consecutive bits . . . etc. Also needed is the ‘complement’ of the above ‘unextended number representation system’, ie an identical ‘unextended number representation’ system as above BUT with ‘reverse binary value symbols set’: ie now the symbols set comprises 1->1 01->2 001->3 000->4.
2. Complete set of ‘unextended’ number representation systems to successively iteratively represent maximum number of eg 4 then 3 then 2 consecutive bits (ie from N maximum number down to 2 maximum number) could be designed/selected: eg 0->1 10->2 110->3 111->4 (111->4 here gained 1 bit reduction, ie recording/representing eg 4 consecutive bits in the input file as 3 bits in the resultant ‘Number File’), then 0->1 10->2 11->3 (‘11->3 here gained 1 bit reduction, ie recording/representing eg 3 consecutive bits in the input file as 2 bits in the resultant ‘Number File’), then now with only maximum consecutive of 2 bits in the latest input ‘Number File’ use 0->1 1->2 (‘1’->2 here gained 1 bit reduction, ie recording/representing eg 2 consecutive bits in the input file as 1 bits in the resultant ‘Number File’). Also needed is the ‘complement’ of the above ‘unextended number representation system’, ie an identical complete set of ‘unextended number representation’ systems as above BUT with ‘reverse binary value symbols set’.

An ‘unextended number number representation’ process iteration's resultant ‘Number File’ size will always be of less than or at very worst equal to the iteration's input file size: needs just pre-arrange to use pre-agreed ‘unextended’ number system/s which has smallest sufficient ‘symbols sets’ to first cover/represent number up to N, then which has smallest sufficient ‘symbols sets’ to cover/represent number up to N−1, then which has smallest sufficient ‘symbols sets’ to cover/represent number up to N−2, & so forth then which has smallest sufficient ‘symbols sets’ to cover/represent number up to specified number eg 2 . . . etc.

In cases where this ‘unextended number representation’ process iteration's new resultant ‘Number File’ is equal (or very very close to) in size to the size of the input file, this invariably signifies the resultant new Number File consists only of very basic bit/s pattern/s repeated many many time throughout the resultant new ‘Number File’, & would be ideal to now for a different & appropriate algorithm to be next ‘selected’ to next reduce the file size by magnitude orders: eg resultant new ‘Number File’ may now likely simply consists of regular continuous successive ‘alternating’ ‘switched’ bits pattern of single ‘0’ bit & single ‘1’ bit (ie an appropriate algorithm here could simply be eg Run Length type algorithm which compresses entire file as ‘10’ bits pattern or ‘01’ bits pattern repeated a specified number of times, &/or plus a single ‘end bit value’ . . . etc).
4. Starting from the very initial 1^{st} consecutive bit/s to the last consecutive bit/s in the original input binary data file, the number of consecutive bit/s at each successive sequential consecutive bit/s is successively recorded/represented in the resultant ‘Number File’: successive alternately using ‘unextended’ number representation system which has smallest sufficient ‘symbols set’ to cover/represent number up to the maximum number of N consecutive bits present in the original input binary data file, & the ‘complement’ ‘reverse binary value symbols set’ of the above ‘unextended number representation’ system. This successive ‘alternating’ use of ‘unextended number representation’ system & its identical ‘complement’ ‘reverse binary value symbols set’ ‘unextended number representation’ system, has the effect of eliminating the possibility of larger longer max number of consecutive bits from being formed/present in the iteration's resultant ‘Number File’, due to very long sequence of successive alternating single ‘1’ & single ‘0’ bit in the iteration's input file being each successively recorded/represented in the iteration's resultant ‘Number File’ as a very long continuous series of eg single ‘0’ bit (ie larger longer max number of consecutive bits now present in the resultant ‘Number File). It could be convention pre-agreed to first use the ‘unextended number representation’ system (& not its ‘complement’ ‘reverse binary value symbols set’) to record/represent the very initial 1^{st} consecutive bit/s of the iteration's input file.

Note also it may be possible, by first using the appropriate choice of the ‘unextended number representation’ system or its ‘complement’ reverse binary value symbols set ‘unextended number representation’ system to record/represent the very initial 1^{st} consecutive bit/s of the iteration's input file, there is no need to record/represent as ‘single bit parameter’ the binary value of the very 1^{st} consecutive bit/s of the very initial 1^{st} original input binary data file used in the very 1^{st} ‘unextended number representation’ process iteration: ie to convention pre-agree to first use the ‘one’ which employs the same symbol value (‘0’ or ‘1’) as the binary value of the very 1^{st} consecutive bit/s in the iteration's input file to represent 1 single consecutive bit.

Note an extra costs single bit needs be provided to indicate the very initial 1^{st} starling consecutive bit/s' binary value in the very initial 1^{st} original input file (it could also optionally record/indicate such extra costs single bit for each & every of all iterations, as parameters of the overall ‘unextended number representation’ process iterations! BUT this is unnecessary). This single bit parameter indicating the very initial 1^{st} starting consecutive bit/s' binary value in the very initial 1^{st} original input file could be stored/or transmitted to remote receiver separately from the final ‘Number File’, or be optionally pre-appended to the overall ‘unextended number representation’ process iterations resultant final ‘Number File’ & stored/or transmitted to remote receiver. This extra costs of only 1 single bit in the overall whole complete ‘unextended number representation’ process iterations will hereinafter conveniently be completely ignored/disregarded in all subsequent calculations/discussions on compression ratio efficiency.

Note it is not necessary to provide/store all the very 1^{st} consecutive bit/s' binary value in each & every of all the iterations' input files! since during each & every of all the lossless reconstruction iterations the reconstruction process at each iteration could simply ‘assume as either 0 or 1’ or even ‘wrongly guess either 0 or 1’ any of the reconstruction iterations' resultant file's very 1^{st} consecutive bit/s' binary value: when all the lossless reconstruction iterations are completed, the final reconstruction iterations' eventual resultant file's very 1^{st} consecutive bit/s' binary value is compared to the provided/stored parameter of the binary value of the very initial 1^{st} original input binary data file, IF both indicates the same binary value then all is fine & the very initial 1^{st} original input binary data file has been losslessly reconstructed faithfully, OTHERWISE each & everyone of all the bits' binary value in the reconstruction iterations' final resultant file will be ‘swapped’/‘switched’ to be of opposite binary value & this will now provide the required lossless faithful reconstruction of the very initial 1^{st} original input binary data file. This is so because each & every of all the ‘unary representation’ process iterations & each & every of all the lossless reconstruction process ‘reverse flow’ iterations here will always produce either a correct resultant file or a correct but reversed bits' resultant file with each & every bits' having the ‘reversed’ opposite binary value as the correct resultant file.

4. This previous iteration's resultant ‘Number File’ in Paragraph 3 above will now next be used as input file in subsequent next iteration (described in Paragraph 3), this time using ‘unextended’ number representation system which has smallest sufficient ‘symbols sets’ (ie symbol sets requiring the least number of bit/s, eg number representation system 0->1 10->2 11->3 requires only at most 2 bits, ie ‘11’, to represent 3 consecutive bits in the input file) to cover/represent up to the maximum number of now M consecutive bits present in this iteration's input file . . . & so forth UNTIL some specified criteria is reached eg the maximum number of consecutive bit/s in the iteration's resultant final ‘Number File’ is exactly eg 1 or 2 . . . etc, or certain specified compression ratio efficiency is attained, or the resultant final file size has been compressed to less than certain specified size . . . etc. Note the maximum number of M consecutive bits present in the previous iteration's resultant ‘Number File (which subsequently now becomes the next iteration's input file) could be larger than the maximum number of N consecutive bits present in the previous iteration's input file, ie it may be that now M>N (the maximum number M consecutive bits in the input file of an iteration could be ascertained by first examining the input file itself): IF so this subsequent next ‘unextended number representation’ iteration will now use using an ‘unextended’ number representation system which has smallest sufficient ‘symbols sets’ (ie this symbols set which now requiring the least number of bit/s to represent maximum number of M consecutive bits in the input file) to cover/represent up to the maximum number of now M consecutive bits present in this iteration's input file.
5. To lossless faithfully reconstruct the very initial 1^{st} original input binary data file, just need to provide the overall ‘unextended number representation’ process iterations resultant final ‘Number File’, together with parameters set/s of the overall iterations which should at least includes the very initial maximum number of consecutive bits present in the very initial 1^{st} original input binary data file used in the very 1^{st} ‘unextended number representation’ process iteration, & the extra costs single bit parameter value needed to indicate the very initial 1^{st} starting consecutive bit/s' binary value in the very initial 1^{st} original input binary data file used in the very 1^{st} ‘unextended number representation’ iteration. Other parameters could be included such as the total number of ‘unextended number representation’ iterations, the overall ‘unextended number representation’ process iterations' ‘specified’ ‘stop’ maximum consecutive bits number, (if any) the parameters regarding the different appropriate algorithm/s ‘selected’ to be used in a particular iteration stage . . . etc.

Lossless faithful reconstruction of the very initial 1^{st} original binary data file in all the methods described in the Description Body above basically comprises simple ‘reverse’ flow iterations of the compression iterations flow.

```
/**************** OUTLINE REFINED SUMMARY *******************/
12. Methods or sub-component method step/s for lossless data based on and
  modifying the methods or sub-component method step/s as described in earlier
  Methods, said methods or sub-component method step/s:
  uses number representation system/s sufficient to cover/represent number
equal to ‘specified’ max number of consecutive bits present in the input file, eg if
there are only max number of consecutive bits of 4 present in the input file THEN the
number representation system could be eg 0->1 10->2 110->3 111->4 (‘111’->4
here gained 1 bit reduction, ie recording/representing eg 4 consecutive bits in the
input file as 3 bits in the resultant ‘Number File’) ...likewise similar number
representation system could be designed/selected sufficient to cover/represent N
maximum number of consecutive bits..... etc, also needed is the ‘complement’ of the
above number representation system’, ie an identical number representation system
as above BUT with ‘reverse binary value symbols set’: ie now the symbols set
comprises 1->1 01->2 001->3 000->4.
  Starting from the very initial 1^{st} consecutive bit/s to the last consecutive bit/s in
  the original input binary data file, the number of consecutive bit/s at each
  successive sequential consecutive bit/s is successively recorded/represented in the
  resultant ‘Number File’: successive alternately using number representation
  system which has smallest sufficient ‘symbols set’ to cover/represent number up
  to the maximum number of N consecutive bits present in the original input binary
  data file, & the ‘complement’ ‘reverse binary value symbols set’ of the above
  number representation system
  OPTIONALLY It could be convention pre-agreed to first use the ‘unextended
number representation’ system (& not its ‘complement’ ‘reverse binary value
symbols set’) to record/represent the very initial 1^{st} consecutive bit/s of the
iteration's input file.
  OPTIONALLY by first using the appropriate choice of the number
representation system or its ‘complement’ ‘reverse binary value symbols set’ number
representation system to record/represent the very initial 1^{st} consecutive bit/s of the
iteration's input file, there is no need to record/represent as ‘single bit parameter’ the
binary value of the very 1^{st} consecutive bit/s of the very initial 1^{st} original input binary
data file used in the very 1^{st} number representation process iteration: ie to
convention pre-agree to first use the ‘one’ which employs the same symbol value (‘0’ or
‘1’) as the binary value of the very 1^{st} consecutive bit/s in the iteration's input file
to represent 1 single consecutive bit.
/************************ END *********************************/
```

Any combination of the methods/any combination of various sub-component/s of the methods (also any combination of various other existing state of art methods)/any combination of method ‘steps’, may be combined/interchanged/adapted/modified/replaced/added/improved upon to give many different implementations.

As an example variant adaptation, among many possible, is as follows:

This scheme is similar to earlier disclosed sub-component technique which ‘successive alternately switched’ binary value recordings to denote eg ‘1 single consecutive bit’, & could be utilised in its place where appropriate & suitably modified. Starting from the initial very 1^{st} consecutive bit/s pattern (which could be either a single ‘1’ or a single ‘0’ or a plurality of ‘1’s or a plurality of ‘0’s) to the very last Nth consecutive bit/s pattern in the ‘input file’, each sequential successive bit/s pattern in the ‘input file’ could be identified by its ‘position #’ (from initial position #1, to position #2, to position #3 . . . . & so forth . . . to position #N). Each bit/s pattern would have either ‘odd’ or ‘even’ position #. It could be pre-arranged so that should the bit/s pattern at the ‘odd’ position # consists of just a single bit pattern of either 1 single ‘0’ or 1 single ‘1’ (alternatively . . . if consists of just exact bits pattern of ‘10’ of exact length 2 bits . . . etc) then eg a single ‘1’ bit could be ‘expected’ to recorded into the ‘resultant file’ to denote this OTHERWISE eg a single ‘0’ bit or even some number representation system which has initial very 1st leading ‘0’ bit could be recorded into the ‘resultant file’, AND should the bit/s pattern at the ‘even’ position # consists of just a single bit pattern of either 1 single ‘0’ or 1 single ‘1’ (alternatively . . . if consists of just exact bits pattern of ‘10’ of exact length 2 bits . . . etc) then eg a single ‘0’ bit could be ‘expected’ to recorded into the ‘resultant file’ to denote this OTHERWISE eg a single ‘1’ bit or even some number representation system which has initial very 1^{st} leading ‘1’ bit could be recorded into the ‘resultant file’. Further it could also optionally be pre-arranged so that were any immediately preceding bit/s pattern consists of a plurality of consecutive bits, then this present current bit/s pattern would now be ‘expected’ instead to utilise a single bit of same ‘expected’ binary value corresponding to that of the immediately preceding bits pattern position # . . . etc.

```
/**************** OUTLINE REFINED SUMMARY *******************/
13. Methods or sub-component method step/s for lossless data based on and
  modifying the methods or sub-component method step/s as described in earlier
  Methods, said methods or sub-component method step/s:
  Starting from the very initial 1^{st} consecutive bit/s to the last consecutive bit/s in
  the original input binary data file, the number of consecutive bit/s at each
  successive sequential consecutive bit/s is successively recorded/represented in the
  resultant ‘Number File’: successive alternately using number representation
  system which has smallest sufficient ‘symbols set’ to cover/represent number up
  to the maximum number of N consecutive bits present in the original input binary
  data file, & the ‘complement’ ‘reverse binary value symbols set’ of the above
  number representation system
  uses ‘successive alternately switched’ binary value recordings to denote eg ‘1
  single consecutive bit’, starting from the initial very 1^{st} consecutive bit/s pattern
  (which could be either a single ‘1’ or a single ‘0’ or a plurality of ‘1’s or a plurality
  of ‘0’s) to the very last Nth consecutive bit/s pattern in the ‘input file’, each
  sequential successive bit/s pattern in the ‘input file’ is identified by its ‘position #’
  (from initial position #1, to position #2, to position #3.....& so forth ....to
  position #N), each bit/s pattern would have either ‘odd’ or ‘even’ position #
It is pre-arranged so that should the bit/s pattern at the ‘odd’ position # consists
of just a single bit pattern of either 1 single ‘0’ or 1 single ‘1’ (other possible
alternatives: .... if consists of just exact bits pattern of ‘10’ of exact length 2 bits....
etc) then eg a single ‘1’ bit could be ‘expected’ to recorded into the ‘resultant file’
to denote this OTHERWISE eg a single ‘0’ bit or even some number representation
system which has initial very 1st leading ‘0’ bit could be recorded into the ‘resultant
file’, AND should the bit/s pattern at the ‘even’ position # consists of just a single
bit pattern of either 1 single ‘0’ or 1 single ‘1’ (other possible alternatives .... if
consists of just exact bits pattern of ‘10’ of exact length 2 bits.... etc) then eg a
single ‘0’ bit could be ‘expected’ to recorded into the ‘resultant file’ to denote this
OTHERWISE eg a single ‘1’ bit or even some number representation system which has
initial very 1^{st} leading ‘1’ bit could be recorded into the ‘resultant file’:
Further it could also optionally be pre-arranged so that were any immediately
preceding bit/s pattern consists of a plurality of consecutive bits, then this present
current bit/s pattern would now be ‘expected’ instead to utilise/record a single bit of
same ‘expected’ binary value corresponding to that of the immediately preceding bits
pattern position #
/************************ END *********************************/
```

Another further example of variant adaptations, among many possible, is as follows: Bits pattern of consecutive ‘1’/s followed by consecutive ‘0’s (eg ‘10’ ‘110’ ‘100’ ‘1100’ ‘11 . . . 10 . . . 0’ . . . etc), such block of variable bits length could instead form the basic recording unit instead & in place of the exact bits pattern ‘10’ of exact length 2 as described in Method starting on page 7 of Description Body. Here it would be adapted so that a non-switched non-alternate binary value would be used to record such a block of at least 3 or more bits in length (ie has at least 1 more ‘1’ or at least 1 more ‘0’, than the smallest possible block ‘10’ of exact length 2), then a ‘First Pass’ to similarly record whether there is ‘additional’ 07s or ‘additional ‘1’/s in the block, then similarly the repetitive ‘First Pass’/‘Second Pass’/‘Third Pass’ . . . ‘Nth Pass’ each referring to such blocks instead, then similarly record the repetitive ‘First Extra1 Pass’/‘Second Extra1 Pass’/‘Third Extra1 Pass’ . . . ‘Nth Extra1 Pass’ each referring to such blocks instead.

May be any of the schemes/sub-component schemes described earlier here in preceding description body, each on their may or may not consistently produce the required results all the time on all possible input datasets, however the various individual component methods/sub-component method step/s described &/or the various combinations of any of the individual sub-component step/s described certainly are needed & could be utilised or modified or adapted & form essential method steps in any of the possible number of new methods/new implementations which could then consistently (or more consistently) produce the required results all the time on all possible (or larger possible) input datasets.

```
/**************** OUTLINE REFINED SUMMARY *******************/
14. Methods or sub-component method step/s for lossless data compressions or for
  compression/representation of sequential list of positive integers or offsetted to
  all be positive integers >0, said methods or sub-component method step/s:
Uses number representation system sufficient to specifically cover/represent
specific number equal to max number of consecutive bits present in the input file or
to specifically cover/represent specific number equal to max largest positive integer
number present in the sequential list of positive (ie all positive integers >0 , which
may be a sequential list of variable length binary base digit numbers), this number
representation system designed/selected sufficient to cover/represent specifically upto
the number of consecutive bit/s in successive sequential consecutive bit/s in the
input file to be compressed file or to specifically cover/represent specific number
equal to max positive integer number present in the sequential list of positive integers
(where N denotes the maximum number of consecutive bits in the input file to be
compressed file or the max positive integer number present in the sequential list of
positive integers): if there are at most N maximum number of consecutive bits all
same binary value in the input file, then the number representation system could be eg of
0->1 10->2 110->3 1110->4 11110->5 111110->6 .......& so forth ........until
eventual just N − 1 number of ‘1’s -> N (here ‘->’ means to represent consecutive
bit/s all of same binary value of specified length), ie a single ‘0’ bit used to
represent consecutive bit/s of length 1 (or positive integer 1), M − 1 number of
leading ‘1’s followed by the end marker/delimiter single bit of ‘0’ to represent M
number of consecutive bits all of same binary value (or positive integer M, where 1 <
M < N the Maximum number of consecutive bits in the input file to be compressed)
in the input file & eventually just N − 1 number of leading all ‘1’s (without following
end marker/delimiter bit of ‘0’, thus attaining 1 bit compression reduction gain when
compressing/representing) to compress/represent N maximum number of
consecutive bits all of same binary value in the input file, OR ‘complement’ of this
number representation system eg 1->1 01->2 001->3 0001->4 00001->5 000001->
6 .......& so forth ........until eventual just N − 1 number of ‘0’s -> N (here ‘->’
means to represent consecutive bit/s all of same binary value of specified length or
specified positive integer) , ie a single ‘1’ bit used to represent consecutive bit/s of
length 1 (or positive integer 1), M − 1 number of leading ‘0’s followed by the end
marker/delimiter single bit of ‘1’ to represent M number of consecutive bits all of
same binary value (or positive integer M, where 1 < M < N the Maximum number of
consecutive bits in the input file to be compressed) in the input file & eventually just
N − 1 number of leading all ‘0’s (without following end marker/delimiter bit of ‘1’,
thus attaining 1 bit compression reduction gain when compressing/representing) to
compress/represent N maximum number of consecutive bits all of same binary value
(or maximum largest positive integer N) in the input file.
15. Methods or sub-component method step/s for lossless data compressions or for
  compression/representation of sequential list of positive integers (which may be
  a sequential list of variable length binary base digit numbers), said methods or
  sub-component method step/s:
  Uses ‘extended’ number representation system/s or various variant schemes of
  ‘extended’ number representation system, where specifically the specific length
  of consecutive bit/s all of same binary value (or successive positive integers) in
  input data file to be compressed could be designed represented by eg 0->1 10->2
  11->‘extend’ (ie 11 bits pattern where occurred means one should look to further
  following bit/s pattern to determine the value of the number represented) 110->3
  1110->4 1111-> again extend (here ‘11’ follows immediately by ‘11’ means to
  repeat extend) 11110->5 111110->6 111111->repeat extend ....& so forth ad
  infinitum, OR eg 0->1 11->2 10->‘extend’ (ie 10 bits pattern where occurred
  means one should look to further following bit/s pattern to determine the value of
  the number represented) 100->3 1011->4 1010-> again extend (here ‘10’
  follows immediately by ‘10’ means to repeat extend) 10100->5 101011->6
  101010->repeat extend ....& so forth ad infinitum, OR as above but with binary
  values now all switched ie ‘0’ in place of ‘1’ & ‘1’ in place of ‘0’
  OR
  eg 0->1 10->2 110->3 111->extend 1110->4 11110->5 111110->6 111111->
  repeat extend ....& so forth ad infinitum, OR eg 0->1 10->2 111->3 110->
  extend 1100->4 11010->5 110111->6 110110->repeat extend ....& so forth
  ad infinitum, OR as above but with binary values now all switched ie ‘0’ in place
  of ‘1’ & ‘1’ inplace of ‘0’
  OR
  Similar but with progressively larger number of bits used to represent ‘extend’ eg
  1111 or 1110 (or corresponding ‘switched binary value scheme) ->extend ....&
  so forth etc .....similarly schemes with progressively larger number of bits used to
  represent ‘extend’ designed such that none of any of the number representations
  bit/s pattern of any lengths/or any combinations of any number of the number
  representations bit/s pattern of any lengths could form the leading prefix of any of
  the ‘extend’ bits pattern
16. Methods or sub-component method step/s for lossless data compressions or for
  compression/representation of sequential list of positive integers (which may be
  a sequential list of variable length binary base digit numbers), said methods or
  sub-component method step/s:
  Uses ‘extended’ number representation system/s or various variant schemes of
  ‘extended’ number representation system, where specifically the specific length
  of consecutive bit/s all of same binary value (or successive positive integers) in
  input data file to be compressed could be designed represented by eg 0->1 10->2
  11->‘extend’ (ie 11 bits pattern where occurred means one should look to further
  following bit/s pattern to determine the value of the number represented) 110->3
  1110->4 1111-> again extend (here ‘11’ follows immediately by ‘11’ means to
  repeat extend) 11110->5 111110->6 111111->repeat extend ....& so forth
  UNTIL the maximum consecutive number of bits present in the input data file to
  be compressed is represented (OPTIONALLY this maximum consecutive
  number may conveniently be represented by the latest ‘repeat extend’ bits pattern,
  if so coincides or designed to ensure so coincides thus gaining 1 bit compression
  reduction), OR eg 0->1 11->2 10->‘extend’ (ie 10 bits pattern where occurred
  means one should look to further additional following bit/s pattern to determine
  the value of the number represented) 100->3 1011->4 1010-> again extend
  (here ‘10’ follows immediately by ‘10’ means to repeat extend) 10100->5
  101011->6 101010-> repeat extend ....& so UNTIL the maximum consecutive
  number of bits present in the input data file to be compressed is represented
  (OPTIONALLY this maximum consecutive number may conveniently be
  represented by the latest ‘repeat extend’ bits pattern, if so coincides or designed
  to ensure so coincides thus gaining 1 bit compression reduction), OR as above
  but with binary values now all switched ie ‘0’ in place of ‘1’ & ‘1’ in place of ‘0’
  OR
  eg 0->1 10->2 110->3 111->extend 1110->4 11110->5 111110->6 111111->
  repeat extend ....& so forth UNTIL the maximum consecutive number of bits
  (or max largest positive integer) present in the input data file to be compressed is
  represented (OPTIONALLY this maximum consecutive number may
  conveniently be represented by the latest ‘repeat extend’ bits pattern, if so
  coincides or designed to ensure so coincides thus gaining 1 bit compression
  reduction), OR eg 0->1 10->2 111->3 110->extend 1100->4 11010->5
  110111->6 110110->repeat extend ....& so forth UNTIL the maximum
  consecutive number of bits (or max largest positive integer) present in the input
  data file to be compressed is represented (OPTIONALLY this maximum
  consecutive number may conveniently be represented by the latest ‘repeat extend’
  bits pattern, if so coincides or designed to ensure so coincides thus gaining 1 bit
  compression reduction), OR as above but with binary values now all switched ie
  ‘0’ in place of ‘1’ & ‘1’ in place of ‘0’
  OR
  Similar but with progressively larger number of bits used to represent ‘extend’ eg
  1111or 1110 (or corresponding ‘switched binary value scheme) ->extend ....&
  so forth etc UNTIL the maximum consecutive number of bits (or max largest
  positive integer) present in the input data file to be compressed is represented
  (OPTIONALLY this maximum consecutive number may conveniently be
  represented by the latest ‘repeat extend’ bits pattern, if so coincides or designed
  to ensure so coincides thus gaining 1 bit compression reduction) .....similarly
  schemes with progressively larger number of bits used to represent ‘extend’
  designed such that none of any of the number representations bit/s pattern of any
  lengths or none of any combinations of any number of the number representations
  bit/s pattern of any lengths could form the leading prefix substring of any of the
  ‘extend’ bits pattern
17. Methods or sub-component method step/s for lossless data compressions or for
  compression/representation of sequential list of positive integers (which may be
  a sequential list of variable length binary base digit numbers) as in accordance in
  any of Paragraphs above, said methods or sub-component method step/s here:
  Alternate successive next sequentially continuously ‘switches’ using a number
  representation system and its corresponding ‘complement reversed binary value’
  number representation system
18. Methods or sub-component method step/s for lossless data compressions or for
  compression/representation of sequential list of positive integers (which may be
  a sequential list of variable length binary base digit numbers) as in accordance in
  any of Paragraphs above, said methods or sub-component method step/s here:
  initial process iteration compress/represent the initial original input file to
  produce a compressed output file.
  subsequent present iteration process takes the previous iteration's compressed
  output file as present iteration's input file to produce this present iteration's
  compressed output file, which in turn is to be used as next further iteration's input
  file .....& so forth ....repeatedly UNTIL some specified criteria is reached.
19. Methods or sub-component method step/s for lossless data compressions or for
  compression/representation of sequential list of positive integers (which may be
  a sequential list of variable length binary base digit numbers) as in accordance in
  any of Paragraphs above, said methods or sub-component method step/s here:
  between any two successive iterations stage the input new data file may
  further be pre-processed by other existing specified, adapted or designed lossless
  compression methods/algorithms to reduce the file size, before starting the
  subsequent iteration/s
20. Methods or sub-component method step/s for lossless reconstruction/lossless
  decompression of compressed data or for lossless reconstruction/lossless
  decompression of compressed representation of sequential list of positive integers
  (which may be a sequential list of variable length binary base digit numbers) as
  in accordance in any of Paragraphs above, said methods or sub-component
  method step/s here:
  Accepts as inputs various parameters of the compression process which should
  at least include the total number of process iterations, the final iteration's
  Compressed File’, together with a single binary bit parameter recording the
  starting binary value, either ‘0’ or ‘1’, of the very 1^{st} consecutive bit/s of the very
  initial 1^{st} original input data file used in the very initial 1^{st} iteration in the
  compression process (but this single binary bit parameter is not needed in the case
  of lossless reconstruction of sequential list of variable length binary positive
  integer numbers).
where in the compression process between any two successive compression process
iterations stage the iteration's input file were further pre-processed by other existing
specified adapted or designed lossless compression methods/algorithms to reduce
the file size, to accept as further ‘extra’ inputs these informations/parameters
/************************ END *********************************/
```

Numerous various different techniques &/or implementations could be derived from the described particular technique & the described particular implementation here, yet will come within the principles of this present invention.

1. Methods or sub-component method step/s for lossless data compressions or for compression/representation of sequential list of positive integers or offsetted to all be positive integers >0 (which may be a sequential list of variable length binary base digit numbers).

2. Methods or sub-component method step/s for lossless data compressions or for compression/representation of sequential list of positive integers or offsetted to all be positive integers >0, said methods or sub-component method step/s:
Uses number representation system sufficient to specifically cover/represent specific number equal to max number of consecutive bits present in the input file or to specifically cover/represent specific number equal to max largest positive integer number present in the sequential list of positive (ie all positive integers >0, which may be a sequential list of variable length binary base digit numbers), this number representation system designed/selected sufficient to cover/represent specifically up to the number of consecutive bits in successive sequential consecutive bit/s in the input file to be compressed file or to specifically cover/represent specific number equal to max positive integer number present in the sequential list of positive integers (where N denotes the maximum number of consecutive bits in the input file to be compressed file or the max positive integer number present in the sequential list of positive integers): if there are at most N maximum number of consecutive bits all of same binary value in the input file, then the number representation system could be eg 0->1 10->2 110->3 1110->4 11110->5 111110->6 . . . & so forth . . . until eventual just N−1 number of ‘1’s->N (here ‘->’ means to represent consecutive bits all of same binary value of specified length), ie a single ‘0’ bit used to represent consecutive bit's of length 1 (or positive integer 1), M−1 number of leading ‘1’s followed by the end marker/delimiter single bit of ‘0’ to represent M number of consecutive bits all of same binary value (or positive integer M, where 1<M<N the Maximum number of consecutive bits in the input file to be compressed) in the input file & eventually just N−1 number of leading all ‘1’s (without following end marker/delimiter bit of ‘0’, thus attaining 1 bit compression reduction gain when compressing/representing) to compress/represent N maximum number of consecutive bits all of same binary value in the input file, OR ‘complement’ of this number representation system eg 1->1 01->2 001->3 0001->4 00001->5 000001->6 . . . & so forth . . . until eventual just N−1 number of ‘0’s->N (here ‘->’ means to represent consecutive bit/s all of same binary value of specified length or specified positive integer), ie a single ‘1’ bit used to represent consecutive bit/s of length 1 (or positive integer 1), M−1 number of leading ‘0’s followed by the end marker/delimiter single bit of ‘1’ to represent M number of consecutive bits all of same binary value (or positive integer M, where 1 <M<N the Maximum number of consecutive bits in the input file to be compressed) in the input file & eventually just N−1 number of leading all ‘0’s (without following end marker/delimiter bit of ‘1’, thus attaining 1 bit compression reduction gain when compressing/representing) to compress/represent N maximum number of consecutive bits all of same binary value (or maximum largest positive integer N) in the input file.

3. Methods or sub-component method step/s for lossless data compressions or for compression/representation of sequential list of positive integers (which may be a sequential list of variable length binary base digit numbers), said methods or sub-component method step/s:
Uses ‘extended’ number representation system/s or various variant schemes of ‘extended’ number representation system, where specifically the specific length of consecutive bit/s all of same binary value (or successive positive integers) in input data file to be compressed could be designed represented by eg 0->1 10->2 11->‘extend’ (ie 11 bits pattern where occurred means one should look to further following bit/s pattern to determine the value of the number represented) 110->3 1110->4 1111-> again extend (here ‘11’ follows immediately by ‘11’ means to repeat extend) 11110->5 111110->6 111111-> repeat extend . . . & so forth ad infinitum, OR eg 0->1 11->2 10->‘extend’ (ie 10 bits pattern where occurred means one should look to further following bit/s pattern to determine the value of the number represented) 100->3 1011->4 1010-> again extend (here ‘10’ follows immediately by ‘10’ means to repeat extend) 10100->5 101011->6 101010-> repeat extend . . . & so forth ad infinitum, OR as above but with binary values now all switched ie ‘0’ in place of ‘1’ & ‘1’ in place of ‘0’
OR
eg 0->1 10->2 110->3 111-> extend 1110->4 11110->5 111110->6 111111-> repeat extend . . . & so forth ad infinitum, OR eg 0->1 10->2 111->3 110-> extend 1100->4 11010->5 110111->6 110110-> repeat extend . . . & so forth ad infinitum, OR as above but with binary values now all switched ie ‘0’ in place of ‘1’ & ‘1’ in place of ‘0’
OR
Similar but with progressively larger number of bits used to represent ‘extend’ eg 1111 or 1110 (or corresponding ‘switched binary value scheme)-> extend . . . & so forth etc. . . . similarly schemes with progressively larger number of bits used to represent ‘extend’ designed such that none of any of the number representations bit/s pattern of any lengths/or any combinations of any number of the number representations bit/s pattern of any lengths could form the leading prefix of any of the ‘extend’ bits pattern

4. Methods or sub-component method step/s for lossless data compressions or for compression/representation of sequential list of positive integers (which may be a sequential list of variable length binary base digit numbers), said methods or sub-component method step/s:
Uses ‘extended’ number representation system/s or various variant schemes of ‘extended’ number representation system, where specifically the specific length of consecutive bit/s all of same binary value (or successive positive integers) in input data file to be compressed could be designed represented by eg 0->1 10->2 11->‘extend’ (ie 11 bits pattern where occurred means one should look to further following bit/s pattern to determine the value of the number represented) 110->3 1110->4 1111-> again extend (here ‘11’ follows immediately by ‘11’ means to repeat extend) 11110->5 111110->6 111111-> repeat extend . . . & so forth UNTIL the maximum consecutive number of bits present in the input data file to be compressed is represented (OPTIONALLY this maximum consecutive number may conveniently be represented by the latest ‘repeat extend’ bits pattern, if so coincides or designed to ensure so coincides thus gaining 1 bit compression reduction), OR eg 0->1 11->2 10->‘extend’ (ie 10 bits pattern where occurred means one should look to further additional following bit/s pattern to determine the value of the number represented) 100->3 1011->4 1010-> again extend (here ‘10’ follows immediately by ‘10’ means to repeat extend) 10100->5 101011->6 101010-> repeat extend . . . & so UNTIL the maximum consecutive number of bits present in the input data file to be compressed is represented (OPTIONALLY this maximum consecutive number may conveniently be represented by the latest ‘repeat extend’ bits pattern, if so coincides or designed to ensure so coincides thus gaining 1 bit compression reduction), OR as above but with binary values now all switched ie ‘0’ in place of ‘1’ & ‘1’ in place of ‘0’
OR
eg 0->1 10->2 110->3 111-> extend 1110->4 11110->5 111110->6 111111-> repeat extend . . . & so forth UNTIL the maximum consecutive number of bits (or max largest positive integer) present in the input data file to be compressed is represented (OPTIONALLY this maximum consecutive number may conveniently be represented by the latest ‘repeat extend’ bits pattern, if so coincides or designed to ensure so coincides thus gaining 1 bit compression reduction), OR eg 0->1 10->2 111->3 110-> extend 1100->4 11010->5 110111->6 110110-> repeat extend . . . & so forth UNTIL the maximum consecutive number of bits (or max largest positive integer) present in the input data file to be compressed is represented (OPTIONALLY this maximum consecutive number may conveniently be represented by the latest ‘repeat extend’ bits pattern, if so coincides or designed to ensure so coincides thus gaining 1 bit compression reduction), OR as above but with binary values now all switched ie ‘0’ in place of ‘1’ & ‘1’ in place of ‘0’
OR
Similar but with progressively larger number of bits used to represent ‘extend’ eg 1111 or 1110 (or corresponding ‘switched binary value scheme)-> extend . . . & so forth etc UNTIL the maximum consecutive number of bits (or max largest positive integer) present in the input data file to be compressed is represented (OPTIONALLY this maximum consecutive number may conveniently be represented by the latest ‘repeat extend’ bits pattern, if so coincides or designed to ensure so coincides thus gaining 1 bit compression reduction) . . . similarly schemes with progressively larger number of bits used to represent ‘extend’ designed such that none of any of the number representations bit/s pattern of any lengths or none of any combinations of any number of the number representations bit/s pattern of any lengths could form the leading prefix substring of any of the ‘extend’ bits pattern

5. Methods or sub-component method step/s for lossless data compressions or for compression/representation of sequential list of positive integers (which may be a sequential list of variable length binary base digit numbers) as in accordance in any of claims 2-4 above, said methods or sub-component method step/s here:
Alternate successive next sequentially continuously ‘switches’ using a number representation system and its corresponding ‘complement reversed binary value’ number representation system

6. Methods or sub-component method step/s for lossless data compressions or for compression/representation of sequential list of positive integers (which may be a sequential list of variable length binary base digit numbers) as in accordance in any of claims 2-5 above, said methods or sub-component method step/s here:
initial process iteration compress/represent the initial original input file to produce a compressed output file.
subsequent present iteration process takes the previous iteration's compressed output file as present iteration's input file to produce this present iteration's compressed output file, which in turn is to be used as next further iteration's input file . . . & so forth . . . repeatedly UNTIL some specified criteria is reached.

7. Methods or sub-component method step/s for lossless data compressions or for compression/representation of sequential list of positive integers (which may be a sequential list of variable length binary base digit numbers) as in accordance in any of claims 2-6 above, said methods or sub-component method step/s here:
between any two successive iterations stage the input new data file may further be pre-processed by other existing specified, adapted or designed lossless compression methods/algorithms to reduce the file size, before starting the subsequent iteration/s

8. Methods or sub-component method step/s for lossless reconstruction/lossless decompression of compressed data or for lossless reconstruction/lossless decompression of compressed representation of sequential list of positive integers (which may be a sequential list of variable length binary base digit numbers) as in accordance in any of claims 2-7 above, said methods or sub-component method step/s here:
Accepts as inputs various parameters of the compression process which should at least include the total number of process iterations, the final iteration's ‘Compressed File’, together with a single binary bit parameter recording the starting binary value, either ‘0’ or ‘1’, of the very 1^{st} consecutive bit/s of the very initial 1^{st} original input data file used in the very initial 1^{st} iteration in the compression process (but this single binary bit parameter is not needed in the case of lossless reconstruction of sequential list of variable length binary positive integer numbers).
where in the compression process between any two successive compression process iterations stage the iteration's input file were further pre-processed by other existing specified adapted or designed lossless compression methods/algorithms to reduce the file size, to accept as further ‘extra’ inputs these informations/parameters

9. Methods or sub-component method step/s for lossless data compressions, said methods or sub-component method step/s here:
Examine input binary data file sequentially looking for each successive sequential next earliest occurrence of exact ‘10’ bits pattern (length 2 bits, with ‘1’ bit followed by a ‘0’ bit), this ‘10’ end-delimited block may be preceded by a number of consecutive bit/s all of same binary value ‘0’s which in turn may or may not be followed by a number of consecutive bit/s all of same binary value ‘1’s OR just preceded by a number of consecutive bit/s all of same binary value ‘1’s OR just preceded by a previous ‘10’ block:
each of these successive sequential earliest next occurrence of ‘10’ end-delimited block is successively sequentially recorded/represented in a new binary ‘Compress File’ with a single ‘1’ binary bit (or a single ‘0’ bit) used to record a ‘10’ end-delimited block, OPTIONALLY could be pre-arranged to start the recording of the very 1^{st} ‘10’ end-delimited block with a single ‘1’ (alternatively a single ‘0’) binary bit to indicate there are no consecutive bit/s whatsoever preceding the very initial 1^{st} ‘10’ block WHEREAS with a single ‘0’ (alternatively a single ‘1’) binary bit to indicate there are a number of consecutive bit/s of all ‘0/s or all ‘0’/s followed by all ‘1’/s or all ‘1’/s only preceding this very initial 1^{st} ‘10’ block
IF there is a ‘10’ block immediately preceding & adjacent to a present ‘10’ block (ie there is no other intervening consecutive bits) then it is switched to using just a single binary bit of opposite/‘switched’ binary value to the preceding last recorded single bit's binary value to record this present ‘10’ block into the binary ‘Compress File’
AND if there is other intervening consecutive bit/s then just use one single bit of same binary value as the preceding last recorded single bit's binary value to record this present ‘10’ block into the binary ‘Compress File’.
The very last consecutive bit/s all of same value binary bits in the input binary data file may be just consecutive bit/s of all ‘0’/s or all ‘0’/s followed by all ‘1’/s or just all ‘1’/s (or ‘none’ whatsoever) immediately following the very last ‘10’ block in the original binary data file, thus an ‘artificial’ single bit will always be post-appended/inserted at the very end bit position of the ‘compressed file’ to help notify/indicate whether there are any consecutive bit/s of all ‘0’s &/or all ‘1’s immediately preceding this post-appended/inserted ‘artificial’ single: setting this post-appended/inserted ‘artificial’ bit to opposite/‘switched’ binary value as the very last recorded single bit's binary value indicates there are no consecutive bit/s of all ‘0’s &/or all ‘1’s whatsoever preceding this ‘artificial’ single bit, setting this post-appended/inserted ‘artificial’ bit to the same binary value as the very last recorded single bit's binary value indicates there are consecutive bit/s of all ‘0’s &/or all ‘1’s preceding this ‘artificial’ bit.

10. Methods or sub-component method step/s for lossless data compressions as in accordance with claim 9 above, said methods or sub-component method step/s here NEXT FURTHER:
Next in a ‘1^{st} Pass’ stage uses as input the ‘Compress File’ & also references the very 1^{st} initial original binary input file, compression process here steps successive sequentially through each of the single bit in the ‘Compress File’ representing ‘10’ end-delimited blocks in the very 1^{st} initial original binary input file which has additional further consecutive bit/s immediately preceding the ‘10’ end-delimiter as in the very 1^{st} initial original binary input file, and record in a new ‘1^{st} Pass’ binary file using a single ‘0’ bit (alternatively a single ‘1’ bit) to indicate IF number of consecutive bit/s all of same binary value ‘0’s (which further may or may not be followed by consecutive bit/s all of same binary value ‘1’s) immediately precedes this present ‘10’ end-delimited block OTHERWISE using single ‘1’ bit (alternatively a single ‘0’ bit) to indicate only consecutive bit/s all of same binary ‘1’s immediately precedes this present ‘10’ end-delimited block.
Next again the compression process goes through a ‘2^{nd} Pass’ stage using as input the ‘1^{st} Pass’ binary file above (also referencing earlier binary ‘Compress File’ & very 1^{st} initial original binary input file) & produces a binary ‘2^{nd} Pass’ file consisting of individual single bits:
it steps through successive sequentially each of the individual single bits in the ‘First Pass binary data file to record into the new ‘Second Pass File’ a single ‘0’ bit (alternative a single ‘1’ bit) if the number of consecutive bits of either ‘0’s or ‘1’s (binary value of which indicated by individual single bit's binary value in the ‘First Pass File) preceding the corresponding ‘10’ block in the original binary data file is exactly 1 (thereafter during each subsequent ‘pass’ there is no further need to further process these ‘10’ blocks ie no further needs to record any increase of by 1 the total number of consecutive bits of all same binary value which immediately precedes the corresponding ‘10’ block in the original binary data file), or record a single ‘1’ bit (corresponding alternatively a single ‘0’ bit) if the number of consecutive bits of either ‘0’s or ‘1’s (indicated by individual single bit's binary value in the ‘First Pass File) preceding the corresponding ‘10’ block in the original binary data file is at least 2 or more.
Repetitively next, the compression process goes through a ‘third pass stage, which uses as input the Second Pass’ binary data file (also referencing the earlier ‘Compressed File’ & original binary data file & ‘First Pass File’ & ‘2nd Pass File) &
produces as output a new Third Pass File’ binary data file of individual single bits:
it steps through successive sequentially each of the individual single bits in the ‘Second Pass binary data file to record into the new ‘Third Pass File’ a single ‘0’ bit (alternative a single ‘1’ bit) if the number of consecutive bits of either ‘0’s or ‘1’s (binary value of which indicated by individual single bit's binary value in the ‘First Pass File) preceding the corresponding ‘10’ block in the original binary data file is exactly 2 (thereafter during each subsequent ‘pass’ there is no further need to further process these ‘10’ blocks ie no further needs to record any increase of by 1 the total number of consecutive bits of all same binary value which immediately precedes the corresponding ‘10’ block in the original binary data file), or record a single ‘1’ bit (corresponding alternatively a single ‘0’ bit) if the number of consecutive bits of either ‘0’s or ‘1’s (binary value of which indicated by individual single bit's binary value in the ‘First Pass File) preceding the corresponding ‘10’ block in the very 1^{st} initial original binary data file is at least 3 or more.
Again & again . . . & so forth . . . repetitively next, the compression process goes through an Nth pass stage, which uses as input the ‘N−1 Pass’ binary data file (also referencing the earlier ‘Compressed File’ & original binary data file & ‘First Pass File’ to ‘N−2 Pass File) & produces as output a new N Pass File’ binary data file of individual single bits:
it steps through successive sequentially each of the individual single bits in the ‘N−1 Pass’ binary data file to record into the new ‘N Pass File’ a single ‘0’ bit (alternatively a single ‘1’ bit) if the number of consecutive bits of either ‘0’s or ‘1’s (binary value of which indicated by individual single bit's binary value in the ‘First Pass File) preceding the corresponding ‘10’ block in the original binary data file is exactly N−1 (thereafter during each subsequent ‘pass’ there is no further need to further process these ‘10’ blocks ie no further needs to record any increase of by 1 the total number of consecutive bits of all same binary value which immediately precedes the corresponding ‘10’ block in the original binary data file), or record a single ‘1’ bit (alternatively a single ‘0’ bit) if the number of consecutive bits of either ‘0’s or ‘1’s (binary value of which indicated by individual single bit's binary value in the ‘First Pass File) preceding the corresponding ‘10’ block in the original binary data file is at least N or more:
Note in the very latest pass (ie with N=total number of all ‘Passes’ so far), if there would not be any number of consecutive bits of all same binary value greater than N preceding any of the corresponding ‘10’ blocks in the original binary data file, then there is no further need to proceed onto further subsequent N+1 pass, it is obvious, or can be inferred that all ‘10’ blocks with a single ‘1’ bit recorded in the final last ‘N Pass File’ indeed all have exactly N consecutive bits of all same binary value.
The compression process now takes as input the ‘First Pass File’ (also referencing original binary data file & ‘Compress File’ & ‘First Pass File’ to ‘N Pass File’) & successive sequentially steps through each of the single ‘0’ bit skipping all the single ‘1’ bit in the input ‘First Pass File’ (ie successive sequentially stepping through only those corresponding ‘10’ blocks with preceding consecutive ‘0’ bit/s), record a single ‘0’ bit (alternatively a single ‘1’ bit) in a new ‘First Extra1 Pass File’ if there is no consecutive ‘1’ bit/s which follows the consecutive ‘0’ bit/s & record a single ‘1’ bit (corresponding alternatively a single ‘0’ bit) in a new ‘First Extra1 Pass File’ if there is at least 1 or more consecutive ‘1’ bit/s which follows the consecutive ‘0’ bit/s
Next the compression process proceeds onto ‘Second Extra1 Pass’ using as input the earlier ‘First Extra1 File’ (also referencing original binary data file & ‘Compress File’ & ‘First Pass File’ to ‘N Pass File’ & ‘First Extra1 Pass), stepping successively sequentially through each single ‘1’ bit in the ‘First Extra1 File’ (ie only those corresponding ‘10’ blocks in the original binary data file with at least 1 or more consecutive ‘1’ bit/s following consecutive ‘0’ bit/s, & completely skipping all single ‘0’ bit in the ‘First Extra1 Pass File’) recording a single ‘0’ bit (alternatively a single ‘1’ bit) in the new ‘Second Extra1 File’ if there is only exactly 1 consecutive ‘1’ bit following consecutive ‘0’ bit/s, & recording a single ‘1’ bit (corresponding alternatively a single ‘0’ bit) in the new ‘Second Extra1 File’ if there is at least 2 or more consecutive ‘1’ bits following consecutive ‘0’ bit/s.
Again next the compression process proceeds onto ‘Third Extra1 Pass’ using as input the earlier ‘Second Extra1 File’ (also referencing original binary data file & ‘Compress File’ & ‘First Pass File’ to ‘N Pass File’ & First Extra1 Pass to ‘Second Extra1 Pass File’), stepping successively sequentially through each single ‘1’ bit in the ‘Second Extra1 File’ (ie only those corresponding ‘10’ blocks with at least 2 or more consecutive ‘1’ bit/s following consecutive ‘0’ bit/s in the original binary data file, & completely skipping all single ‘0’ bit in the ‘Second Extra1 Pass File’) recording a single ‘0’ bit (alternatively a single ‘1’ bit) in the new ‘Second Extra1 File’ if there is only exactly 2 consecutive ‘1’ bits following consecutive ‘0’ bit/s, & recording a single ‘1’ bit (corresponding alternatively a single ‘0’ bit) in the new ‘Second Extra1 File’ if there is at least 3 or more consecutive ‘1’ bits following consecutive ‘0’ bit/s & so forth.
At M Extra1 Pass, compression process proceeds onto ‘M Extra1 Pass’ using as input the earlier ‘M−1 Extra1 File’ (also referencing original binary data file & ‘Compress File’ & ‘First Pass File’ to ‘N Pass File’ & ‘First Extra1 Pass File’ to ‘M−2 Extra1 Pass File’), stepping successively sequentially through each single ‘1’ bit in the ‘M−1 Extra1 File’ (ie only those corresponding ‘10’ blocks with preceding at least M or more consecutive ‘1’ bit/s following consecutive ‘0’ bit/s in the original binary data file, & completely skipping all single ‘0’ bit in the ‘M−1 Extra1 Pass File’) recording a single ‘0’ bit (alternatively a single ‘1’ bit) in the new ‘M Extra1 File’ if there is only exactly M consecutive ‘1’ bits following consecutive ‘0’ bit/s & recording a single ‘1’ bit (corresponding alternatively a single ‘0’ bit) in the new ‘M Extra1 File’ if there is at least M+1 or more consecutive ‘1’ bits following consecutive ‘0’ bit/s:
Note in the very latest pass (ie with M=total number of all ‘Passes’ so far), if there would not be any number of consecutive bits of all same binary value greater than M preceding any of the corresponding ‘10’ blocks in the original binary data file, then there is no further need to proceed onto further subsequent M+1 pass, it is obvious or can be inferred that all ‘10’ blocks with a single ‘1’ bit recorded in the final last ‘M Pass File’ indeed all have exactly M consecutive bits of all same binary value.

11. Methods or sub-component method step/s for lossless reconstruction of compressed data as described in claim 10 above, said methods or sub-component method step/s here:
Accept as input from these ‘Compressed File’ & (if any) ‘1^{st} Pass File’ to ‘N Pass File’ & (if any) ‘1^{st} Extra 1 Pass File’ to ‘M Extra1 Pass File’, together with the various very small number of parameters of the whole complete compression process iterations which should at least include the number of Pass Files N, the number of Extra1 Pass Files M, the single ‘artificial’ bit value (if not already post-appended to the resultant ‘Compress File’).
OPTIONALLY All of these files ‘Compressed File’ & (if any) ‘1^{st} Pass File’ to ‘N Pass File’ & (if any) ‘1^{st} Extra1 Pass File’ to ‘M Extra1 Pass File’ are merged as a single, together with various parameters of the whole complete compression process iterations which should at least include the single ‘artificial’ bit value (if not already post-appended to the resultant ‘Compress File’), N the number of Pass Files & M the number of Extra1 Pass Files (from which the total Passes N & total Extra1 Passes M are conveyed) & the sizes of each files in the same respective order at which they are merged (in pre-arranged/pre-agreed protocol &/or fixed format) to enable lossless reconstructions:
OPTIONALLY All the various parameters above could also be eg pre-appended to the above merged file at pre-defined/pre-agreed initial bit position/s or byte/s position/s &/or particular fixed format/syntax thus there is now a just a single file
OPTIONALLY any of these individual files, or the single merged file could again be used as new ‘original binary data file’ to be processed anew to produced new ‘Compressed File’ & a number of new Pass Files & a number of new Extra1 Pass Files, together with the parameters of this latest compression process (which should also now include the total number of ‘compressions iterations anew’ parameter) to enable lossless reconstruction of the very 1st initial original binary data file: all these files above, &/or together with the parameters (which should now further include a new parameter of the total number of ‘compressions iterations anew’), could then be merged into a latest new single merged file from which the very 1^{st} initial original binary data file could be losslessly reconstructed . . . this latest new single merged file could iteratively repetitively again be used as another latest new ‘original binary data file’ to be processed anew/compression iterations anew . . . & so forth, achieving very large lossless compression ratio.

12. Methods or sub-component method step/s based on and modified from the Methods or sub-component step/s as described in claim 10 above:
Successive sequential record in Compress File using a single ‘0’ or ‘1’ bit each next earliest possible occurrence of ‘10’ block in the original binary data file, in manner as described in claim 11 above (successive bit's binary value alternately ‘switched, or remain same as preceding latest recorded bit's binary value).
Successive sequentially stepping through each of the ‘non-alternating’ ‘non-switched’ single bit in the ‘Compress File’ (completely ignoring/skipping all the alternating ‘switched’ single bit) to record a single bit of ‘0’ in a new ‘First Pass File’ if the corresponding ‘10’ block in the original binary data file has preceding consecutive bits of all ‘0’s which then may or may not possibly in turn be followed by consecutive bit/s of all ‘1’s, and to record a single bit of ‘1’ in a new ‘First Pass File’ if the corresponding ‘10’ block in the original binary data file only has preceding consecutive bits of all ‘1’s (in manner as described in earlier implementation above).
Successive sequentially stepping through each & every of the single bits (whether ‘0’ or ‘1’ binary value) in the ‘First Pass File’ to record in a new ‘Second Pass File’ the ‘total’ number of consecutive bit/s (of ‘0’ or ‘1’, already indicated in the ‘First Pass File’) preceding the corresponding ‘10’ block in the original binary data file: the ‘total’ number of consecutive bit/s here recorded/represented using number representation system which uses exactly the same number of bit/s or less than as in the total number of consecutive bit/s (of all same binary value) that it records/represents: examples of such number representation systems are disclosed earlier in the description body eg 0->1 10->2 110->3 111->‘extend’, or 0->1 10->2 11->‘extend’, or 1->1 00->2 01->‘extend’ . . . etc. (Note here in place of the above number representation system/s illustrated, ‘unary’ number representation system could be used instead: ‘alternately’ continuous successively ‘switched’ between using a number of ‘unary’ ‘0’ bit/s & a number of ‘unary’ ‘1’s bit/s, same number of ‘unary’ bit/s as the number of consecutive bit/s of all same binary value, to represent the ‘total’ number of consecutive bit/s: a single ‘1’ bit or a single ‘0’ bit to represent ‘total’ number of 1 consecutive bit, 2 consecutive ‘1’s or 2 consecutive ‘0’s bits to represent ‘total’ number of 2 consecutive bits . . . N consecutive ‘1’s bits or N consecutive ‘0’ bits to represent ‘total’ number of N consecutive bits), OR using any of the number representation system/s as described earlier in claims 2-4.
Subsequent to this ‘Second Pass’ stage where the ‘total’ number of consecutive bit/s are completely recorded (instead of incrementing the number of consecutive bit/s by 1 at each subsequent passes, as in earlier described implementation in the description body), there is no further need whatsoever to proceed with any further subsequent passes.
Successively sequentially stepping through only each of the single ‘0’ bit completely ignore/skipping all the single ‘1’ bits in the ‘First Pass File’, record in a new ‘First Extra1 Pass File’ the ‘total’ number of consecutive bit/s of all ‘1’s (which follows the consecutive bit/s of all ‘0’s) preceding the corresponding ‘10’ block in the original binary data file: the ‘total’ number of consecutive ‘1’s bit/s here are recorded/represented using number representation system which costs only 1 ‘extra’ single bit more than the total number of consecutive ‘1’s bit/s that it records/represents: examples of such number representation systems are similar to as disclosed earlier in the description body eg here it is 0->0 10->1 110->2 111->‘extend’, or 0->0 10->1 11->‘extend’, or 1->0 00->1 01->‘extend’ . . . etc. (Note here in place of the above number representation system/s illustrated, ‘unary’ number representation system could be used instead: ‘alternately’ continuous successively ‘switched’ between using a number of ‘unary’ ‘0’ bit/s & a number of ‘unary’ ‘1’s bit/s, 1 more than the ‘total’ number of consecutive bit/s of all same binary value, to represent the ‘total’ number of consecutive bit/s of all same binary value: here it is a single ‘1’ bit or a single ‘0’ bit to represent 0 consecutive ‘1’ bit/s (ie there is zero, no consecutive ‘1’ bit/s), 2 consecutive ‘1’s or 2 consecutive ‘0’s bits to represent ‘total’ of 1 consecutive ‘1’s bits . . . N consecutive ‘1’s bits or N consecutive ‘0’ bits to represent of ‘total’ of N−1 consecutive bits), OR using any of the number representation system/s as described earlier in claims 2-4
Subsequent to this ‘First Extra1 Pass’ stage where the ‘total’ number of consecutive bit/s of all ‘1’s are completely recorded (instead of incrementing the number of consecutive bit/s by 1 at each subsequent Extra1 passes, as in earlier described implementation in the description body), there is no further need whatsoever to proceed with any further subsequent Extra1 passes.

13. Methods or sub-component method step/s for lossless reconstruction of compressed data as described in claim 10 above, said methods or sub-component method step/s here:
From the above ‘Compress File’ & ‘First Pass File’ & ‘Second Pass File’ & ‘First Extra1 Pass File’, together with the various compression process parameters (or pre-appended to the beginning of the single ‘merged’ file of all the files), the original binary data file can always be losslessly reconstructed.

14. Methods or sub-component method step/s for lossless data compressions, said methods or sub-component method step/s here:
examine the original binary data file of arbitrary size sequentially, from initial very 1^{st} starting consecutive bit/s all of same binary value (either ‘0’s, or ‘1’s) to the very end consecutive bit's all of same binary value position (either ‘0’s, or ‘1’s), looking for each successive sequential immediately next adjacent consecutive bit/s all of same binary value (ie a single ‘0’ or a single ‘1’, or a number of consecutive ‘0’s or a number of consecutive ‘1’s: note each successive sequential immediately next adjacent consecutive bit/s in the original binary input file will all be of different/opposite binary value to the binary value of its immediately preceding consecutive bit/s, ie alternatingly ‘switched’ from 0/s to 1/s & 1/s to 0/s successively): Each of these successive sequential immediately next adjacent consecutive bit/s all of same binary value in the original binary data file is successively sequentially recorded in a new ‘Unary Representation’ data file with just one single ‘1’ binary bit or with just one single ‘0’ binary bit, if the consecutive bit/s consists of just a single bit of ‘0’ or a single bit of ‘1’
OPTIONALLY the very initial 1^{st} recorded bit in the ‘Unary File’ could be convention pre-arranged to start recording the very initial first occurrence of consecutive bit/s all of same binary value in the input file with eg a single ‘1’ bit to conveniently correctly convey/indicate that the very initial 1^{st} consecutive bit/s all of same binary value in the input file is of length only 1 single bit, & with eg a single ‘1’ bit to conveniently correctly convey/indicate that the very initial 1^{st} consecutive bit/s all of same binary value in the input file is of length at least 2 or more bits.
If the immediately next adjacent consecutive bit/s is consists of just a single binary bit (necessarily always of different/opposite binary value to the binary value of its immediately preceding binary bit) in the original binary data file, then it is ‘switched’ to using just a single binary bit with binary value different/opposite to the latest recorded binary bit value entry in the ‘Unary File’, to represent/record this present single consecutive bit in the ‘Unary File’
If the immediately next adjacent consecutive bit/s in the original binary data file are not just a single ‘0’ bit or are not just a single ‘1’ bit (ie there are now at least 2 or more consecutive bits of all ‘0’s or of all ‘1’s), then they are represented/recorded in the ‘Unary File’ as a number of consecutive ‘adapted unary bits of unary 0’/s or ‘unary 1’/s, all of same binary value as the immediately preceding binary bit value recorded in the ‘Unary File’, except that in this ‘adapted’ unary representation the very last bit in this number of unary consecutive bits will be made to be ‘switched’ to be of different/opposite binary value to the binary value of all the other consecutive unary bit/s
Each resultant ‘Unary File’ produced (which will always be of same equal file size as the input file, ie ignoring/disregarding the 1 single bit extra costs to indicate the very 1^{st} initial original binary input file) could subsequently be used as a new ‘input file’ in subsequent repeated iterations, it is obvious here that at each iteration the maximum length of consecutive bits all of same binary value in the resultant ‘Unary File’ will be reduced by 1 compared to the maximum length of consecutive bits in the iteration's new ‘input binary file’ used in the iteration:
The repeated iterations may be ‘stopped’ when maximum length of consecutive bits all of same binary value in the resultant ‘Unary File’ becomes equal to certain specified length, whereupon subsequently various different lossless compression algorithm/s may be selected appropriately to actually reduce the file size as much as is possible

15. Methods or sub-component method step/s further compresses the resultant final iteration's ‘Unary File’ produced in accordance with claim 14 above where the max consecutive bits all of same binary value therein is length 2 bits only, said methods or sub-component method step/s HERE FURTHER:
Successive sequentially steps through each immediately next adjacent consecutive bit/s, from the very initial 1^{st} consecutive bit/s to the last consecutive bit/s in the input final ‘Unary File’ (or previous iteration's resultant ‘Reduced File’, if now used as input file in this iteration):
to record a single bit into a new ‘Reduced File’ (of either ‘0’ or ‘1’ binary value) with binary value ‘switched’ to be of different/opposite binary value to the binary value of the immediately preceding ‘recorded’ bit in the ‘Reduced File’, if the present latest corresponding consecutive bit/s in the input final ‘Unary File’ consists only of a single ‘0’ bit or consists only of a single ‘1’ bit.
OPTIONALLY another possible adapted implementation, among many possible, will be to just use a single ‘0’ bit to represent successive sequential immediately next adjacent consecutive bit/s of just 1 single bit, & to represent successive sequential next occurrence of 2 consecutive bits all of same binary value (instead of above described ‘alternatingly’ ‘switched’/‘same’ as immediately preceding recorded bit's binary value . . . ).
OPTIONALLY the very initial 1^{st} recorded bit in the ‘Reduced File’ could be convention pre-arranged to start recording the very initial first occurrence of consecutive bit/s (which can only be of length at most 2 bits here) all of same binary value in the input file with eg a single ‘1’ bit to conveniently correctly convey/indicate that the very initial 1^{st} consecutive bit/s all of same binary value in the input file is of length 2 bits (instead of just a single bit) & a single ‘1’ bit to conveniently correctly convey/indicate that the very initial 1^{st} consecutive bit/s all of same binary value in the input file is of length 1 single bit.
to record a single bit into a new ‘Reduced File’ (of either ‘0’ or ‘1’ binary value) with binary value to be the same binary value as the binary value of the immediately preceding ‘recorded’ bit in the ‘Reduced File’, if the present latest consecutive bit/s in the input file consists of 2 consecutive bits of either ‘00’ or ‘11’ bits patterns
In cases where this ‘file size reduction’ process iteration's new resultant ‘Reduced File’ is equal (or very very close to) in size to the size of the input file, this invariably signifies the resultant new ‘Reduced File’ consists only of very basic bit/s pattern/s repeated many many time throughout the resultant new ‘Reduced File’, & would be ideal to now for a different & appropriate algorithm to be next ‘selected’ to next reduce the file size by magnitude orders: eg resultant new ‘Reduced File’ may simply consists of regular continuous successive ‘alternating’ ‘switched’ bits pattern of single ‘0’ bit & single ‘1’ bit (ie an appropriate algorithm here could simply be Run Length type algorithm which compresses entire file as ‘10’ bits pattern or ‘01’ bits pattern repeated a specified number of times, &/or plus a single ‘end bit value’ . . . etc
OPTIONALLY the very initial 1^{st} recorded bit in the ‘Reduced File’ could be pre-arranged to start recording the very initial first occurrence of consecutive bit/s (which can only be of length at most 2 bits here) all of same binary value in the input file with eg a single ‘1’ bit to conveniently correctly convey/indicate that the very initial 1^{st} consecutive bit/s all of same binary value in the input file is of length 2 bits (instead of just a single bit), & with eg a single ‘1’ bit to conveniently correctly convey/indicate that the very initial 1^{st} consecutive bit/s all of same binary value in the input file is of length 1 single bit.
The ‘file size reduction’ method here will always provide/store as a ‘single bit parameter’ the binary value of the very 1^{st} consecutive bit/s of all ‘0’/s or ‘1’/s of the very initial 1^{st} original input binary file used in the very initial 1^{st} iteration in the ‘unary representation’ process (ie which lossless reconstruction process would attempt to subsequently ‘recreate’ faithfully, its not the binary value of the very 1^{st} consecutive number of bit/s ‘0’ or ‘1’ of the final iteration's resultant final ‘Reduced File’: note only the very initial 1^{st} original input binary file input file's very 1^{st} consecutive bit/s' binary value needs be provided, not all the successive iterations' input files'), which could optionally be conveyed eg with pre-agreed format to insert/pre-append an ‘extra’ very first single ‘1’ bit or an ‘extra’ very first single ‘0’ bit in eg the very first bit position of the final iteration's resultant ‘Reduced File’ to notify that the value of the very first ‘bit’ in the very initial 1^{st} original input binary data file as ‘1’ or ‘0’ respectively

16. Methods or sub-component method steps as in accordance in any of claims 15 above, said methods or sub-component method step/s HERE FURTHER:
The resultant ‘Reduced File’ from claim 15 above is now to be used as new input file (in place of the input final ‘Unary File’, or any previous earlier iteration's input ‘Reduced File’) in a new iteration of the ‘file size reduction’ process in Paragraph 1 above, UNTIL certain specified criteria is attained eg certain specified compression ratio is achieved, or eg file size is reduced to certain specified size, or eg there remains not more than a specified total number of all consecutive 2 bits of same binary value in the latest iteration's ‘Reduced File’ . . . etc. The resultant ‘Reduced File’ at each iteration needs to be checked if number of max consecutive bits at end of the iteration grows to be > eg 2: if it does not then proceed to next ‘file size reduction’ as described in Paragraph 2 here, OTHERWISE (if > eg 2 now) then next iteration should go through earlier ‘unary representation’ process again until number of max consecutive bits again becomes not more than eg 2 before proceeds onto next iteration of ‘file size reduction’ process.
The resultant final iteration's ‘Reduced File’, together with various of the parameters of the ‘file size reduction’ process which should at least include the total number of ‘file size reduction’ process iterations . . . , & together with the parameters of the earlier ‘Unary File’ process which should at least include the total number of ‘Unary File’ process iterations, & together with the ‘single bit parameter’ of the binary value of the very 1^{st} consecutive bit/s of all ‘0’/s or ‘1’/s of the very initial 1^{st} original input binary file used in the very initial 1^{st} iteration in the ‘unary representation’ process, & the ‘specified’ number of max consecutive bits, could now be stored (whether ‘separately’, or pre-appended to pre-agreed fixed initial bit/s positions of the resultant final ‘Reduced File’) which would enable lossless faithful reconstruction of the very initial original binary data file.

16. Methods or sub-component method step/s based on or modified from methods or sub-component method step/s as described in claim 14 or 15 above, said methods or sub-component method step/s here:
the ‘file size reduction’ process could also use other various number representation system described in any of the claims 2-4 eg 0->1 10->2 11->3 . . . etc if the ‘unary representation’ process specifies ‘stop’ to be at max consecutive bits of eg 3 . . . etc., this method here first uses ‘unary representation’ process to iteratively reduces the maximum number of bits present in any consecutive bit/s of all same binary value in the new resultant final ‘Unary File’ to a specified maximum number eg 3 . . . etc (note here all the various iteration's resultant ‘Unary File/s’ including the resultant final ‘Unary File’ will be of exact same size as the very 1st initial original input binary data file size throughout, ie ignoring/disregarding the earlier described small number of parameter bit/s), then next ‘file size reduction’ process will produce a ‘Reduced File’ with file size always less than or at very worst equal to the file size of the present iteration's input file & IF there are now maximum number of bits present in any consecutive bit/s (all of same binary value) greater than the specified maximum number (eg 3 . . . etc) in this ‘file size reduction’ iteration's resultant new ‘Reduced File’ then the overall process flow will start again at the beginning of the ‘unary representation’ process above with this iteration's resultant new ‘Reduced File’ used as input file, OTHERWISE the overall process flow will iterate again in ‘file size reduction’ process with this iteration's resultant new ‘Reduced File’ used as input file:
This overall process flow repeatedly iterates UNTIL certain specified criteria is attained eg certain specified compression ratio is achieved, or eg file size is reduced to certain specified size, or eg there remains not more than a specified total number of all consecutive 3 bits of same binary value in the latest iteration's ‘Reduced File’ . . . .

17. Methods or sub-component method step/s for lossless data compressions, said methods or sub-component method step/s:
uses number representation system/s as described in claim 2 or claim 4 above
Starting from the very initial 1^{st} consecutive bit/s to the last consecutive bit/s in the original input binary data file, the number of consecutive bit/s at each successive sequential consecutive bit/s is successively recorded/represented in the resultant ‘Number File’ using above number representation system which has smallest sufficient ‘symbols set’ to cover/represent number up to the maximum number of consecutive bits present in the original input binary data file
OPTIONALLY an extra costs single bit needs be provided to indicate the very initial 1^{st} starting consecutive bit/s' binary value in the very initial 1^{st} original input file (it could also optionally record/indicate such extra costs single bit for each & every of all iterations, as parameters of the overall number representation’ process iterations! BUT this is unnecessary), this single bit parameter indicating the very initial 1^{st} starting consecutive bit/s' binary value in the very initial 1^{st} original input file could be stored separately from the final ‘Number File’, or be optionally pre-appended to the overall number representation process iterations resultant final ‘Number File’
This previous iteration's resultant ‘Number File’ in Paragraph 3 above will now next be used as input file in subsequent next iteration, this time using number representation system which has smallest sufficient ‘symbols sets’ (ie symbol sets requiring the least number of bit/s, eg number representation system 0->1 10->2 11->3 requires only at most 2 bits, ie ‘11’, to represent 3 consecutive bits in the input file) to cover/represent up to the maximum number of now M consecutive bits present in this iteration's input file . . . & so forth UNTIL some specified criteria is reached eg the maximum number of consecutive bit/s in the iteration's resultant final ‘Number File’ is exactly eg 1 or 2 . . . etc, or certain specified compression ratio efficiency is attained, or the resultant final file size has been compressed to less than certain specified size . . . etc:
Note the maximum number of M consecutive bits present in the previous iteration's resultant ‘Number File (which subsequently now becomes the next iteration's input file) could be larger than the maximum number of N consecutive bits present in the previous iteration's input file, ie it may be that now M>N (the maximum number M consecutive bits in the input file of an iteration could be ascertained by first examining the input file itself): IF so this subsequent next ‘unextended number representation’ iteration will now use a number representation system which has smallest sufficient ‘symbols sets’ (ie this symbols set which now requiring the least number of bit/s to represent maximum number of M consecutive bits in the input file) to cover/represent up to the maximum number of now M consecutive bits present in this iteration's input file.

18. Methods or sub-component method step/s for lossless reconstruction of compressed data as described in claim 17 above, said methods or sub-component method step/s here:
To lossless faithfully reconstruct the very initial 1^{st} original input binary data file, just need to provide the overall number representation process iterations resultant final ‘Number File’, together with parameters set/s of the overall iterations which should at least includes the very initial maximum number of consecutive bits present in the very initial 1^{st} original input binary data file used in the very 1^{S}′ ‘ number representation process iteration, & the extra costs single bit parameter value needed to indicate the very initial 1^{st} starting consecutive bit/s’ binary value in the very initial 1^{st} original input binary data file used in the very 1^{st} ‘number representation iteration: Other parameters could be included such as the total number of number representation iterations, the overall number representation process iterations' ‘specified’ ‘stop’ maximum consecutive bits number, (if any) the parameters regarding the different appropriate algorithm/s ‘selected’ to be used in a particular iteration stage.

19. Methods or sub-component method step/s for lossless data based on and modifying the methods or sub-component method step/s as described in claim 17 above, said methods or sub-component method step/s:
Whenever M the maximum number of consecutive bits present in the latest iteration's resultant file becomes >=the maximum number of consecutive bits present in the latest iteration's input file THEN the particular iteration number/identification & the particular iteration's parameter M of maximum number of consecutive bits present in the latest iteration's resultant file needs be recorded/conveyed eg pre-appended to the resultant file at pre-specified initial bits positions OR separately stored, Or each & every iterations' number/identification & corresponding maximum number of consecutive bits present in the latest iteration's resultant file could simply be all recorded/conveyed eg pre-appended to the resultant file at pre-specified initial bits positions OR separately stored

20. Methods or sub-component method step/s for lossless data based on and modifying the methods or sub-component method step/s as described in claim 17 or claim 19 above, said methods or sub-component method step/s:
OPTIONALLY the number representation system & its ‘complement’ binary representation system are successively alternately used to record/represent successive consecutive bit/s all of same binary value
the actual maximum number of M consecutive bits present in the previous iteration's resultant ‘Number File (which subsequently now becomes the next iteration's input file) could be larger than the maximum number of N consecutive bits present in the previous iteration's input file, ie it may be that now M>N (the maximum number M consecutive bits in the input file of an iteration could be ascertained by first examining the input file itself), EVEN IF so this subsequent next number representation iteration will still not be required to now use an number representation system which has smallest sufficient ‘symbols sets’ (ie this symbols set which now requiring the least number of bit/s to represent maximum number of M consecutive bits in the input file) to cover/represent up to the maximum number of now M consecutive bits present in this iteration's input file, this iteration could SIMPLY assume any consecutive number of bits >N−1 (all of same binary value) present in this iteration's input file to be composed of an integer multiple of N−1 consecutive bits PLUS a ‘remainder’ number of consecutive bits <N−1 (all of same binary value), & thus able to sequential successively utilise number representation system/s which has smallest sufficient ‘symbols sets’ to cover/represent up to the maximum number of initially N then now N−1, N−2, N−3 . . . N−(N−2) consecutive bits present in each subsequent successive iteration's input file→its now obvious that the total number of iterations will only be at most N−1 (ie total of N−1 iterations, each successive iterations uses number representation system/s sufficient to cover/represent initially N then now N−1, N−2, N−3 . . . N−(N−2) maximum number of consecutive bits all of same binary value in the iteration's input file, & even though during any or some of these iterations eg during iteration which uses number representation system sufficient to cover/represent N−2 maximum consecutive number of bits it is also very possible that the actual maximum number of consecutive bits (all of same binary value) present in the iteration's input file is <N−2 (on the other hand if that the actual maximum number of consecutive bits (all of same binary value) present in the iteration's input file is >N−2, this iteration could SIMPLY assume any consecutive number of bits >N−1 (all of same binary value) present in this iteration's input file to be composed of an integer multiple of N−1 consecutive bits PLUS a ‘remainder’ number of consecutive bits <N−1 (all of same binary value): NOTE this ‘remainder’ number of consecutive bit/s on its own could not represent any particular number representation number eg ‘remainder’ bit/s of eg ‘1’ needs be combined with an immediately following bit of ‘0’ in the input file to be able to concatenate form bits pattern ‘10’ to represent the number ‘2’ . . . .

21. Methods or sub-component method step/s for lossless reconstruction of compressed data as described in claim 20 above, said methods or sub-component method step/s here:
Accept as input the overall ‘unextended number representation’ process iterations resultant final ‘Number File’, together with parameters set/s of the overall iterations which should at least includes the very initial maximum number of consecutive bits present in the very initial 1^{st} original input binary data file used in the very 1^{st} number representation process iteration, & the extra costs single bit parameter value needed to indicate the very initial 1^{st} starting consecutive bit/s' binary value in the very initial 1^{st} original input binary data file used in the very 1^{st} number representation iteration, other parameters could be included such as the total number of number representation iterations, the overall number representation process iterations' ‘specified’ ‘stop’ maximum consecutive bits number, (if any) the parameters regarding the different appropriate algorithm/s ‘selected’ to be used in a particular iteration stage

22. Methods or sub-component method step/s for lossless data based on and modifying the methods or sub-component method step/s as described in claim 17 or claim 19 or claim 20 above, said methods or sub-component method step/s:
uses number representation system/s sufficient to cover/represent number equal to ‘specified’ max number of consecutive bits present in the input file, eg if there are only max number of consecutive bits of 4 present in the input file THEN the number representation system could be eg 0->1 10->2 110->3 111->4 (‘111’->4 here gained 1 bit reduction, ie recording/representing eg 4 consecutive bits in the input file as 3 bits in the resultant ‘Number File’) . . . likewise similar number representation system could be designed/selected sufficient to cover/represent N maximum number of consecutive bits . . . etc, also needed is the ‘complement’ of the above number representation system’, ie an identical number representation system as above BUT with ‘reverse binary value symbols set’: ie now the symbols set comprises 1->1 01->2 001->3 000->4 .
Starting from the very initial 1^{st} consecutive bit/s to the last consecutive bit/s in the original input binary data file, the number of consecutive bit/s at each successive sequential consecutive bit/s is successively recorded/represented in the resultant ‘Number File’: successive alternately using number representation system which has smallest sufficient ‘symbols set’ to cover/represent number up to the maximum number of N consecutive bits present in the original input binary data file, & the ‘complement’ ‘reverse binary value symbols set’ of the above number representation system
OPTIONALLY It could be convention pre-agreed to first use the ‘unextended number representation’ system (& not its ‘complement’ ‘reverse binary value symbols set’) to record/represent the very initial 1^{st} consecutive bit/s of the iteration's input file.
OPTIONALLY by first using the appropriate choice of the number representation system or its ‘complement’ ‘reverse binary value symbols set’ number representation system to record/represent the very initial 1^{st} consecutive bit/s of the iteration's input file, there is no need to record/represent as ‘single bit parameter’ the binary value of the very 1^{st} consecutive bit/s of the very initial 1^{st} original input binary data file used in the very 1^{st} number representation process iteration: ie to convention pre-agree to first use the ‘one’ which employs the same symbol value (‘0’ or ‘1’) as the binary value of the very 1^{st} consecutive bit/s in the iteration's input file to represent 1 single consecutive bit.

23. Methods or sub-component method step/s for lossless data based on and modifying the methods or sub-component method step/s as described in claim 17 or claim 19 or claim 20 or claim 22 above, said methods or sub-component method step/s:
Starting from the very initial 1^{st} consecutive bit/s to the last consecutive bit/s in the original input binary data file, the number of consecutive bit/s at each successive sequential consecutive bit/s is successively recorded/represented in the resultant ‘Number File’: successive alternately using number representation system which has smallest sufficient ‘symbols set’ to cover/represent number up to the maximum number of N consecutive bits present in the original input binary data file, & the ‘complement’ ‘reverse binary value symbols set’ of the above number representation system
uses ‘successive alternately switched’ binary value recordings to denote eg ‘1 single consecutive bit’, starting from the initial very 1^{st} consecutive bit/s pattern (which could be either a single ‘1’ or a single ‘0’ or a plurality of ‘1’s or a plurality of ‘0’s) to the very last Nth consecutive bit/s pattern in the ‘input file’, each sequential successive bit/s pattern in the ‘input file’ is identified by its ‘position #’ (from initial position #1, to position #2, to position #3 . . . . & so forth . . . to position #N), each bit/s pattern would have either ‘odd’ or ‘even’ position #
It is pre-arranged so that should the bit/s pattern at the ‘odd’ position # consists of just a single bit pattern of either 1 single ‘0’ or 1 single ‘1’ (other possible alternatives: . . . if consists of just exact bits pattern of ‘10’ of exact length 2 bits . . . etc) then eg a single ‘1’ bit could be ‘expected’ to recorded into the ‘resultant file’ to denote this OTHERWISE eg a single ‘0’ bit or even some number representation system which has initial very 1st leading ‘0’ bit could be recorded into the ‘resultant file’, AND should the bit/s pattern at the ‘even’ position # consists of just a single bit pattern of either 1 single ‘0’ or 1 single 1′ (other possible alternatives . . . if consists of just exact bits pattern of ‘10’ of exact length 2 bits . . . etc) then eg a single ‘0’ bit could be ‘expected’ to recorded into the ‘resultant file’ to denote this OTHERWISE eg a single ‘1’ bit or even some number representation system which has initial very 1^{st} leading ‘1’ bit could be recorded into the ‘resultant file’:
Further it could also optionally be pre-arranged so that were any immediately preceding bit/s pattern consists of a plurality of consecutive bits, then this present current bit/s pattern would now be ‘expected’ instead to utilise/record a single bit of same ‘expected’ binary value corresponding to that of the immediately preceding bits pattern position #

24. Methods or sub-component method step/s as in accordance in any of claims 1- above, said methods or sub-component method step/s here:
adapts/modify the methods/sub-component steps as described in any of the claims 2-23 above to N-ary based implementations/applications

25. Methods or sub-component method step/s for lossless data compressions or for compression/representation of sequential list of positive integers integers or offsetted to all be positive integers >0, said methods or sub-component method step/s:
Any combination of the methods, any combination of various sub-component/s method step/s as described in any of the claims 2-24 above, AND also any combination of various other existing state of art methods may be combined/interchanged/adapted/modified/replaced/added/improved upon to give various adapted implementations
